(19) United States
(12) Patent Application Publication
(10) Pub. No.: US 2024/0295814 A1
(43) Pub. Date: Sep. 5, 2024

(54) RESIST COMPOSITION, RESIST PATTERN FORMING METHOD, AND POLYMER

(71) Applicant: TOKYO OHKA KOGYO CO., LTD., Kawasaki-shi (JP)

(72) Inventors: Keiichi IBATA, Kawasaki-shi (JP); Tomotaka YAMADA, Kawasaki-shi (JP); Takuya UEHARA, Kawasaki-shi (JP)

(21) Appl. No.: 18/424,025

(22) Filed: Jan. 26, 2024

(30) Foreign Application Priority Data
Feb. 10, 2023 (JP) 2023-019220

(51) Int. Cl. G03F 7/039; G03F 7/029; G03F 7/038; G03F 7/075; G03F 7/32

(52) U.S. Cl. CPC G03F 7/0392; G03F 7/029; G03F 7/0382; G03F 7/0758; G03F 7/322

(57) ABSTRACT

A resist composition that generates acid upon exposure and exhibits changed solubility in a developing solution under action of acid. The resist composition contains a polymer containing a siloxane bond and an ionic group represented by General Formula (I0), which is decomposed upon exposure to generate an acid. In General Formula (I0), M^{m+} represents a sulfonium cation or an iodonium cation, m represents an integer of 1 or more, and * represents a bonding site

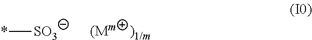

### BACKGROUND OF THE INVENTION

### Field of the Invention

The present invention relates to a resist composition, a resist pattern forming method, and a polymer.

Priority is claimed on Japanese Patent Application No. 2023-019220, filed on Feb. 10, 2023, the content of which is incorporated herein by reference.

### Description of Related Art

In the manufacture of electronic components, a treatment including etching is carried out on a laminate in which a resist film is formed on a substrate such as a silicon wafer using a resist material. For example, a treatment in which a resist pattern is formed on a resist film by selectively exposing the resist film, and dry etching is carried out using the resist film as a mask to form a pattern on the substrate is carried out.

In recent years, in the production of semiconductor elements and liquid crystal display elements, with advances in lithography techniques, rapid progress in the field of pattern fining has been achieved. In general, the pattern fining technique involves shortening the wavelength (increasing the energy) of the light source for exposure.

Resist materials have been required to have lithography characteristics such as sensitivity to these light sources for exposure and resolution capable of reproducing a fine-sized pattern.

As a resist material that satisfies these requirements, a chemical amplification-type resist composition that contains a base material component having solubility in a developing solution, which is changed under action of acid, and an acid generator component that generates acid upon exposure has been used in the related art.

In the chemical amplification-type resist composition, a resin having a plurality of constitutional units is generally used in order to improve lithography characteristics. In addition, a chemical amplification-type resist composition in which an acid generator component is used in combination with an acid diffusion controlling agent that controls the diffusion of the acid generated from the acid generator component upon exposure has been proposed.

Further, as the resist material, a material having etching resistance is required in order to fulfill the function as a mask for substrate processing. On the other hand, a silicon-containing resin is generally used as a base material component.

For example, Patent Document 1 discloses a resist composition containing a silicon-containing resin, an acid generator component, and a photodecomposable base that controls the diffusion of acid in order to cope with pattern fining and etching processing.

### CITATION LIST

### Patent Document

[Patent Document 1] Japanese Unexamined Patent Application, First Publication No. 2022-59575

### SUMMARY OF THE INVENTION

With further advances in lithography techniques, rapid progress in the field of pattern fining is being achieved together with the expansion of application fields. In association with this, in a case of producing a semiconductor element or the like, a technique that makes it possible to form a fine-sized pattern in a favorable shape is required. For example, lithography using an extreme ultraviolet ray (EUV) aims to form a fine pattern in a range of ten and several nm. As the pattern size becomes smaller as described above, it becomes difficult to achieve both etching resistance and lithography characteristics.

On the other hand, in such a resist composition as disclosed in Patent Document 1, which contains a silicon-containing resin as a base material component, there is an advantage of high dry etching resistance as compared with a resist composition containing a general organic material as the base material component; however, in the formation of a targeted fine pattern, there is a need for further improvement in terms of the effect of reducing pattern roughness.

The present invention has been made in consideration of the above circumstances, and an object of the present invention is to provide a resist composition that contains a silicon-containing resin and has an enhanced effect of reducing pattern roughness, a resist pattern forming method using the resist composition, and a polymer useful as a base material component of the resist composition.

In order to achieve the above-described object, the present invention employs the following configurations.

That is, a first aspect of the present invention is a resist composition characterized by being a resist composition that generates acid upon exposure and exhibits changed solubility in a developing solution under action of acid, the resist composition containing a polymer (A1) containing a siloxane bond and an ionic group represented by General Formula (I0), which is decomposed upon exposure to generate acid.

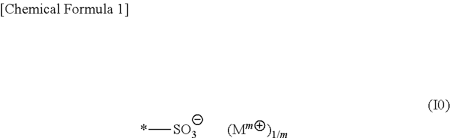

[In the formula, M^{m+} represents a sulfonium cation or an iodonium cation. m represents an integer of 1 or more. * represents a bonding site.]

A second aspect of the present invention is a resist pattern forming method characterized by including a step (i) of forming a resist film on a support using the resist composition according to the first aspect, a step (ii) of exposing the resist film, and a step (iii) of developing the exposed resist film to form a resist pattern.

A third aspect of the present invention is a polymer characterized by containing a siloxane bond and an ionic group represented by General Formula (I0″), which is decomposed upon exposure to generate acid.

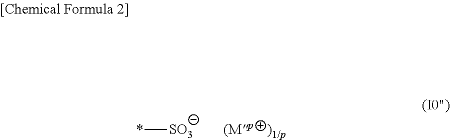

[In the formula, M″^{p+} represents an onium cation or a metal cation. p represents an integer of 1 or more. * represents a bonding site.]

A fourth aspect of the present invention is a polymer characterized by containing a siloxane bond and an ionic group represented by General Formula (I0), which is decomposed upon exposure to generate acid.

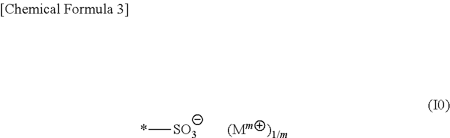

[In the formula, M^{m+} represents a sulfonium cation or an iodonium cation. m represents an integer of 1 or more. * represents a bonding site.]

According to the present invention, it is possible to provide a resist composition that contains a silicon-containing resin and has an enhanced effect of reducing pattern roughness, a resist pattern forming method using the resist composition, and a polymer useful as a base material component of the resist composition

### DETAILED DESCRIPTION OF THE INVENTION

In the present specification and the scope of the present claims, the term “aliphatic” is a relative concept used with respect to the term “aromatic” and defines a group or compound that has no aromaticity.

The term “alkyl group” includes a monovalent saturated hydrocarbon group that is linear, branched, or cyclic unless otherwise specified. The same applies to the alkyl group of an alkoxy group.

The term “alkylene group” includes a divalent saturated hydrocarbon group that is linear, branched, or cyclic unless otherwise specified.

Examples of the “halogen atom” include a fluorine atom, a chlorine atom, a bromine atom, and an iodine atom.

The term “constitutional unit” means a monomer unit (a monomeric unit) that constitutes a polymeric compound (a resin, a polymer, or a copolymer).

In a case where the phrase “may have a substituent” is described, both of a case where a hydrogen atom (—H) is substituted with a monovalent group and a case where a methylene group (—CH₂—) is substituted with a divalent group are included.

The term “exposure” is used as a general concept that includes irradiation with active energy rays such as an ultraviolet ray, a radiation, and an electron beam.

The term “acid decomposable group” is a group having acid decomposability, in which at least part of bonds in the structure of the acid decomposable group can be cleaved under action of acid.

Examples of the acid decomposable group having a polarity that is increased under action of acid include groups that are decomposed under action of acid to generate a polar group.

Examples of the polar group include a carboxy group, a hydroxyl group, an amino group, and a sulfo group (—SO₃H).

More specific examples of the acid decomposable group include a group (for example, a group obtained by protecting a hydrogen atom of the OH-containing polar group with an acid dissociable group) obtained by protecting the above-described polar group with an acid dissociable group.

The term “acid dissociable group” refers to any one of (i) a group having acid dissociability, in which a bond between the acid dissociable group and an atom adjacent to the acid dissociable group can be cleaved under action of acid; and (ii) a group in which part of bonds are cleaved under action of acid, and then a decarboxylation reaction occurs, thereby cleaving the bond between the acid dissociable group and the atom adjacent to the acid dissociable group.

It is necessary that the acid dissociable group that constitutes the acid decomposable group be a group that exhibits a lower polarity than the polar group generated by the dissociation of the acid dissociable group. Thus, in a case where the acid dissociable group is dissociated under action of acid, a polar group that exhibits a higher polarity than the acid dissociable group is generated, thereby increasing the polarity. As a result of the above, the polarity of the total components having this acid dissociable group is increased. With the increase in the polarity, the solubility in a developing solution relatively changes. The solubility in a developing solution is increased in a case where the developing solution is an alkali developing solution, whereas the solubility in a developing solution is decreased in a case where the developing solution is an organic developing solution.

The term “base material component” is an organic compound having a film-forming ability. The organic compounds used as the base material component are roughly classified into a non-polymer and a polymer. As the non-polymer, those having a molecular weight of 500 or more and less than 4,000 are generally used. Hereinafter, a “low molecular weight compound” refers to a non-polymer having a molecular weight of 500 or more and less than 4,000. As the polymer, those having a molecular weight of 1,000 or more are generally used. Hereinafter, a “resin”, a “polymeric compound”, or a “polymer” refers to a polymer having a molecular weight of 1,000 or more. As the molecular weight of the polymer, a weight average molecular weight in terms of the polystyrene equivalent value determined by gel permeation chromatography (GPC) is used.

The term “constitutional unit derived from” means a constitutional unit that is formed by the cleavage of a multiple bond between carbon atoms, for example, an ethylenic double bond.

In the present specification and the scope of the present claims, asymmetric carbon atoms may be present, and thus enantiomers or diastereomers may be present depending on the structures represented by the chemical formula. In that case, these isomers are represented by one chemical formula. These isomers may be used alone or in the form of a mixture.

(Resist composition) The resist composition according to the first aspect of the present invention is a resist composition that generates an acid upon exposure and whose solubility in a developing solution is changed by the action of an acid. One embodiment of such a resist composition contains a silicon-containing resin (A) (hereinafter, also referred to as a “component (A)”), where the component (A) includes a specific polymer, that is, a polymer (A1) containing a siloxane bond and an ionic group represented by General Formula (I0), which is decomposed upon exposure to generate acid.

The resist composition according to the present embodiment may be used for an alkali developing process in which an alkali developing solution is used in the developing treatment in the formation of a resist pattern, or may be used for a solvent developing process in which a developing solution containing an organic solvent (organic developing solution) used in the developing treatment.

That is, in a case where the resist composition according to the present embodiment is a “negative-tone resist composition for an alkali developing process” that forms a negative-tone resist pattern in an alkali developing process or a “positive-tone resist composition for a solvent developing process” that forms a positive-tone resist pattern in a solvent developing process, a resin soluble in an alkali developing solution is used as the preferred component (A), and a crosslinking agent component is further blended thereto. In such a resist composition, in a case where acid is generated from the polymer (A1) upon exposure, the acid acts to cause crosslinking between the resin soluble in an alkali developing solution and the crosslinking agent component, and as a result, the solubility in an alkali developing solution is decreased (the solubility in an organic developing solution is increased). The polymer (A1) may be a resin soluble in an alkali developing solution.

Therefore, in the resist pattern formation, by conducting selective exposure of a resist film formed by applying the resist composition onto a support, the exposed portions of the resist film change to an insoluble state in an alkali developing solution (a soluble state in an organic developing solution), whereas the unexposed portions of the resist film remain soluble in an alkali developing solution (an insoluble state in an organic developing solution), and thus a negative-tone resist pattern is formed by carrying out development with the alkali developing solution. Further, in this case, a positive-tone resist pattern is formed by developing with the organic developing solution.

That is, in a case where the resist composition according to the present embodiment is a “positive-tone resist composition for an alkali developing process” that forms a positive-tone resist pattern in an alkali developing process or a “negative-tone resist composition for a solvent developing process” that forms a negative-tone resist pattern in a solvent developing process, a resin having a polarity that is increased under action of acid is used as the preferred component (A). In a case of using a resin having a polarity that is increased under action of acid, the polarity of the resin changes before and after the exposure, and thus it is possible to obtain a favorable development contrast not only in the alkali developing process but also in the solvent developing process.

In a case of applying an alkali developing process, a resin having a polarity that is increased under action of acid is substantially insoluble in an alkali developing solution prior to exposure. However, in a case where acid is generated from the polymer (A1) upon exposure, the action of this acid causes an increase in the polarity, thereby increasing the solubility in an alkali developing solution. The polymer (A1) may be a resin having a polarity that is increased under action of acid.

Therefore, in the resist pattern formation, in a case of carrying out selective exposure of a resist film formed by applying the resist composition onto a support, exposed portions of the resist film change from an insoluble state to a soluble state in an alkali developing solution, whereas unexposed portions of the resist film remain insoluble in an alkali developing solution, and thus, a positive-tone resist pattern is formed by alkali developing. Alternatively, in this case, a negative-tone resist pattern is formed in a case where development is carried out with an organic developing solution.

Among the above, the resist composition according to the present embodiment is particularly useful for the alkali developing process, and it is suitable as a “negative-tone resist composition for an alkali developing process”.

### <Polymer (A1)>

The polymer (A1) is a polymer (hereinafter, also referred to as a “component (A1)”) containing a siloxane bond (a Si—O—Si bond) and an ionic group represented by General Formula (I0), which is decomposed upon exposure to generate acid.

In the resist composition according to the present embodiment, the component (A1) acts as an acid generator that generates acid upon exposure. In addition, the component (A1) can be a base material component that mainly constitutes a resist film.

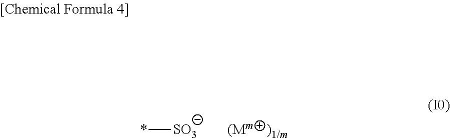

[In the formula, M^{m+} represents a sulfonium cation or an iodonium cation. m represents an integer of 1 or more. * represents a bonding site.]

In General Formula (I0), examples of the cation moiety ((M^{m+})_{1/m}) include cations each represented by General Formulae (ca-1) to (ca-3).

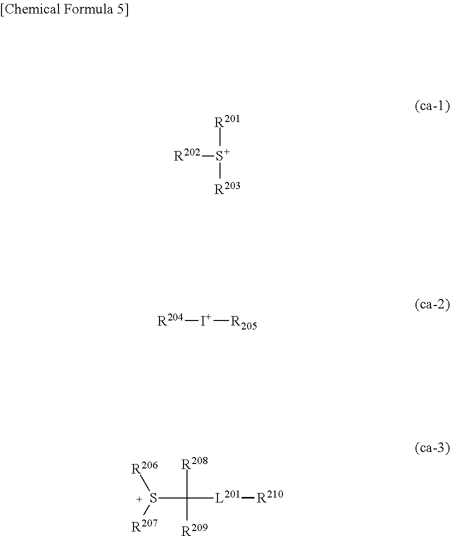

[In the formula, R²⁰¹ to R²⁰⁷ each independently represent an aryl group which may have a substituent, an alkyl group which may have a substituent, or an alkenyl group which may have a substituent. R²⁰¹ to R²⁰³, and R²⁰⁶ and R²⁰⁷ may be bonded to each other to form a ring together with the sulfur atoms in the formulae. R²⁰⁸ and R²⁰⁹ each independently represent a hydrogen atom or an alkyl group having 1 to 5 carbon atoms. R²¹⁰ represents an aryl group which may have a substituent, an alkyl group which may have a substituent, an alkenyl group which may have a substituent, or a —SO₂—-containing cyclic group which may have a substituent. L²⁰¹ represents —C(═O)— or —C(═O)—O—.]

In General Formulae (ca-1) to (ca-3), examples of the aryl group as R²⁰¹ to R²⁰⁷ include an unsubstituted aryl group having 6 to 20 carbon atoms, where a phenyl group or a naphthyl group is preferable.

The alkyl group as R²⁰¹ to R²⁰⁷ is preferably a chain-like or cyclic alkyl group which has 1 to 30 carbon atoms.

The alkenyl group as R²⁰¹ to R²⁰⁷ preferably has 2 to 10 carbon atoms.

Examples of the substituent which may be contained in R²⁰¹ to R²⁰⁷ and R²¹⁰ include an alkyl group, a halogen atom, a halogenated alkyl group, a carbonyl group, a cyano group, an amino group, an aryl group, and groups each represented by General Formulae (ca-r-1) to (ca-r-7).

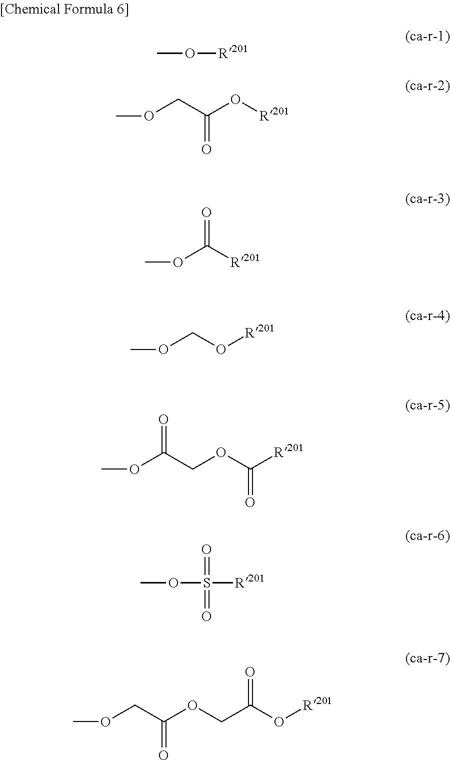

[In the formulae, each R′²⁰¹ independently represents a hydrogen atom, a cyclic group which may have a substituent, a chain-like alkyl group which may have a substituent, or a chain-like alkenyl group which may have a substituent.]

Cyclic group which may have substituent:

The cyclic group is preferably a cyclic hydrocarbon group, and the cyclic hydrocarbon group may be an aromatic hydrocarbon group or an aliphatic hydrocarbon group. The aliphatic hydrocarbon group indicates a hydrocarbon group that has no aromaticity. The aliphatic hydrocarbon group may be saturated or unsaturated. In general, it is preferable that the aliphatic hydrocarbon group is saturated.

The aromatic hydrocarbon group as R′²⁰¹ is a hydrocarbon group having an aromatic ring. The aromatic hydrocarbon group preferably has 3 to 30 carbon atoms, more preferably has 5 to 30 carbon atoms, still more preferably has 5 to 20 carbon atoms, particularly preferably has 6 to 15 carbon atoms, and most preferably has 6 to 10 carbon atoms. Here, the number of carbon atoms in a substituent is not included in the number of carbon atoms.

Specific examples of the aromatic ring contained in the aromatic hydrocarbon group as R′²⁰¹ include benzene, fluorene, naphthalene, anthracene, phenanthrene, biphenyl, or an aromatic heterocyclic ring obtained by substituting a part of carbon atoms constituting these aromatic rings with a hetero atom. Examples of the hetero atom in the aromatic heterocyclic rings include an oxygen atom, a sulfur atom, and a nitrogen atom.

Specific examples of the aromatic hydrocarbon group as R′²⁰¹ include a group obtained by removing one hydrogen atom from the above-described aromatic ring (an aryl group; for example, a phenyl group or a naphthyl group) and a group in which one hydrogen atom in the aromatic ring has been substituted with an alkylene group (for example, an arylalkyl group such as a benzyl group, a phenethyl group, a 1-naphthylmethyl group, a 2-naphthylmethyl group, 1-naphthylethyl group, or a 2-naphthylethyl group). The alkylene group (an alkyl chain in the arylalkyl group) preferably has 1 to 4 carbon atoms, more preferably has 1 or 2 carbon atoms, and particularly preferably has 1 carbon atom.

Examples of the cyclic aliphatic hydrocarbon group as R′²⁰¹ include aliphatic hydrocarbon groups containing a ring in the structure thereof.

Examples of the aliphatic hydrocarbon group containing a ring in the structure thereof include an alicyclic hydrocarbon group (a group obtained by removing one hydrogen atom from an aliphatic hydrocarbon ring), a group in which the alicyclic hydrocarbon group is bonded to the terminal of a linear or branched aliphatic hydrocarbon group, and a group in which the alicyclic hydrocarbon group is interposed in a linear or branched aliphatic hydrocarbon group.

The alicyclic hydrocarbon group preferably has 3 to 20 carbon atoms and more preferably has 3 to 12 carbon atoms.

The alicyclic hydrocarbon group may be a polycyclic group or a monocyclic group. The monocyclic alicyclic hydrocarbon group is preferably a group obtained by removing one or more hydrogen atoms from a monocycloalkane. The monocycloalkane is preferably a monocycloalkane having 3 to 6 carbon atoms, and specific examples thereof include cyclopentane and cyclohexane. The polycyclic alicyclic hydrocarbon group is preferably a group obtained by removing one or more hydrogen atoms from a polycycloalkane, and the polycycloalkane preferably has 7 to 30 carbon atoms. Among the above, the polycycloalkane is more preferably a polycycloalkane having a bridged ring-based polycyclic skeleton, such as adamantane, norbornane, isobornane, tricyclodecane, or tetracyclododecane; or a polycycloalkane having a condensed ring-based polycyclic skeleton, such as a cyclic group having a steroid skeleton.

Among them, the cyclic aliphatic hydrocarbon group as R′²⁰¹ is preferably a group obtained by removing one or more hydrogen atoms from a monocycloalkane or a polycycloalkane, more preferably a group obtained by removing one hydrogen atom from a polycycloalkane, particularly preferably an adamantyl group or a norbornyl group, and most preferably an adamantyl group.

The linear or branched aliphatic hydrocarbon group which may be bonded to the alicyclic hydrocarbon group preferably has 1 to 10 carbon atoms, more preferably has 1 to 6 carbon atoms, still more preferably has 1 to 4 carbon atoms, and particularly preferably has 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group is preferably a branched alkylene group, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

The cyclic hydrocarbon group as R′²⁰¹ may contain a hetero atom such as a heterocyclic ring. Examples thereof include a lactone-containing cyclic groups, an —SO₂—-containing cyclic group, and another heterocyclic group represented by each of Chemical Formulae (r-hr-1) to (r-hr-16) described below.

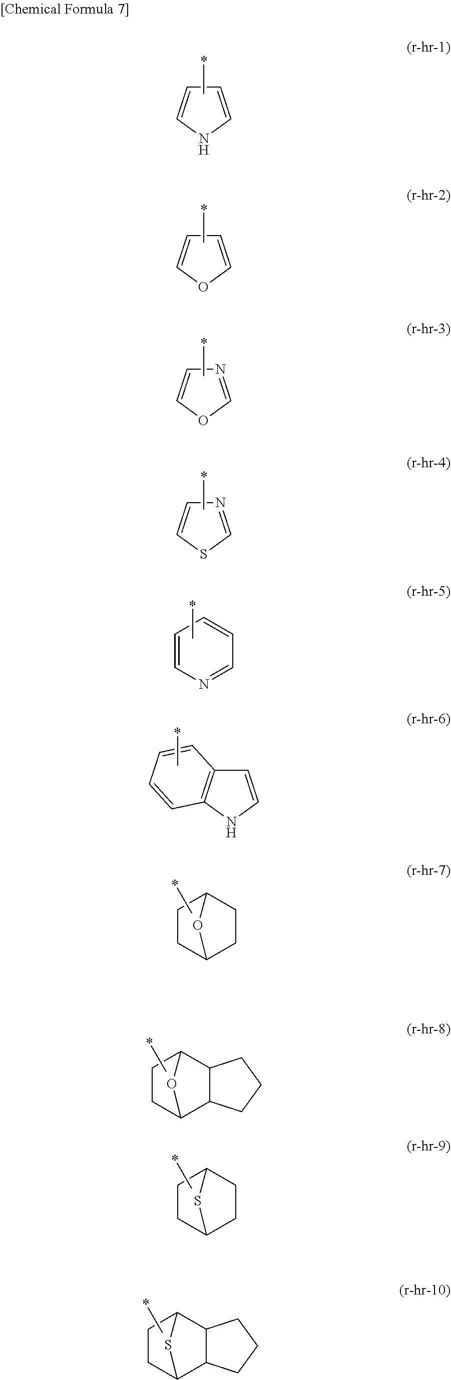

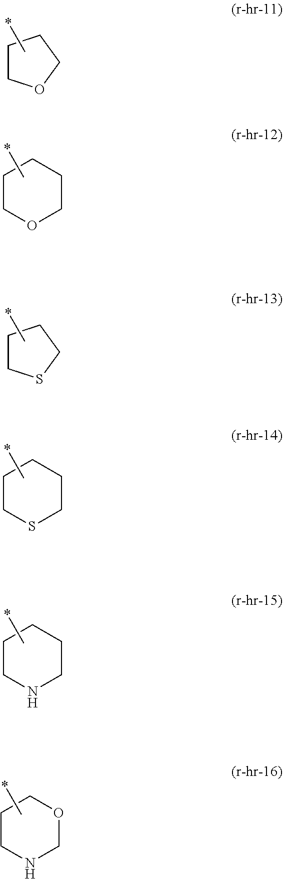

Examples of the substituent of the cyclic group as R′²⁰¹ include an alkyl group, an alkoxy group, a halogen atom, a halogenated alkyl group, a hydroxyl group, a carbonyl group, and a nitro group.

The alkyl group as the substituent is preferably an alkyl group having 1 to 5 carbon atoms, and a methyl group, an ethyl group, a propyl group, an n-butyl group, or a tert-butyl group is most preferable.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and most preferably a methoxy group or an ethoxy group.

The halogen atom as the substituent is preferably a fluorine atom.

Examples of the above-described halogenated alkyl group as the substituent include a group in which part or all of hydrogen atoms in an alkyl group having 1 to 5 carbon atoms such as a methyl group, an ethyl group, a propyl group, an n-butyl group, or a tert-butyl group have been substituted with the above-described halogen atom.

The carbonyl group as the substituent is a group that is substituted for a methylene group (—CH₂—) constituting the cyclic hydrocarbon group.

Chain-like alkyl group which may have substituent:

The chain-like alkyl group as R′²⁰¹ may be linear or branched.

The linear alkyl group preferably has 1 to 20 carbon atoms, more preferably 1 to 15 carbon atoms, and most preferably 1 to 10 carbon atoms.

The branched alkyl group preferably has 3 to 20 carbon atoms, more preferably has 3 to 15 carbon atoms, and most preferably has 3 to 10 carbon atoms. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-like alkenyl group which may have substituent:

Such a chain-like alkenyl group as R′²⁰¹ may be linear or branched, and it preferably has 2 to 10 carbon atoms, more preferably has 2 to 5 carbon atoms, still more preferably has 2 to 4 carbon atoms, and particularly preferably has 3 carbon atoms. Examples of the linear alkenyl group include a vinyl group, a propenyl group (an allyl group), and a butynyl group. Examples of the branched alkenyl group include a 1-methylvinyl group, a 2-methylvinyl group, a 1-methylpropenyl group, and a 2-methylpropenyl group.

Among the above, the chain-like alkenyl group is preferably a linear alkenyl group, more preferably a vinyl group or a propenyl group, and particularly preferably a vinyl group.

Examples of the substituent in the chain-like alkyl group or alkenyl group as R′²⁰¹ include an alkoxy group, a halogen atom, a halogenated alkyl group, a hydroxyl group, a carbonyl group, a nitro group, an amino group, and a cyclic group as R′201

Examples of the cyclic group which may have a substituent, the chain-like alkyl group which may have a substituent, or the chain-like alkenyl group which may have a substituent, as R′²⁰¹, also include in addition to those described above, an acid dissociable group represented by General Formula (a1-r-2) as a cyclic group which may have a substituent or a chain-like alkyl group which may have a substituent.

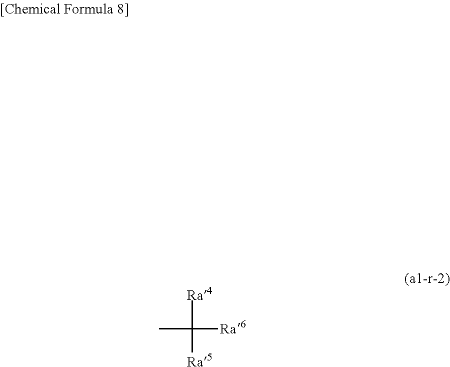

[In the formula, Ra′⁴ to Ra′⁶ each represents a hydrocarbon group, and Ra′⁵ and Ra′⁶ may be bonded to each other to form a ring.]

Examples of the hydrocarbon group as Ra′⁴ include a linear or branched alkyl group, a chain-like or cyclic alkenyl group, a chain-like alkynyl group, and a cyclic hydrocarbon group.

The linear alkyl group as Ra′⁴ has preferably 1 to 5 carbon atoms, more preferably 1 to 4 carbon atoms, and still more preferably 1 or 2 carbon atoms. Specific examples thereof include a methyl group, an ethyl group, an n-propyl group, an n-butyl group, and an n-pentyl group. Among these, a methyl group, an ethyl group, or an n-butyl group is preferable, and a methyl group or an ethyl group is more preferable.

The branched alkyl group as Ra′⁴ has preferably 3 to 10 carbon atoms and more preferably 3 to 5 carbon atoms. Specific examples thereof include an isopropyl group, an isobutyl group, a tert-butyl group, an isopentyl group, a neopentyl group a 1,1-diethylpropyl group, and a 2,2-dimethylbutyl group. Among these, an isopropyl group is preferable.

The chain-like or cyclic alkenyl group as Ra′⁴ is preferably an alkenyl group having 2 to 10 carbon atoms.

In a case where Ra′⁴ represents a cyclic hydrocarbon group, the hydrocarbon group may be an alicyclic hydrocarbon group or an aromatic hydrocarbon group and may be a polycyclic group or a monocyclic group.

The alicyclic hydrocarbon group which is a monocyclic group is preferably a group in which one hydrogen atom has been removed from a monocycloalkane. The monocycloalkane is preferably a monocycloalkane having 3 to 6 carbon atoms, and specific examples thereof include cyclopentane and cyclohexane.

The alicyclic hydrocarbon group which is a polycyclic group is preferably a group in which one hydrogen atom has been removed from a polycycloalkane. The polycycloalkane preferably has 7 to 12 carbon atoms, and specific examples thereof include adamantane, norbornane, isobornane, tricyclodecane, and tetracyclododecane.

In a case where the cyclic hydrocarbon group as Ra′⁴ is an aromatic hydrocarbon group, the aromatic hydrocarbon group is a hydrocarbon group having at least one aromatic ring.

The aromatic ring is not particularly limited as long as it is a cyclic conjugated system having (4n+2) π electrons, and the aromatic ring may be monocyclic or polycyclic. The aromatic ring preferably has 5 to 30 carbon atoms, more preferably has 5 to 20 carbon atoms, still more preferably has 6 to 15 carbon atoms, and particularly preferably has 6 to 12 carbon atoms.

Specific examples of the aromatic ring include aromatic hydrocarbon rings such as benzene, naphthalene, anthracene, and phenanthrene; and an aromatic heterocyclic ring obtained by substituting a part of carbon atoms constituting the above-described aromatic hydrocarbon ring with a hetero atom. Examples of the hetero atom in the aromatic heterocyclic rings include an oxygen atom, a sulfur atom, and a nitrogen atom. Specific examples of the aromatic heterocyclic ring include a pyridine ring and a thiophene ring.

Specific examples of the aromatic hydrocarbon group as Ra′⁴ include a group obtained by removing one hydrogen atom from the above-described aromatic hydrocarbon ring or aromatic heterocyclic ring (an aryl group or a heteroaryl group); a group obtained by removing one hydrogen atom from an aromatic compound having two or more aromatic rings (for example, biphenyl or fluorene); and a group in which one hydrogen atom of the above-described aromatic hydrocarbon ring or aromatic heterocyclic ring has been substituted with an alkylene group (for example, an arylalkyl group such as a benzyl group, a phenethyl group, a 1-naphthylmethyl group, a 2-naphthylmethyl group, a 1-naphthylethyl group, or a 2-naphthylethyl group). The alkylene group bonded to the aromatic hydrocarbon ring or aromatic heterocyclic ring preferably has 1 to 4 carbon atoms, more preferably has 1 or 2 carbon atoms, and particularly preferably has 1 carbon atom.

The chain-like or cyclic alkenyl group as Ra′⁴ is preferably an alkenyl group having 2 to 10 carbon atoms.

Examples of the hydrocarbon group as Ra′⁵ or Ra′⁶ include the same one as Ra′⁴ described above.

Ra′⁵ and Ra′⁶ may be bonded to each other to form a ring.

Among them, R′²⁰¹ is preferably a cyclic group which may have a substituent and is more preferably a cyclic hydrocarbon group which may have a substituent. More specifically, it is, for example, preferably a group obtained by removing one or more hydrogen atoms from a phenyl group, a naphthyl group, or a polycycloalkane; a lactone-containing cyclic group; —SO₂—-containing cyclic group; or the like.

In General Formulae (ca-1) to (ca-3), in a case where R²⁰¹ to R²⁰³ and R²⁰⁶ and R²⁰⁷ are bonded to each other to form a ring with a sulfur atom in the formula, these groups may be bonded to each other via a hetero atom such as a sulfur atom, an oxygen atom, or a nitrogen atom, or a functional group such as a carbonyl group, —SO—, —SO₂—, —SO₃—, —COO—, —CONH—, or —N(R_{N})— (here, R_{N} represents an alkyl group having 1 to 5 carbon atoms). Regarding the ring to be formed, it is preferable that a ring containing the sulfur atom in the formula in the ring skeleton thereof is a 3-membered to 10-membered ring and it is particularly preferable that it is a 5-membered to 7-membered ring, in a case where the sulfur atom is included. Specific examples of the ring to be formed include a thiophene ring, a thiazole ring, a benzothiophene ring, a dibenzothiophene ring, a 9H-thioxanthene ring, a thioxanthone ring, a thianthrene ring, a phenoxathiin ring, a tetrahydrothiophenium ring, and a tetrahydrothiopyranium ring.

R²⁰⁸ and R²⁰⁹ each independently represent a hydrogen atom or an alkyl group having 1 to 5 carbon atoms and are preferably a hydrogen atom or an alkyl group having 1 to 3 carbon atoms. In a case of representing an alkyl group, R²⁰⁸ and R²⁰⁹ may be bonded to each other to form a ring.

R²¹⁰ represents an aryl group which may have a substituent, an alkyl group which may have a substituent, an alkenyl group which may have a substituent, or a —SO₂—-containing cyclic group which may have a substituent.

Examples of the aryl group as R²¹⁰ include an unsubstituted aryl group having 6 to 20 carbon atoms, and a phenyl group or a naphthyl group is preferable.

The alkyl group as R²¹⁰ is preferably a chain-like or cyclic alkyl group which has 1 to 30 carbon atoms.

The alkenyl group as R²¹⁰ preferably has 2 to 10 carbon atoms.

The —SO₂—-containing cyclic group as R²¹⁰ is not particularly limited, and any —SO₂—-containing cyclic group can be used. Specific examples thereof include groups each represented by General Formulae (b5-r-1) to (b5-r-4), where a “—SO₂—-containing polycyclic group” is preferable, and a group represented by General Formula (b5-r-1) is more preferable.

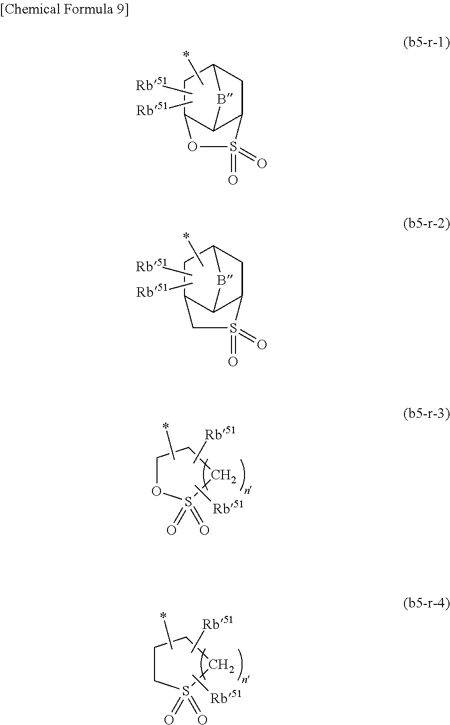

[In the formulae, each Rb′^{S1} independently represents a hydrogen atom, an alkyl group, an alkoxy group, a halogen atom, a halogenated alkyl group, a hydroxyl group, —COOR″, —OC(═O)R″, a hydroxyalkyl group, or a cyano group; R″ represents a hydrogen atom, an alkyl group, a lactone-containing cyclic group, or an —SO₂—-containing cyclic group; B″ represents an oxygen atom, a sulfur atom, or an alkylene group having 1 to 5 carbon atoms, which may contain an oxygen atom or a sulfur atom; and n′ represents an integer in a range of 0 to 2. * represents a bonding site.]

In General Formulae (b5-r-1) and (b5-r-2), B″ represents an alkylene group having 1 to 5 carbon atoms which may contain an oxygen atom or a sulfur atom, an oxygen atom, or a sulfur atom. B″ is preferably an alkylene group having 1 to 5 carbon atoms or —O—, more preferably an alkylene group having 1 to 5 carbon atoms, and still more preferably a methylene group.

In General Formulae (b5-r-1) to (b5-r-4), each Rb′⁵¹ independently represents a hydrogen atom, an alkyl group, an alkoxy group, a halogen atom, a halogenated alkyl group, a hydroxyl group, —COOR″, —OC(═O)R″, a hydroxyalkyl group, or a cyano group, and among the above, each Rb′⁵¹ is independently preferably a hydrogen atom or a cyano group.

Specific examples of the groups each represented by General Formulae (b5-r-1) to (b5-r-4) are shown below. In the formulae shown below, “Ac” represents an acetyl group.

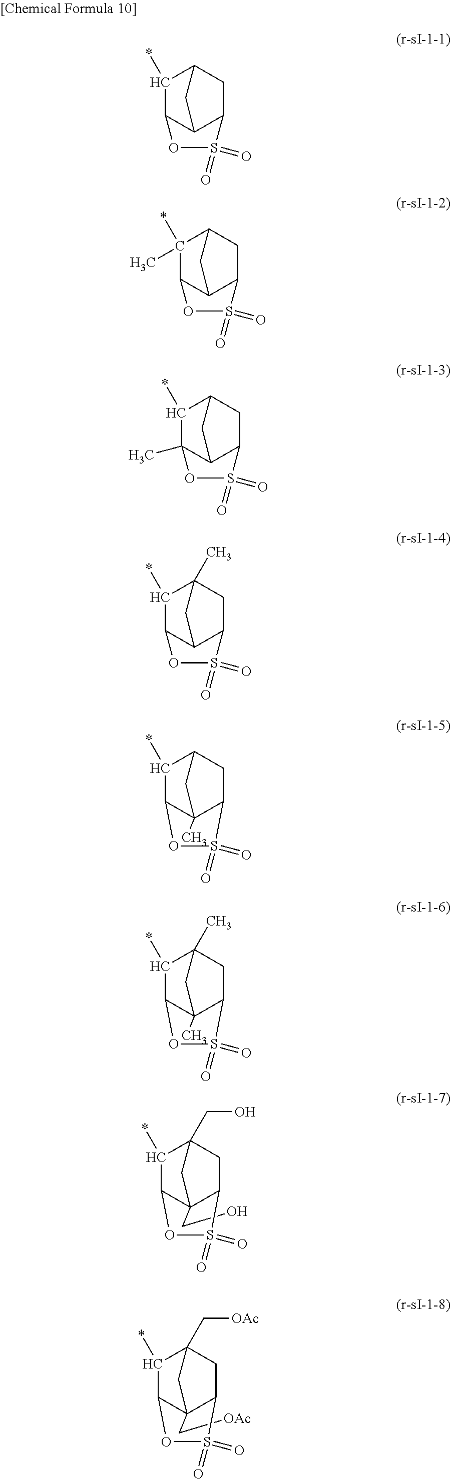

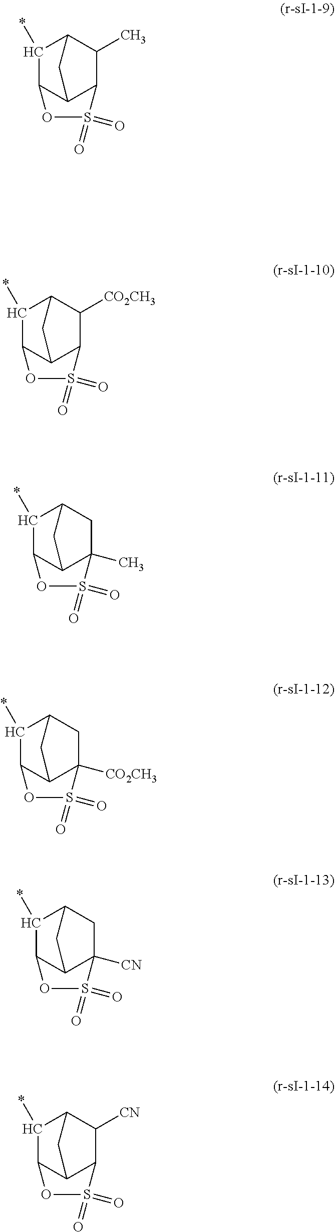

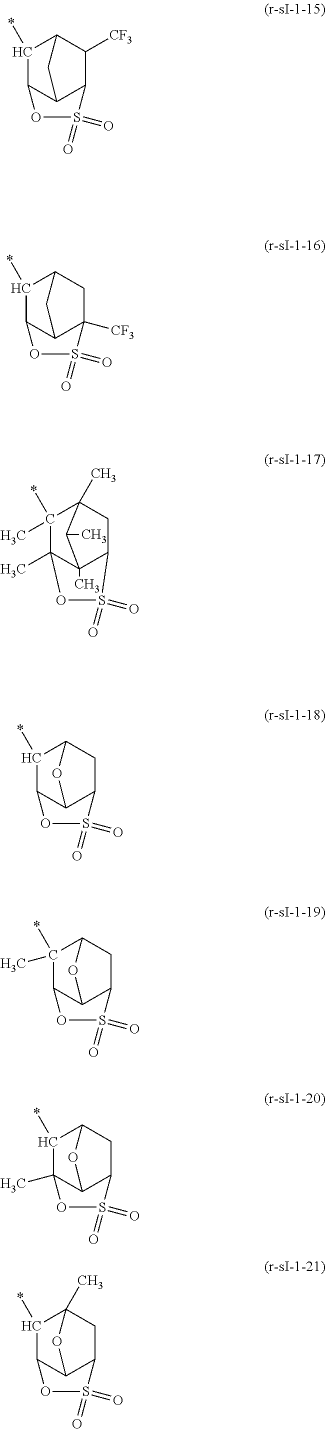

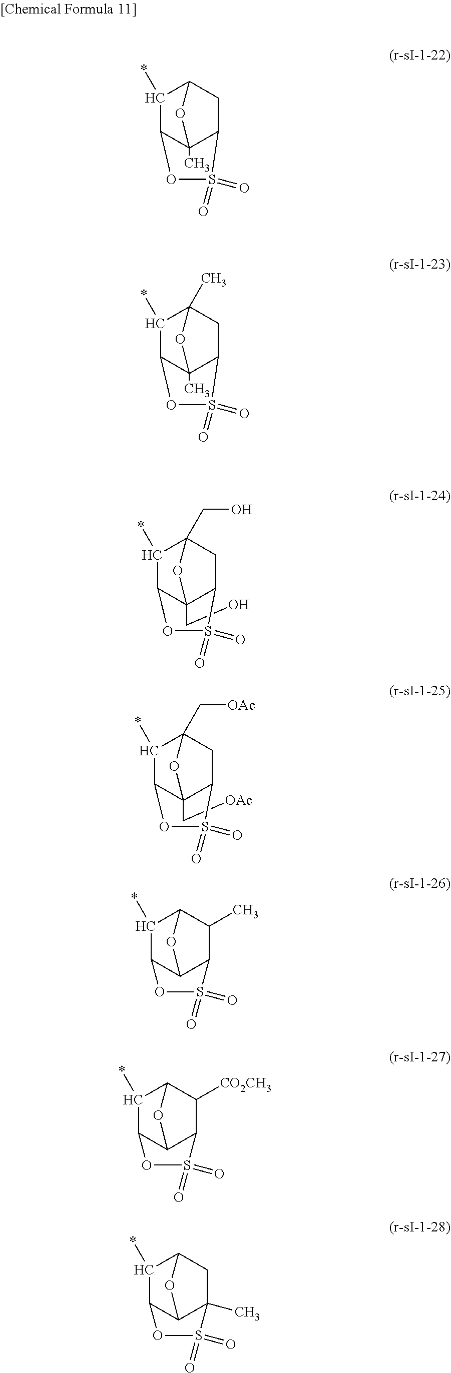

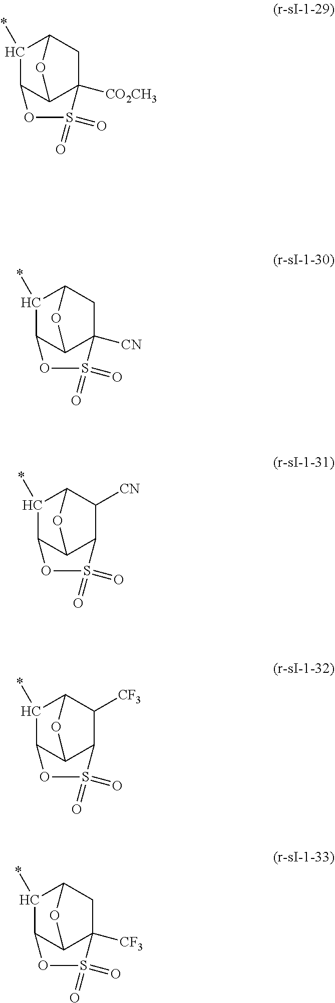

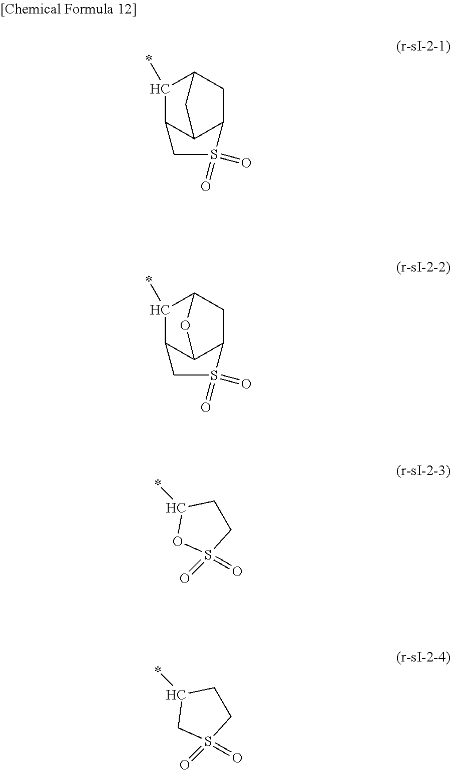

Specific examples of the suitable cation represented by General Formula (ca-1) include cations each represented by the following chemical formulae.

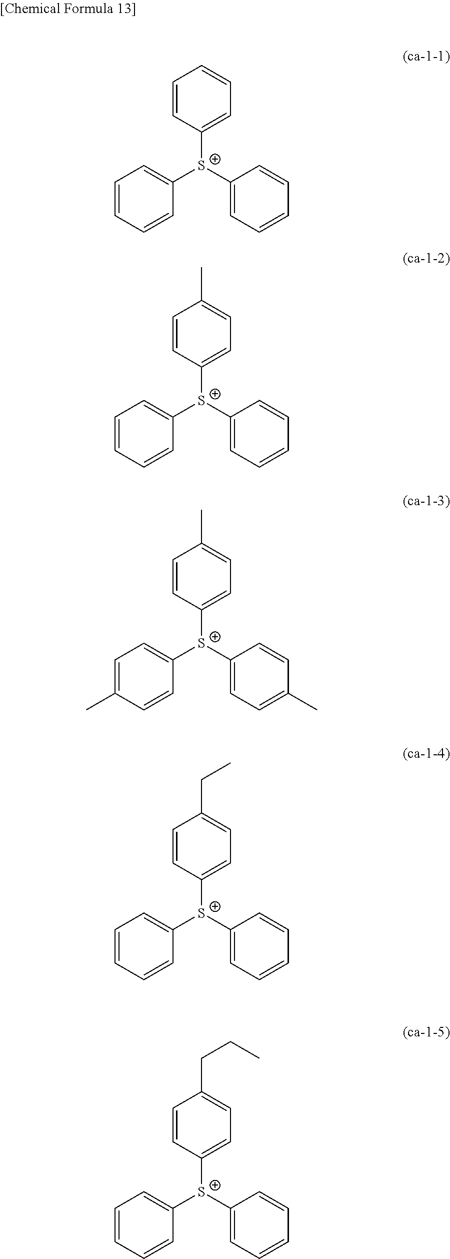

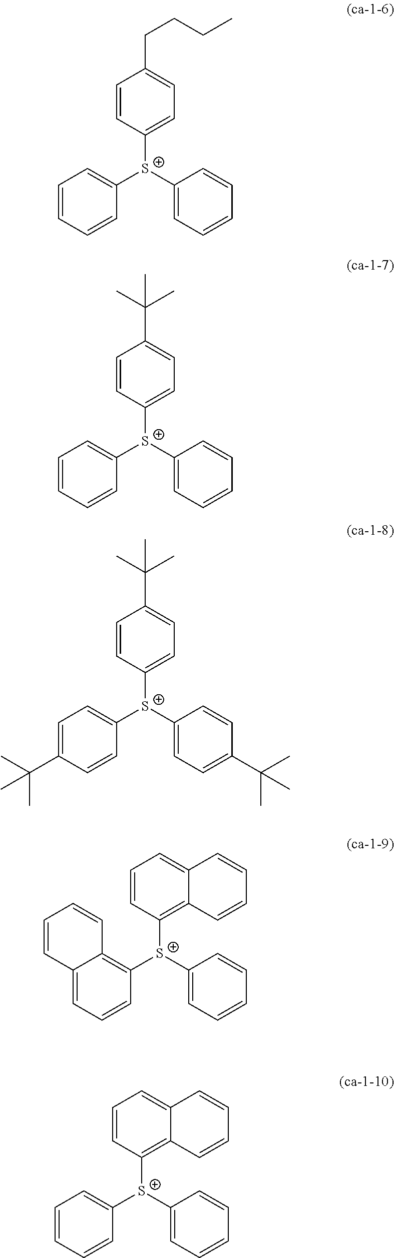

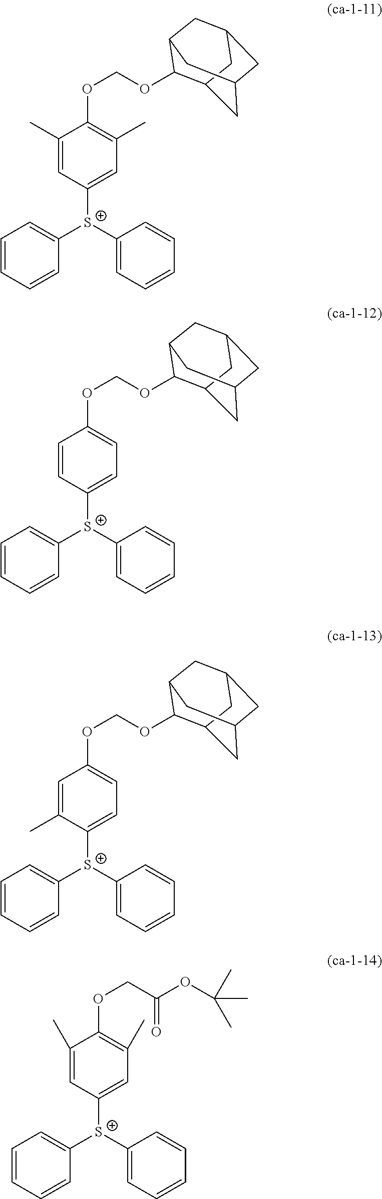

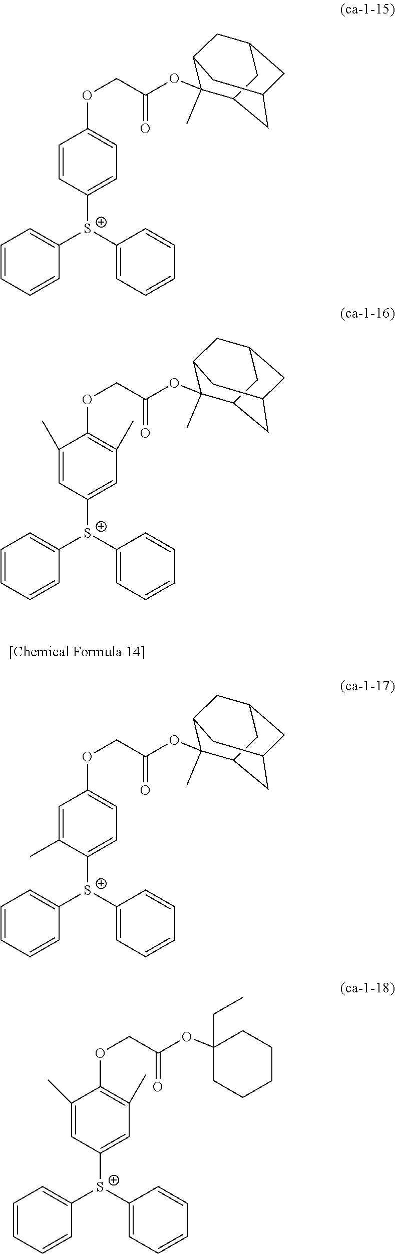

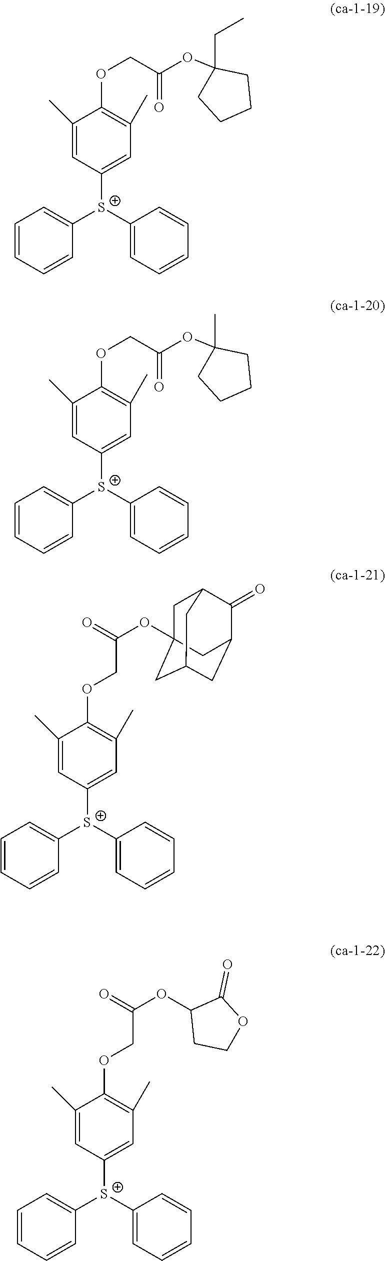

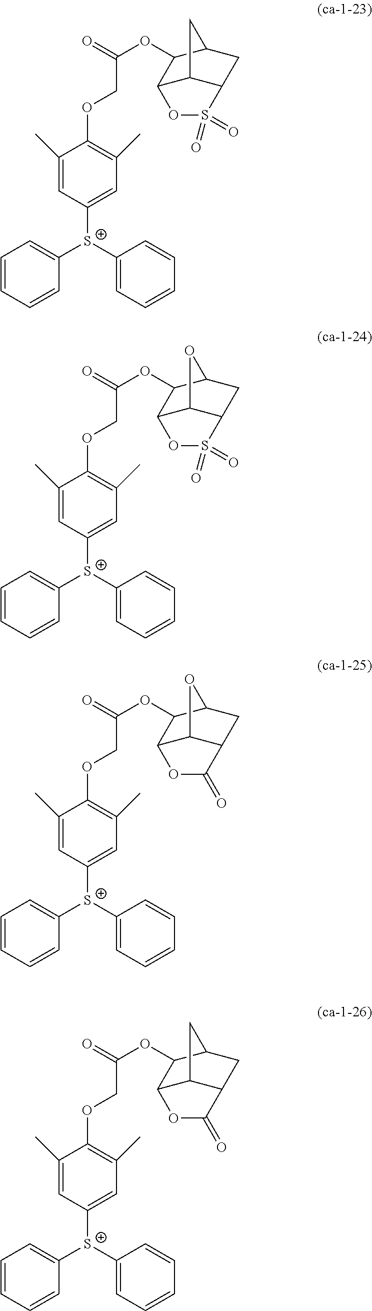

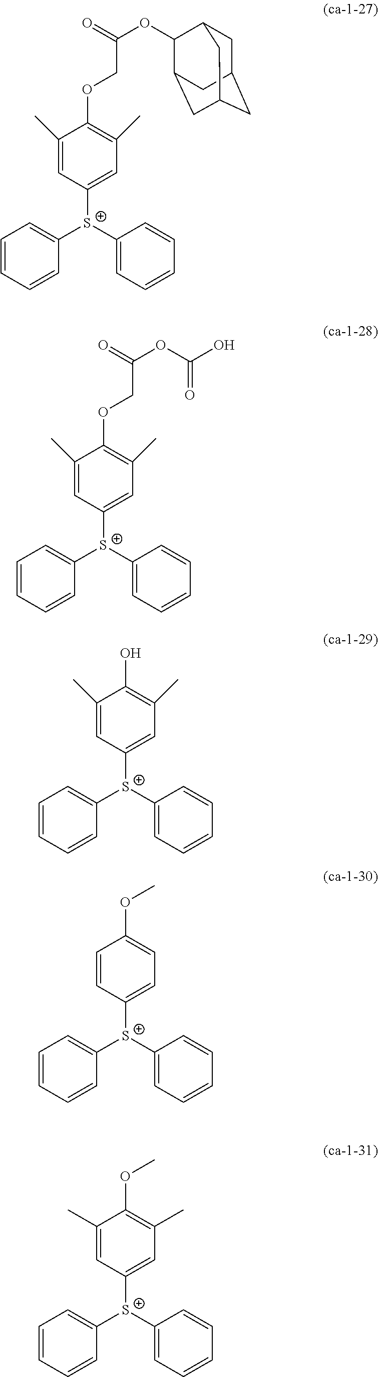

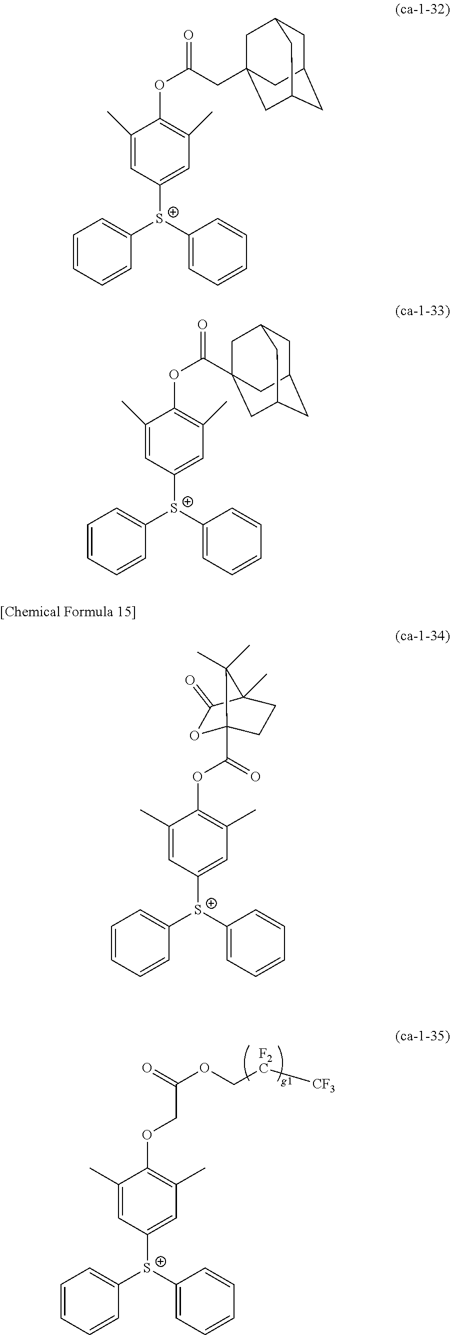

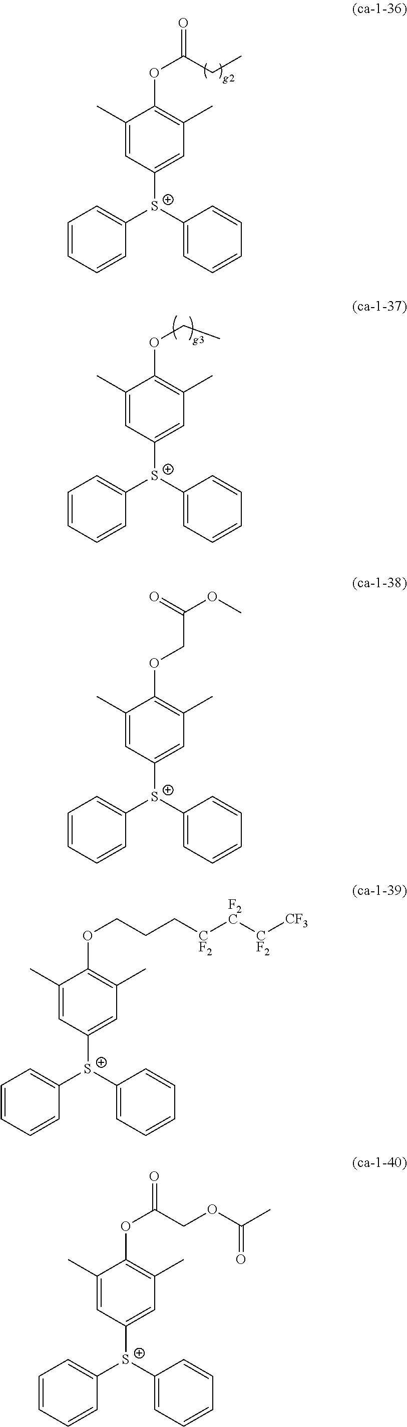

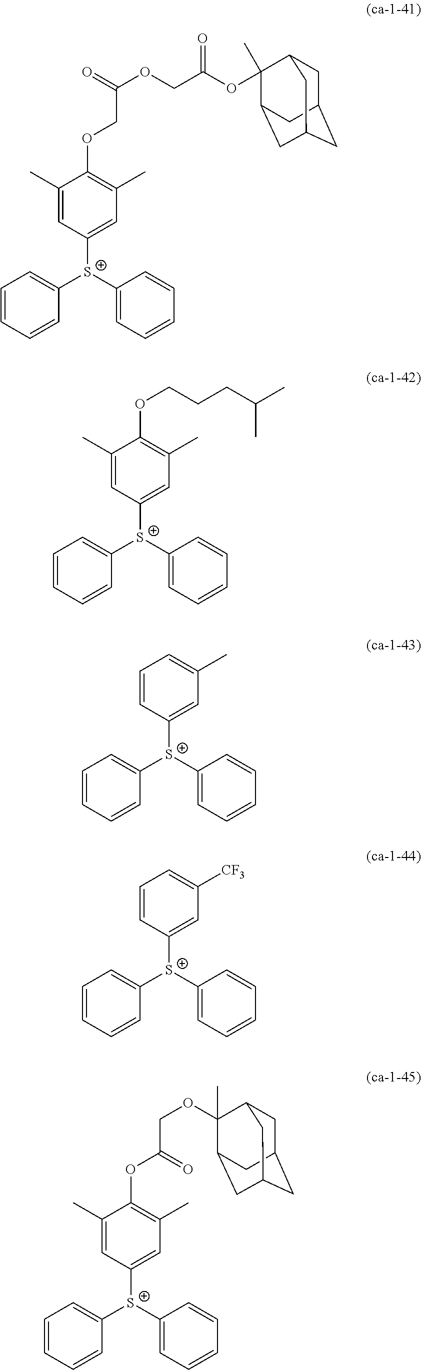

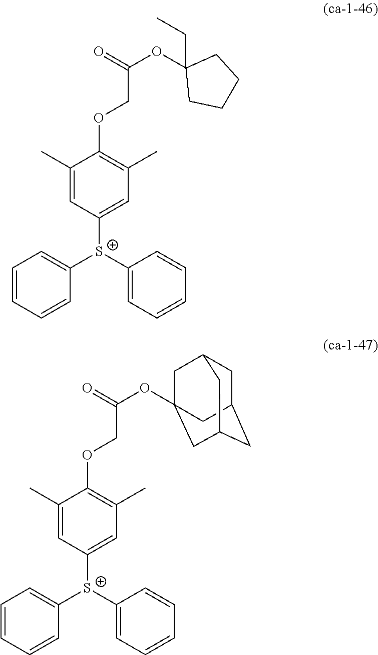

[In the formulae, g1, g2, and g3 represent the numbers of repetitions, g1 is an integer in a range of 1 to 5, g2 is an integer in a range of 0 to 20, and g3 is an integer in a range of 0 to 20.]

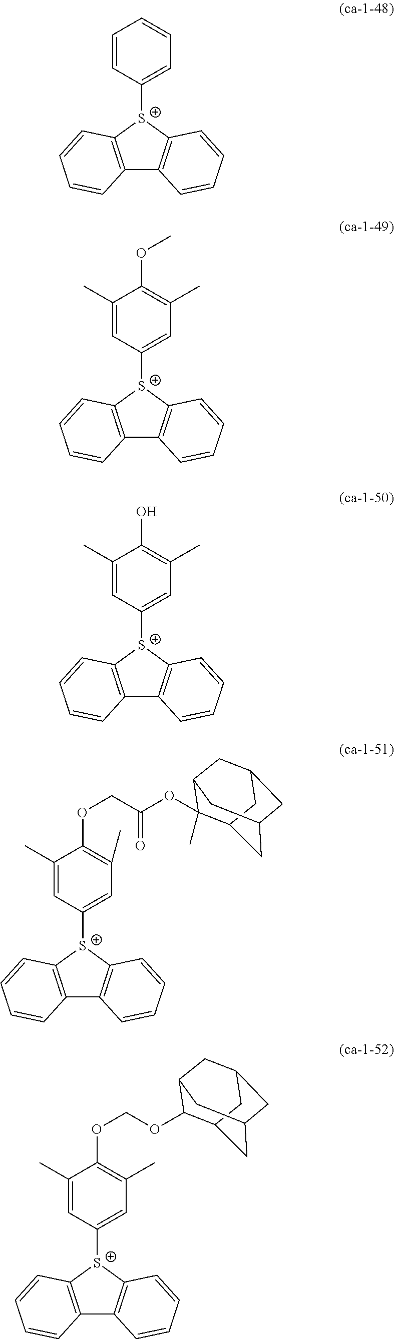 [SMILES: c1ccc(-[s+]2c3ccccc3c3ccccc32)cc1 ; COc1c(C)cc(-[s+]2c3ccccc3c3ccccc32)cc1C ; Cc1cc(-[s+]2c3ccccc3c3ccccc32)cc(C)c1O ; Cc1cc(-[s+]2c3ccccc3c3ccccc32)cc(C)c1OCC(=O)OC1(C)C2CC3CC(C2)CC1C3 ; Cc1cc(-[s+]2c3ccccc3c3ccccc32)cc(C)c1OCOC1C2CC3CC(C2)CC1C3]

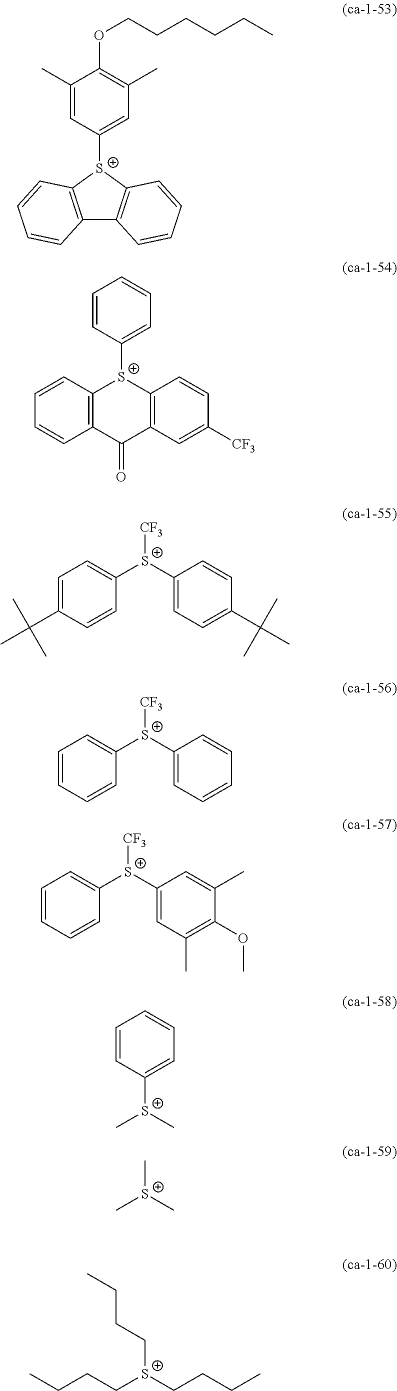

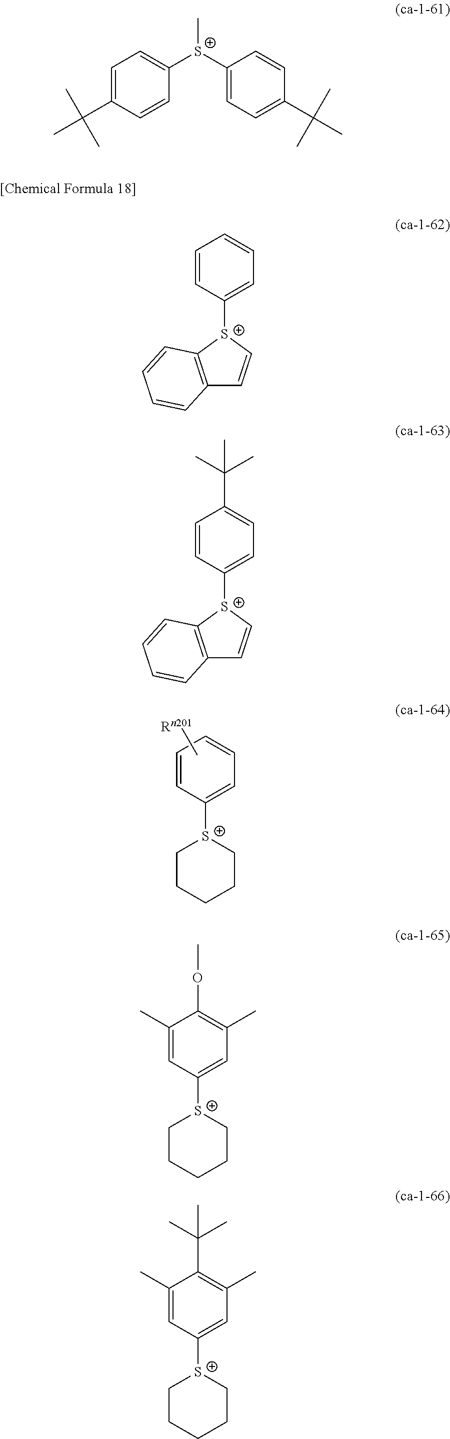

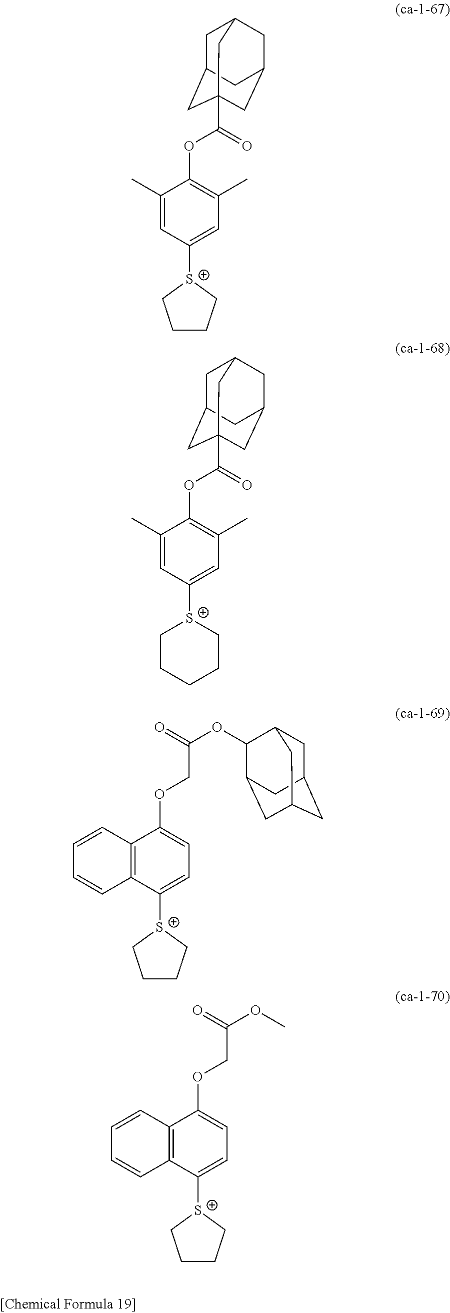 [SMILES: Cc1cc([S+]2CCCC2)cc(C)c1OC(=O)C12CC3CC(CC(C3)C1)C2 ; Cc1cc([S+]2CCCCC2)cc(C)c1OC(=O)C12CC3CC(CC(C3)C1)C2 ; O=C(COc1ccc([S+]2CCCC2)c2ccccc12)OC1C2CC3CC(C2)CC1C3 ; COC(=O)COc1ccc([S+]2CCCC2)c2ccccc12]

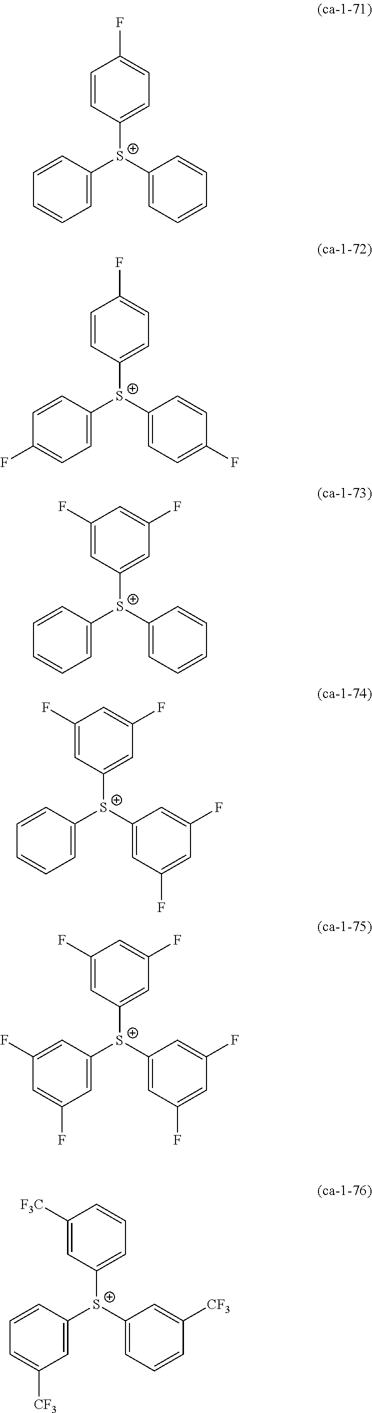 [SMILES: Fc1ccc([S+](c2ccccc2)c2ccccc2)cc1 ; Fc1ccc([S+](c2ccc(F)cc2)c2ccc(F)cc2)cc1 ; Fc1cc(F)cc([S+](c2ccccc2)c2ccccc2)c1 ; Fc1cc(F)cc([S+](c2ccccc2)c2cc(F)cc(F)c2)c1 ; Fc1cc(F)cc([S+](c2cc(F)cc(F)c2)c2cc(F)cc(F)c2)c1 ; FC(F)(F)c1cccc([S+](c2cccc(C(F)(F)F)c2)c2cccc(C(F)(F)F)c2)c1]

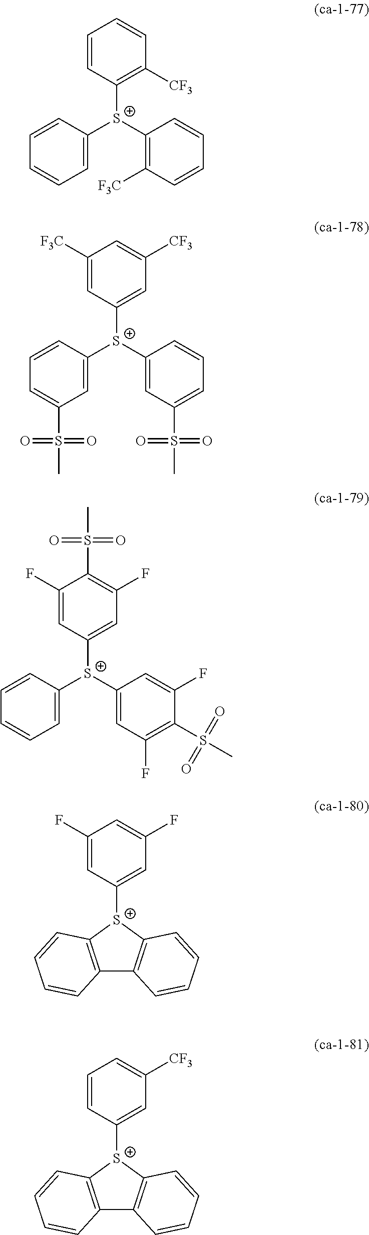 [SMILES: FC(F)(F)c1ccccc1[S+](c1ccccc1)c1ccccc1C(F)(F)F ; CS(=O)(=O)c1cccc([S+](c2cc(C(F)(F)F)cc(C(F)(F)F)c2)c2cccc(S(C)(=O)=O)c2)c1 ; CS(=O)(=O)c1c(F)cc([S+](c2ccccc2)c2cc(F)c(S(C)(=O)=O)c(F)c2)cc1F ; Fc1cc(F)cc(-[s+]2c3ccccc3c3ccccc32)c1 ; FC(F)(F)c1cccc(-[s+]2c3ccccc3c3ccccc32)c1]

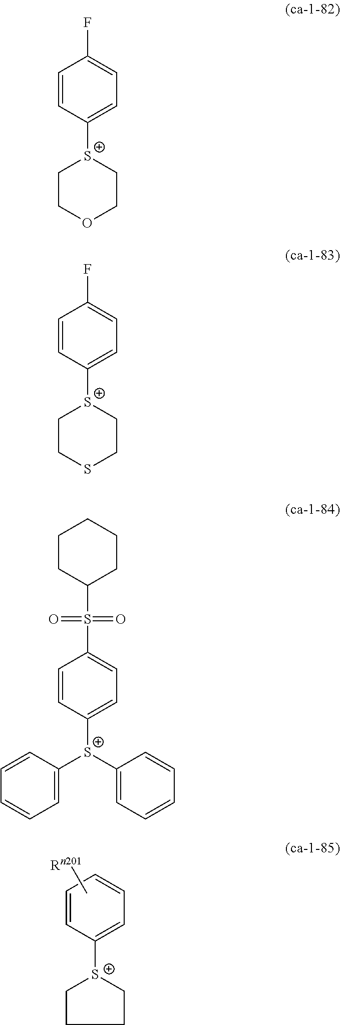

[In the formulae, R″²⁰¹ represents a hydrogen atom or a substituent, and examples of the substituent include the same ones as those exemplified as the substituent which may be contained in R²⁰¹ to R²⁰⁷ and R²¹⁰ to R²¹².]

Specific examples of the suitable cation represented by General Formula (ca-2) include a diphenyliodonium cation and a bis(4-tert-butylphenyl)iodonium cation.

Specific examples of the suitable cation represented by General Formula (ca-3) include cations each represented by General Formulae (ca-3-1) to (ca-3-6).

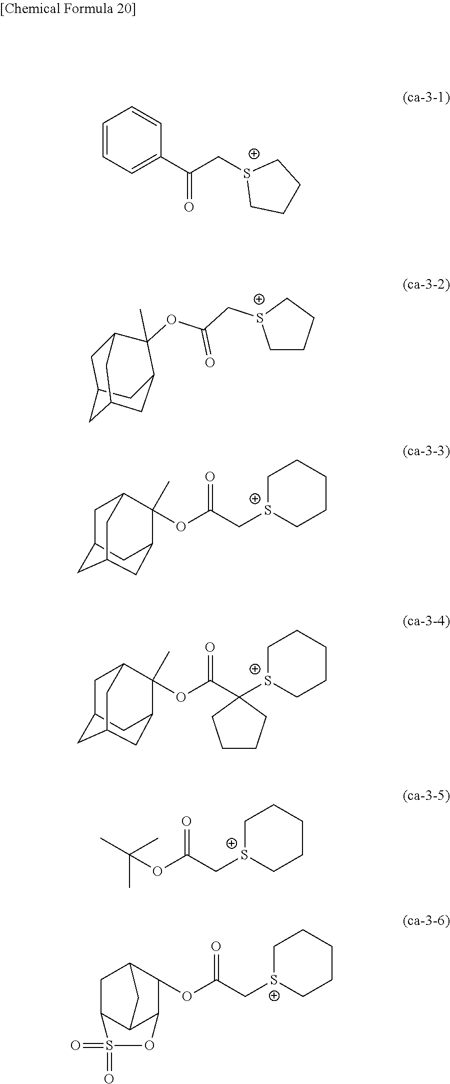

The cation moiety ((Mₘ₊) in the component (A1) is preferably at least one selected from the group consisting of the cations represented by General Formulae (ca-1) to (ca-3) described above, and it is more preferably at least one selected from the group consisting of the cations represented by General Formulae (ca-1) and (ca-2). Suitable examples thereof include the cations each represented by Chemical Formulae (ca-1-1), (ca-1-74), (ca-1-77), (ca-1-48), (ca-1-81), and (ca-1-85) described above; and a diphenyliodonium cation and a bis(4-tert-butylphenyl)iodonium cation.

Alternatively, the cation moiety ((M^{m+})_{1/m}) is preferably at least one selected from the group consisting of cations represented by General Formulae (ca-1) to (ca-3), and it is more preferably at least one selected from the group consisting of cations represented by General Formulae (ca-1) and (ca-2) described above, among which a cation represented by General Formula (ca-1) is still more preferable, and at least one selected from the group consisting of the cations represented by Chemical Formulae (ca-1-1) to (ca-1-85) described above is particularly preferable.

In particular, from the viewpoint of increasing sensitivity, the suitable cation represented by General Formula (ca-1) preferably has, as a substituent, an electron-withdrawing group such as a fluorine atom, a fluorinated alkyl group, or a sulfonyl group and is, for example, particularly preferably a cation selected from the group consisting of cations each represented by Chemical Formulae (ca-1-44) and (ca-1-71) to (ca-1-84).

Alternatively, the cation moiety ((M^{m+})_{1/m}) is preferably an m-valent sulfonium cation having a fluorine atom, from the viewpoint of increasing sensitivity. This cation moiety ((M^{m+})_{1/m}) is preferably a cation represented by General Formula (ca-1-1).

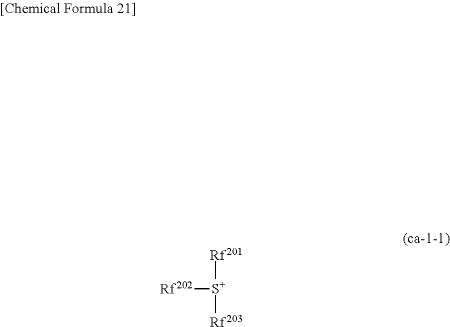

[In the formula, Rf²⁰¹ to Rf²⁰³ each independently represent an aryl group which may have a substituent, an alkyl group which may have a substituent, or an alkenyl group which may have a substituent. Rf²⁰¹ to Rf²⁰³ may be bonded to each other to form a ring together with the sulfur atoms in the formula. However, at least one of Rf²⁰¹ to Rf²⁰³ contains at least one fluorine atom.]

Rf²⁰¹ to Rf²⁰³ in General Formula (ca-1-1) are each the same as R²⁰¹ to R²⁰³ in General Formula (ca-1). However, at least one of Rf²⁰¹ to Rf²⁰³ contains at least one fluorine atom. The cation represented by General Formula (ca-1-1) preferably contains three or more fluorine atoms. Any one of Rf²⁰¹ to Rf²⁰³ may have three or more fluorine atoms, or the total number of fluorine atoms contained in Rf²⁰¹ to Rf²⁰³ may be three or more.

In the resist composition according to the present embodiment, as the component (A1), it is preferable to use a resin that is soluble in an alkali developing solution and contains a crosslinkable group. Such a component (A1) is preferably a resin further containing a phenolic hydroxyl group in addition to the siloxane bond and the ionic group represented by General Formula (I0).

For example, the component (A1) is preferably polysiloxane, and among the above, a silsesquioxane resin is more preferably contained.

### <21 Silsesquioxane Resin>>

The polymer main chain of the silsesquioxane resin in the present embodiment consists of a repeating structure of a Si—O bond, and preferred examples thereof include a polymer having a constitutional unit represented by General Formula (a0-1) described later (hereinafter, this constitutional unit is also referred to as a “constitutional unit (a01)”).

Alternatively, the polymer main chain of the silsesquioxane resin in the present embodiment consists of a repeating structure of a Si—O bond, and preferred examples thereof include a polymer having a constitutional unit represented by General Formula (a0-2) described later (hereinafter, this constitutional unit is also referred to as a “constitutional unit (a02)”).

Alternatively, the polymer main chain of the silsesquioxane resin in the present embodiment consists of a repeating structure of a Si—O bond and contains the ionic group represented by General Formula (I0), and preferred examples thereof include a polymer having a constitutional unit represented by General Formula (a1-1) described later (hereinafter, this constitutional unit is also referred to as a “constitutional unit (a1)”).
In regard to constitutional unit (a01)

The constitutional unit (a01) is a constitutional unit represented by General Formula (a0-1).

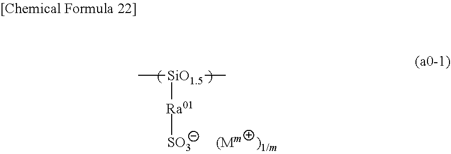

[In the formula, Ra⁰¹ represents a divalent linking group having 1 to 40 carbon atoms. M^{m+} represents a sulfonium cation or an iodonium cation. m represents an integer of 1 or more].

in General Formula (a0-1), The cation moiety ((M^{m+})_{1/m}) is the same as the cation moiety ((M^{m+})_{1/m}) in General Formula (I0) described above.

In Formula (a0-1), examples of the divalent linking group having 1 to 40 carbon atoms, as Ra⁰¹, include those containing a divalent hydrocarbon group which may have a substituent and those containing a divalent linking group containing a hetero atom.
Divalent hydrocarbon group which may have substituent:

The divalent hydrocarbon group which may have a substituent, as Ra⁰¹, may be an aliphatic hydrocarbon group or may be an aromatic hydrocarbon group.
Aliphatic hydrocarbon group

The aliphatic hydrocarbon group indicates a hydrocarbon group that has no aromaticity. The aliphatic hydrocarbon group may be saturated or may be unsaturated (for example, an alkenylene group, an alkynylene group, or the like).

Examples of the aliphatic hydrocarbon group include a chain-like aliphatic hydrocarbon group, and an aliphatic hydrocarbon group containing a ring in the structure thereof. The chain-like aliphatic hydrocarbon group may be a linear aliphatic hydrocarbon group or may be a branched aliphatic hydrocarbon group.
Linear or branched aliphatic hydrocarbon group

The linear aliphatic hydrocarbon group preferably has 1 to 10 carbon atoms, more preferably has 1 to 6 carbon atoms, still more preferably has 1 to 4 carbon atoms, and particularly preferably has 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group described above preferably has 2 to 10 carbon atoms, more preferably has 3 to 6 carbon atoms, still more preferably has 3 or 4 carbon atoms, and particularly preferably has 3 carbon atoms.

The branched aliphatic hydrocarbon group is preferably a branched alkylene group, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

The linear or branched aliphatic hydrocarbon group may have or may not have a substituent. Examples of the substituent in the linear or branched aliphatic hydrocarbon group include an alkoxy group, a halogen atom (preferably a fluorine atom), a halogenated alkyl group, a hydroxyl group, a carbonyl group, a nitro group, and an amino group.
Aliphatic hydrocarbon group containing ring in structure thereof

Examples of the aliphatic hydrocarbon group containing a ring in the structure thereof include a cyclic aliphatic hydrocarbon group which may have a substituent containing a hetero atom in the ring structure thereof (a group obtained by removing two hydrogen atoms from an aliphatic hydrocarbon ring), a group in which the cyclic aliphatic hydrocarbon group is bonded to the terminal of a linear or branched aliphatic hydrocarbon group, and a group in which the cyclic aliphatic hydrocarbon group is interposed in a linear or branched aliphatic hydrocarbon group. Examples of the linear or branched aliphatic hydrocarbon group include the same ones as those described above.

The cyclic aliphatic hydrocarbon group preferably has 3 to 20 carbon atoms and more preferably has 3 to 12 carbon atoms.

The cyclic aliphatic hydrocarbon group may be a polycyclic group or a monocyclic group. The monocyclic alicyclic hydrocarbon group is preferably a group obtained by removing two hydrogen atoms from a monocycloalkane. The monocycloalkane is preferably a monocycloalkane having 3 to 6 carbon atoms, and specific examples thereof include cyclopropane, cyclopentane, and cyclohexane. The polycyclic alicyclic hydrocarbon group is preferably a group obtained by removing two hydrogen atoms from a polycycloalkane, and the polycycloalkane preferably has 7 to 12 carbon atoms. Specific examples of the polycycloalkane include adamantane, norbornane, isobornane, tricyclodecane, and tetracyclododecane.

The cyclic aliphatic hydrocarbon group may have or may not have a substituent. Examples of the substituent include an alkyl group, an alkoxy group, a halogen atom (preferably an iodine atom), a halogenated alkyl group, a hydroxy group, and a carbonyl group.

In the cyclic aliphatic hydrocarbon group, a part of carbon atoms constituting the ring structure thereof may be substituted with a substituent containing a hetero atom. The substituent containing a hetero atom is preferably —O—, —C(═O)—O—, —S—, —S(═O)₂—, or —S(═O)₂—O—.
Aromatic hydrocarbon group

The aromatic hydrocarbon group is a hydrocarbon group having at least one aromatic ring.

The aromatic ring is not particularly limited as long as it is a cyclic conjugated system having (4n+2) π electrons, and the aromatic ring may be monocyclic or polycyclic. The aromatic ring preferably has 5 to 30 carbon atoms, more preferably has 5 to 20 carbon atoms, still more preferably has 6 to 15 carbon atoms, and particularly preferably has 6 to 12 carbon atoms. Here, the number of carbon atoms in a substituent is not included in the number of carbon atoms.

Specific examples of the aromatic ring include aromatic hydrocarbon rings such as benzene, naphthalene, anthracene, and phenanthrene; and an aromatic heterocyclic ring obtained by substituting a part of carbon atoms constituting the above-described aromatic hydrocarbon ring with a hetero atom. Examples of the hetero atom in the aromatic heterocyclic rings include an oxygen atom, a sulfur atom, and a nitrogen atom. Specific examples of the aromatic heterocyclic ring include a pyridine ring and a thiophene ring.

Specific examples of the aromatic hydrocarbon group include a group obtained by removing two hydrogen atoms from the above-described aromatic hydrocarbon ring or aromatic heterocyclic ring (an arylene group or a heteroarylene group); a group obtained by removing two hydrogen atoms from an aromatic compound having two or more aromatic rings (for example, biphenyl or fluorene); and a group in which one hydrogen atom of a group (an aryl group or a heteroaryl group) obtained by removing one hydrogen atom from the above-described aromatic hydrocarbon ring or aromatic heterocyclic ring has been substituted with an alkylene group (for example, a group in which one hydrogen atom further has been removed from an aryl group in arylalkyl groups such as a benzyl group, a phenethyl group, a 1-naphthylmethyl group, a 2-naphthylmethyl group, a 1-naphthylethyl group, or a 2-naphthylethyl group). The alkylene group bonded to the aryl group or the heteroaryl group preferably has 1 to 4 carbon atoms, more preferably has 1 or 2 carbon atoms, and particularly preferably has 1 carbon atom.

In the aromatic hydrocarbon group, the hydrogen atom contained in the aromatic hydrocarbon group may be substituted with a substituent. For example, the hydrogen atom bonded to the aromatic ring in the aromatic hydrocarbon group may be substituted with a substituent. Examples of the substituent include an alkyl group, an alkoxy group, a halogen atom (preferably an iodine atom or a fluorine atom), a halogenated alkyl group, and a hydroxy group.

The alkyl group as the substituent is preferably an alkyl group having 1 to 5 carbon atoms, and a methyl group, an ethyl group, a propyl group, an n-butyl group, or a tert-butyl group is more preferable.

Examples of the alkoxy group, the halogen atom, and the halogenated alkyl group, as the substituent, include those exemplified as the substituent that is substituted for a hydrogen atom contained in the cyclic aliphatic hydrocarbon group.

In addition, the divalent hydrocarbon group which may have a substituent, as Ra⁰¹, may have a condensed ring structure of an aromatic ring with an aromatic ring, may have a condensed ring structure of an aromatic ring with an aliphatic hydrocarbon ring, or may have a condensed ring structure of an aliphatic hydrocarbon ring with an aliphatic hydrocarbon ring.
Divalent linking group containing hetero atom

Examples of the divalent linking group containing a hetero atom, as Ra⁰¹, include —O—, —C(═O)—O—, —O—C(═O)—, —C(═O)—, —O—C(═O)—O—, —C(═O)—NH—, —NH—, —NH—C(═NH)—(H may be substituted with a substituent such as an alkyl group and an acyl group), —S—, —S(═O)₂—, and —S(═O)₂—O—; a group represented by General Formula —Y²¹—O—Y²²—, —Y²¹—O—, —Y²¹—C(═O)—O—, —C(═O)—O—Y²¹, —[Y²¹—C(═O)—O]_{m″}—Y²²—, —Y²¹—O—C(═O)—Y²²—, or —Y²¹—S(═O)₂—O—Y²²— [in the formulae, Y²¹ and Y²² each independently represent a divalent hydrocarbon group which may have a substituent, O represents an oxygen atom, and m″ represents an integer in a range of 0 to 3]; and a group represented by General Formula —O—C(═O)—Y²³—C(═O)—O—, —S—Y²³—C(═O)—O—, or —[O—C(═O)—Y²³]_{n″}—C(═O)—O— [in the formulae, Y²³'s each independently represent a divalent hydrocarbon group which may have a substituent, and n″ represents an integer in a range of 0 to 3]. When the divalent linking group including a hetero atom is —C(═O)—NH—, —C(═O)—NH—C(═O)—, —NH—, or —NH—C(═NH)—, H may be substituted with a substituent such as an alkyl group or an acyl group. The substituent (an alkyl group, an acyl group, or the like) preferably has 1 to 10 carbon atoms, more preferably has 1 to 8 carbon atoms, and particularly preferably has 1 to 5 carbon atoms.

In the general formulae described above, Y²¹, Y²², and Y²³ each independently represent a divalent hydrocarbon group which may have a substituent, and examples thereof include the same ones as those in the description for the divalent hydrocarbon group which may have a substituent as Ra⁰¹.

Y²¹ is preferably a linear aliphatic hydrocarbon group, more preferably a linear alkylene group, still more preferably a linear alkylene group having 1 to 5 carbon atoms, and particularly preferably a methylene group or an ethylene group.

Y²² is preferably a linear or branched aliphatic hydrocarbon group and more preferably a methylene group, an ethylene group, or an alkylmethylene group. The alkyl group in the alkylmethylene group is preferably a linear alkyl group having 1 to 5 carbon atoms, more preferably a linear alkyl group having 1 to 3 carbon atoms, and most preferably a methyl group.

m″ represents an integer in a range of 0 to 3, and it is preferably an integer in a range of 0 to 2, more preferably 0 or 1, and particularly preferably 1.

Y²³ is preferably a linear aliphatic hydrocarbon group or an aromatic hydrocarbon group which may have a substituent, more preferably a linear alkylene group, a linear alkenylene group, or an arylene group or heteroarylene group which may have a substituent, and still more preferably a methylene group, an ethylene group, a vinylene group, or a phenylene group which may have a substituent.

n″ represents an integer in a range of 0 to 3, and it is preferably an integer of 1 or 2 and particularly preferably 1.

In particular, from the viewpoint of synthesis, Ra⁰¹ in General Formula (a0-1) is, among the above, preferably a divalent linking group containing an ester bond, a divalent linking group containing an ether bond (—O—), or a divalent linking group containing a thioether bond (—S—), more preferably a divalent linking group containing an ester bond, and still more preferably a divalent linking group containing an ester bond (—C(═O)—O—, —O—C(═O)—).

Alternatively, from the viewpoint of the strength of the acid generated by being decomposed upon exposure, Ra⁰¹ in General Formula (a0-1) is, among the above, preferably a divalent linking group further containing a fluorine atom, and it is more preferable that a fluorine atom is bonded to the carbon atom adjacent to the S atom in General Formula (a0-1).

Ra⁰¹ is preferably a divalent linking group represented by each of *—C(═O)—O—Ra⁰¹²—**, *—O—C(═O)—Ra⁰¹²—**, *—Ra⁰¹¹—O—O—C(═O)—Ra⁰¹¹—O—**, *—O—Ra⁰¹²—**, *—Ra⁰¹¹—O—C(═O)—Y²³—C(═O)—O—Ra⁰¹²—**, *—Ra⁰¹¹—O—C(═O)—Ra⁰¹²—**, *—Ra⁰¹¹—C(═O)—O—Ra⁰¹²—** and *—Ra⁰⁰¹—S—Y²³—C(═O)—O—Ra⁰¹²—** more preferably a divalent linking group represented by each of *—Ra⁰¹¹—O—C(═O)—Y²³—C(═O)—O—Ra⁰¹²—** and *—Ra⁰¹²—O—C(═O)—Ra⁰¹²—**, and particularly preferably a divalent linking group represented by *—Ra⁰¹¹—O—C(═O)—Y²³—C(═O)—O—Ra⁰¹²—*

Alternatively, Ra⁰¹ is preferably a divalent linking group represented by *—Ra⁰¹¹[O—C(═O)—Y²³]]_{n″}—C(═O)—O—Ra⁰¹²—**

“*” in the formulae described above represents a bonding site to Si in General Formula (a0-1). “**” in the formulae described above represents a bonding site to S in SO₃— in General Formula (a0-1).

In the formulae described above, Ra⁰¹¹'s each independently represent a divalent hydrocarbon group which may have a substituent or a single bond. Examples of the divalent hydrocarbon group which may have a substituent, as Ra⁰¹¹, include the same ones as those in the description for the divalent hydrocarbon group which may have a substituent as Ra⁰¹.

Ra⁰¹²'s each independently represent an alkylene group which may have a fluorine atom or a phenylene group which may have a fluorine atom, and where an alkylene group having a fluorine atom or a phenylene group having a fluorine atom is preferable, and an alkylene group having a fluorine atom is more preferable. The alkylene group as Ra⁰¹² is preferably an alkylene group having 1 to 5 carbon atoms, and it is more preferable that a fluorine atom is bonded to the carbon atom adjacent to the S atom in SO₃—.

Y²³'s each independently represent a divalent hydrocarbon group which may have a substituent. Examples of the divalent hydrocarbon group which may have a substituent, as Y²³, include the same ones as those in the description for the divalent hydrocarbon group which may have a substituent as Ra⁰¹.

n″ represents an integer in a range of 0 to 3, and it is preferably an integer of 1 or 2 and particularly preferably 1.

Hereinafter, preferred specific examples of Ra⁰¹ are shown.

“*” in the chemical formulae represents a bonding site to Si in General Formula (a0-1). “**” in the chemical formulae represents a bonding site to S in SO₃— in General Formula (a0-1).

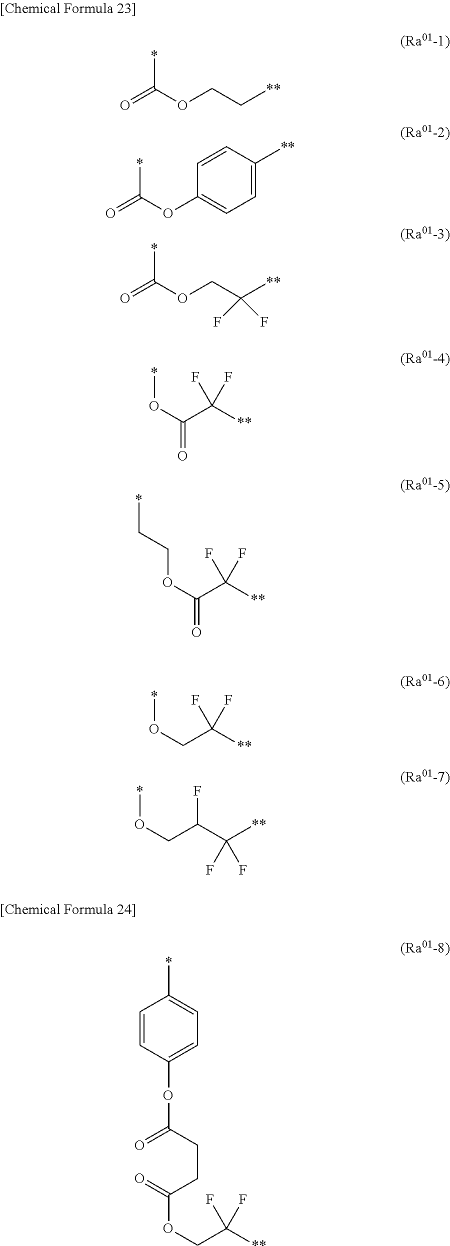

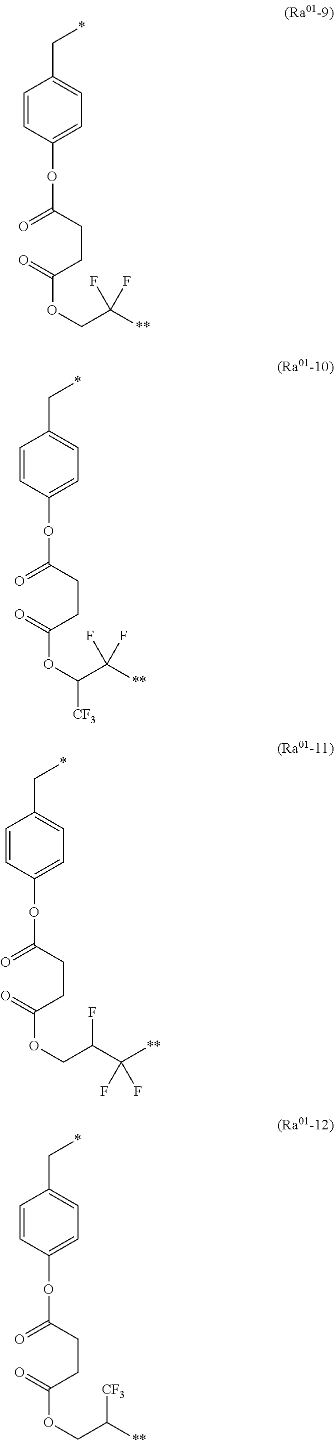

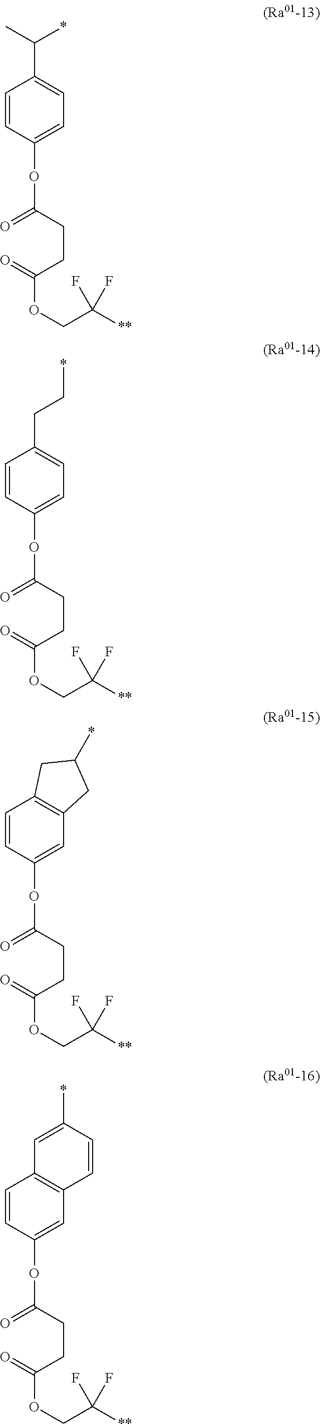

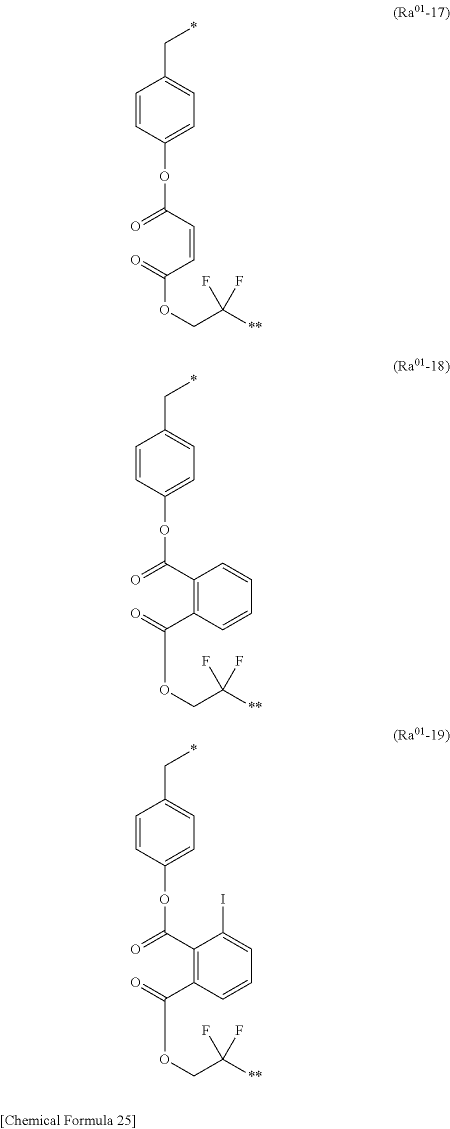

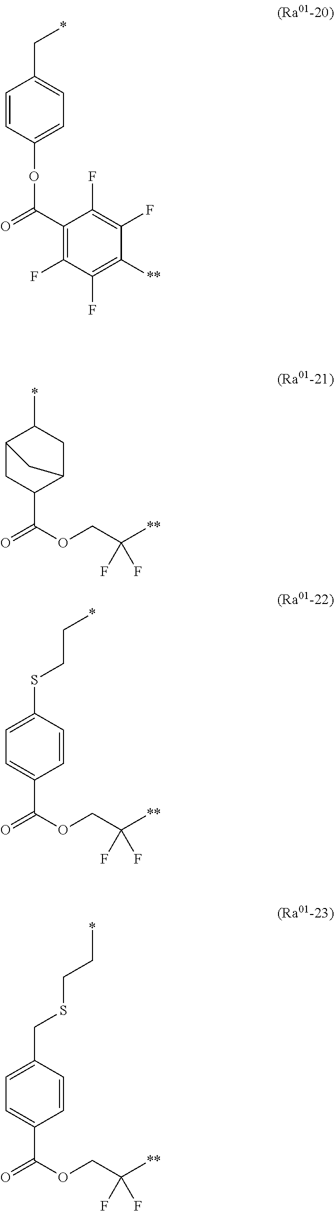

Ra⁰¹ is preferably a divalent linking group selected from the group consisting of the linking groups each represented by Chemical Formulae (Ra⁰¹-1) to (Ra⁰¹-23). Among these, a divalent linking group selected from the group consisting of the linking groups each represented by Chemical Formulae (Ra⁰¹-9), (Ra⁰¹-18), (Ra⁰¹-19), and (Ra⁰¹-20) is more preferable.

Preferred specific examples of the constitutional unit (the constitutional unit (a01)) represented by General Formula (a0-1) are shown below. The cation moiety ((M^{m+})_{1/m}) is the same as the cation moiety ((M^{m+})_{1/m}) in General Formula (I0) described above.

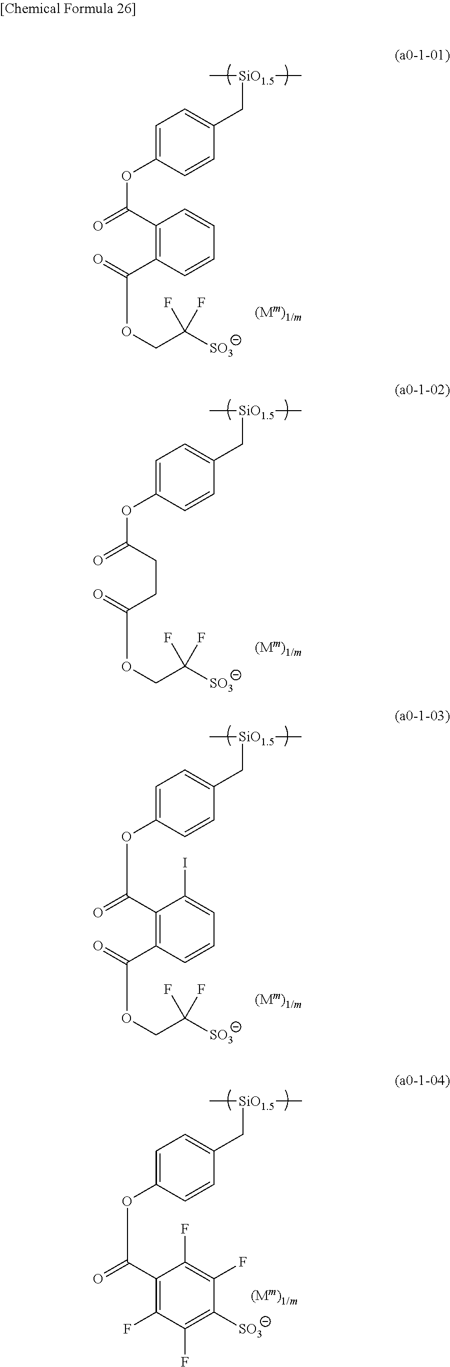

The constitutional unit (a01) is preferably a constitutional unit selected from the group consisting of the constitutional units each represented by Chemical Formulae (a0-1-01) to (a0-1-04), and it is more preferably a constitutional unit selected from the group consisting of the constitutional units each represented by Chemical Formulae (a0-1-01) to (a0-1-03).

In a case where the silsesquioxane resin in the present embodiment has the constitutional unit (a01), the constitutional unit (a01) may be one kind or may be two or more kinds.

The proportion of the constitutional unit (a01) in the silsesquioxane resin in the present embodiment is, for example, 1% by mole or more and 50% by mole or less, and it is preferably 1% by mole or more and less than 50% by mole, more preferably 1% by mole or more and 40% by mole or less, still more preferably 2% by mole or more and 30% by mole or less, and particularly preferably 5% by mole or more and 20% by mole or less, with respect to the total amount (100% by mole) of all constitutional units that constitute the silsesquioxane resin.

In a case where the proportion of the constitutional unit (a01) is equal to or larger than the lower limit value of the above-described preferred range, the effect of reducing pattern roughness is likely to be enhanced. On the other hand, in a case where it is equal to or smaller than the upper limit value of the above-described preferred range, the balance with other constitutional units can be obtained, and thus the crosslinking properties, the solubility in a developing solution, and the like can be easily controlled.
In regard to constitutional unit (a02):

The constitutional unit (a02) is a constitutional unit represented by General Formula (a0-2).

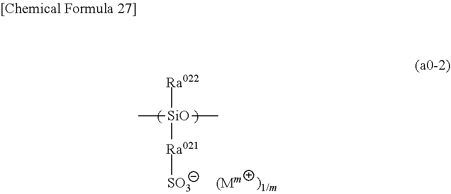

[In the formula, Ra⁰²¹ represents a divalent linking group having 1 to 40 carbon atoms. Ra⁰²² represents a hydrocarbon group which may have a substituent. M^{m+} represents a sulfonium cation or an iodonium cation. m represents an integer of 1 or more].

in General Formula (a0-2), The cation moiety ((M^{m+})_{1/m}) is the same as the cation moiety ((M^{m+})_{1/m}) in General Formula (I0) described above.

in General Formula (a0-2), the divalent linking group having 1 to 40 carbon atoms, as Ra⁰²¹, is the same as the divalent linking group having 1 to 40 carbon atoms, as Ra⁰¹ in General Formula (a0-1) described above.

In Formula (a0-2), Examples of the hydrocarbon group which may have a substituent, as Ra⁰²², include a chain-like aliphatic hydrocarbon group which may have a substituent, a cyclic group which may have a substituent, and a group obtained by combining these.

The chain-like aliphatic hydrocarbon group as Ra⁰²² may be a chain-like saturated aliphatic hydrocarbon group or may be a chain-like unsaturated aliphatic hydrocarbon group; where the chain-like aliphatic hydrocarbon group may be linear or may be branched. The chain-like aliphatic hydrocarbon group has 1 to 10 carbon atoms and preferably has 1 to 6 carbon atoms, among which a methyl group, an ethyl group, a propyl group, or an isopropyl group is more preferable, a methyl group or an ethyl group is still more preferable, and a methyl group is particularly preferable.

The cyclic group as Ra⁰²² is preferably a cyclic hydrocarbon group, and the cyclic hydrocarbon group may be an aromatic hydrocarbon group or may be a cyclic aliphatic hydrocarbon group. In addition, the aliphatic hydrocarbon group may be saturated or may be unsaturated.

The aromatic hydrocarbon group referred to here is a hydrocarbon group having an aromatic ring. Specific examples of the aromatic ring contained in the aromatic hydrocarbon group include benzene, fluorene, naphthalene, anthracene, phenanthrene, biphenyl, and an aromatic heterocyclic ring obtained by substituting part of carbon atoms constituting one of these aromatic rings with a hetero atom. Examples of the hetero atom in the aromatic heterocyclic rings include an oxygen atom, a sulfur atom, and a nitrogen atom.

Specific examples of the aromatic hydrocarbon group include a group (an aryl group such as a phenyl group or a naphthyl group) obtained by removing one hydrogen atom from the above-described aromatic ring and a group (an arylalkyl group such as a benzyl group, a phenethyl group, a 1-naphthylmethyl group, a 2-naphthylmethyl group, 1-naphthylethyl group, or a 2-naphthylethyl group) obtained by substituting one hydrogen atom in the aromatic ring with an alkylene group. The alkylene group (an alkyl chain in the arylalkyl group) preferably has 1 to 4 carbon atoms, more preferably has 1 or 2 carbon atoms, and particularly preferably has 1 carbon atom.

Examples of the cyclic aliphatic hydrocarbon group referred to here include aliphatic hydrocarbon groups containing a ring in the structure thereof. Examples of the aliphatic hydrocarbon group containing a ring in the structure thereof include an alicyclic hydrocarbon group (a group obtained by removing one hydrogen atom from an aliphatic hydrocarbon ring), a group in which the alicyclic hydrocarbon group is bonded to the terminal of a linear or branched aliphatic hydrocarbon group, and a group in which the alicyclic hydrocarbon group is interposed in a linear or branched aliphatic hydrocarbon group.

The alicyclic hydrocarbon group preferably has 3 to 20 carbon atoms and more preferably has 3 to 12 carbon atoms.

The alicyclic hydrocarbon group may be a polycyclic group or a monocyclic group. The monocyclic alicyclic hydrocarbon group is preferably a group obtained by removing one or more hydrogen atoms from a monocycloalkane. The monocycloalkane preferably has 3 to 8 carbon atoms, and specific examples thereof include cyclopentane and cyclohexane. The polycyclic alicyclic hydrocarbon group is preferably a group obtained by removing one or more hydrogen atoms from a polycycloalkane, and the polycycloalkane preferably has 7 to 30 carbon atoms.

The substituent which may be contained in the hydrocarbon group as Ra⁰²² may be monovalent or divalent.

Examples of the monovalent substituent include an alkyl group, a carboxy group, a hydroxy group, an amino group, a sulfo group, a halogen atom, a halogenated alkyl group, an alkoxy group, an alkyloxycarbonyl group, and a nitro group. Examples of the divalent substituent include —O—, —C(═O)—O—, —C(═O)—, —O—C(═O)—O—, —C(═O)—NH—, —NH—, ═N—, —NH—C(═NH)—, —S—, —S(═O)₂—, and —S(═O)₂—O—. It is noted that H of NH in the divalent substituent may be substituted with an alkyl group or an acyl group.

Ra⁰²² is preferably a chain-like aliphatic hydrocarbon group which may have a substituent or an aromatic hydrocarbon group which may have a substituent. Among the above, it is more preferably a linear saturated aliphatic hydrocarbon group or an aryl group, still more preferably an alkyl group having 1 to 6 carbon atoms, a phenyl group, or a naphthyl group, and particularly preferably a methyl group or a phenyl group.

Preferred specific examples of the constitutional unit represented by General Formula (a0-2) are shown below.

The cation moiety ((M^{m+})_{1/m}) is the same as the cation moiety ((M^{m+})_{1/m}) in General Formula (I0) described above. Ra⁰²¹ is the same as the divalent linking group having 1 to 40 carbon atoms, as Ra⁰¹ in General Formula (a0-1) described above.

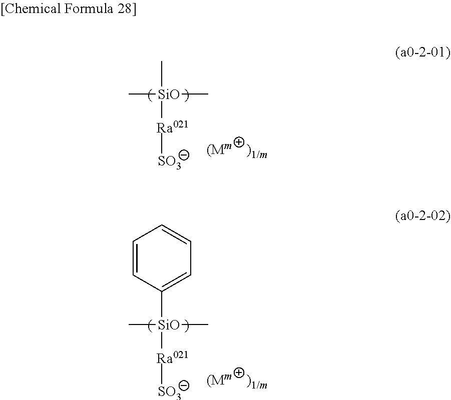

In a case where the silsesquioxane resin in the present embodiment has the constitutional unit (a02), the constitutional unit (a02) may be one kind or may be two or more kinds.

The proportion of the constitutional unit (a02) in the silsesquioxane resin in the present embodiment is, for example, 1% by mole or more and 50% by mole or less, and it is preferably 1% by mole or more and less than 50% by mole, more preferably 1% by mole or more and 40% by mole or less, still more preferably 2% by mole or more and 30% by mole or less, and particularly preferably 5% by mole or more and 20% by mole or less, with respect to the total amount (100% by mole) of all constitutional units that constitute the silsesquioxane resin.

In a case where the proportion of the constitutional unit (a02) is equal to or larger than the lower limit value of the above-described preferred range, the etching resistance is likely to be enhanced in addition to the effect of reducing the pattern roughness. On the other hand, in a case where it is equal to or smaller than the upper limit value of the above-described preferred range, the balance with other constitutional units can be obtained, and thus the characteristics of the resist film to be formed, such as the solubility in a developing solution, can be easily controlled.
In regard to constitutional unit (a1)

The constitutional unit (a1) is a constitutional unit represented by General Formula (a1-1).

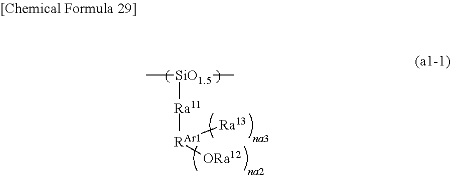

[In the formula, Ra¹¹ represents a divalent linking group or a single bond. R^{Ar1} represents an aromatic hydrocarbon group. Ra¹² represents a hydrocarbon group having 1 to 6 carbon atoms or a hydrogen atom. Ra¹³ represents a hydrocarbon group having 1 to 6 carbon atoms. na2 is 1 or 2. na3 represents an integer in a range of 0 to 4.]

In General Formula (a1-1), the aromatic hydrocarbon group as R^{Ar1} is a hydrocarbon group having at least one aromatic ring. The aromatic ring is not particularly limited as long as it is a cyclic conjugated system having (4n+2) π electrons, and the aromatic ring may be monocyclic or polycyclic. The aromatic ring preferably has 5 to 30 carbon atoms, more preferably has 5 to 20 carbon atoms, still more preferably has 6 to 15 carbon atoms, and particularly preferably has 6 to 12 carbon atoms. Here, the number of carbon atoms in a substituent is not included in the number of carbon atoms.

Specific examples of the aromatic ring include benzene, naphthalene, anthracene, and phenanthrene, where benzene or naphthalene is preferable, and benzene is more preferable.

In the aromatic hydrocarbon group as R^{Ar1}, the hydrogen atom bonded to the aromatic ring may be substituted with a substituent. Examples of the substituent include a halogen atom, a halogenated alkyl group, and a hydroxyl group. The halogen atom as the substituent is preferably a fluorine atom. Examples of the halogenated alkyl group as the substituent include a group obtained by substituting part or all of hydrogen atoms in the above-described alkyl group having 1 to 5 carbon atoms with a halogen atom.

in General Formula (a1-1), examples of the divalent linking group as Ra¹¹ include a divalent hydrocarbon group which may have a substituent, and the divalent linking group is the same as those in the description for the divalent hydrocarbon group which may have a substituent, as Ra⁰¹ in General Formula (a0-1).

Among them, Ra¹¹ is preferably a linear or branched aliphatic hydrocarbon group or a single bond, and more preferably a linear or branched aliphatic hydrocarbon group. The linear or branched aliphatic hydrocarbon group is preferably an alkylene group having 1 to 6 carbon atoms, more preferably an alkylene group having 1 to 5 carbon atoms, still more preferably a methylene group (—CH₂—), an ethylene group (—CH₂—CH₂—), —CH(CH₃)—, a propylene group, or an isopropylene group, particularly preferably —CH₂—, —CH₂—CH₂—, or —CH(CH₃)—, and most preferably —CH₂—.

In General Formula (a1-1), the hydrocarbon group as Ra¹² may be linear, branched, or cyclic, and it is preferably linear or branched. The hydrocarbon group as Ra¹² may be a saturated hydrocarbon group or may be an unsaturated hydrocarbon group, and it is preferably a saturated hydrocarbon group.

The hydrocarbon group as Ra¹² has 1 to 6 carbon atoms and preferably has 1 to 5 carbon atoms, among which a methyl group, an ethyl group, a propyl group, or an isopropyl group is more preferable, a methyl group or an ethyl group is still more preferable, and a methyl group is particularly preferable.

Among the above, Ra¹² is preferably a hydrogen atom, that is, —ORa¹² is preferably a phenolic hydroxyl group.

In General Formula (a1-1), Ra¹³ represents a hydrocarbon group having 1 to 6 carbon atoms, and examples thereof include the same one as the hydrocarbon group as Ra¹²

In General Formula (a1-1), na2 is preferably 1.

In General Formula (a1-1), na3 is preferably an integer in a range of 0 to 3, more preferably 0 or 1, and particularly preferably 0.

Specific examples of the constitutional unit represented by General Formula (a1-1) are shown below.

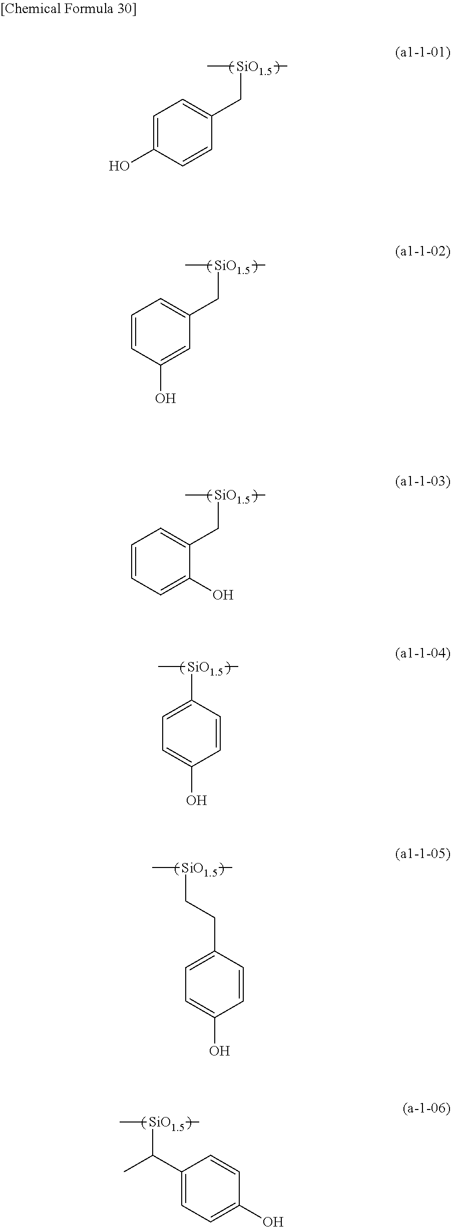

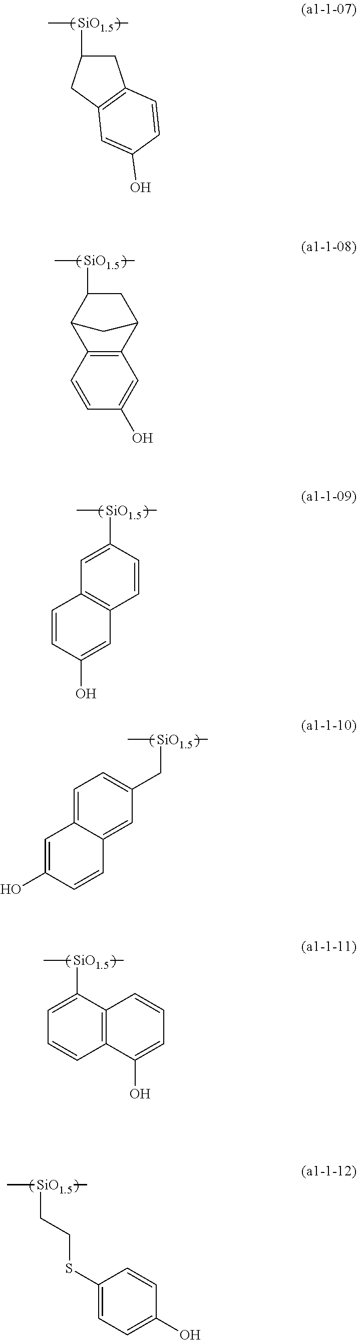

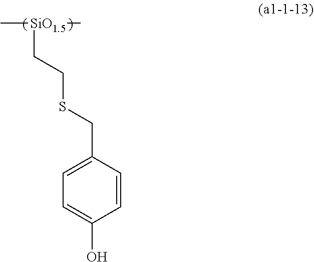

In a case where the silsesquioxane resin in the present embodiment has the constitutional unit (a1), the constitutional unit (a1) may be one kind or may be two or more kinds.

The proportion of the constitutional unit (a1) in the silsesquioxane resin in the present embodiment is, for example, 50% by mole or more, and it is preferably more than 50% by mole, more preferably 60% by mole or more and 99% by mole or less, still more preferably 70% by mole or more and 98% by mole or less, and particularly preferably 80% by mole or more and 95% by mole or less, with respect to the total amount (100% by mole) of all constitutional units that constitute the silsesquioxane resin.

In a case where the proportion of the constitutional unit (a1) is equal to or larger than the lower limit value of the above-described preferred range, crosslinking due to exposure is likely to be promoted during pattern formation. On the other hand, in a case where it is equal to or smaller than the upper limit value of the above-described preferred range, the balance with other constitutional units can be obtained, and thus the characteristics of the resist film to be formed can be easily controlled.
Other constitutional units

The silsesquioxane resin that is preferable as the component (A1) may have other constitutional units other than the constitutional unit (a01), the constitutional unit (a02), and the constitutional unit (a1), which are described above.

Examples of the other constitutional units include a constitutional unit (a21), a constitutional unit (a22), and a constitutional unit (a3), which are described below.
Constitutional unit (a21)

The constitutional unit (a21) is a constitutional unit represented by General Formula (a2-1). In a case where the constitutional unit (a21) is contained, it is possible to easily control the characteristics of a resist film that is formed by using the resist composition.

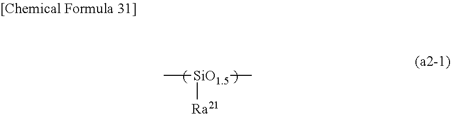

[In the formula, Ra²¹ is a hydrocarbon group which may have a substituent or a hydrogen atom.]

In General Formula (a2-1), the hydrocarbon group which may have a substituent, as Ra²¹, is the same as the hydrocarbon group which may have a substituent, as Ra⁰²² in General Formula (a0-2) described above. Ra²¹ is preferably a chain-like aliphatic hydrocarbon group which may have a substituent or an aromatic hydrocarbon group which may have a substituent.

In the chain-like aliphatic hydrocarbon group which may have a substituent, the aliphatic hydrocarbon group may be a saturated aliphatic hydrocarbon group or may be an unsaturated aliphatic hydrocarbon group. The substituent which may be contained in the chain-like aliphatic hydrocarbon group is preferably an iodine atom.

Preferred specific examples of the constitutional unit represented by General Formula (a2-1) are shown below.

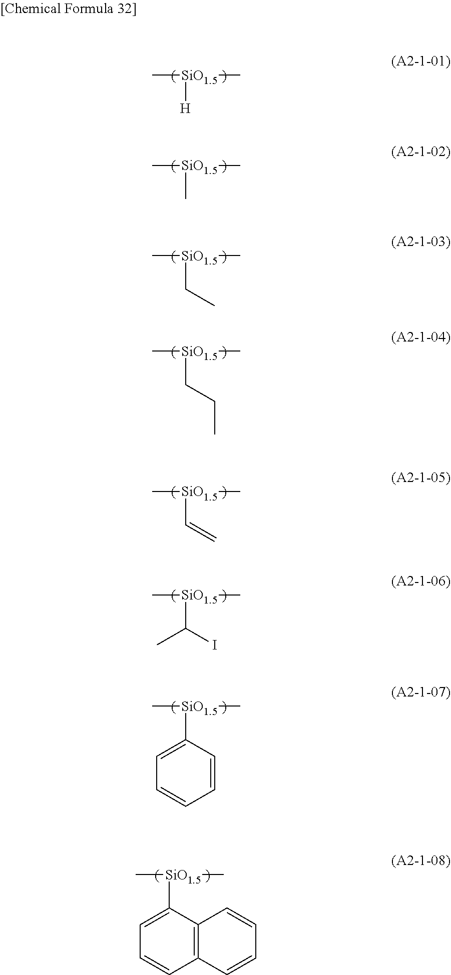

In a case where the silsesquioxane resin in the present embodiment has the constitutional unit (a21), the constitutional unit (a21) may be one kind or may be two or more kinds.

The proportion of the constitutional unit (a21) in the silsesquioxane resin in the present embodiment is, for example, preferably 30% by mole or less, more preferably 1% by mole or more and 25% by mole or less, and still more preferably 2% by mole or more and 20% by mole or less, with respect to the total amount (100% by mole) of all constitutional units that constitute the silsesquioxane resin.
Constitutional unit (a22)

The constitutional unit (a21) is a constitutional unit represented by General Formula (a2-2). In a case where the constitutional unit (a22) is contained, it is possible to easily control the characteristics of a resist film that is formed by using the resist composition.

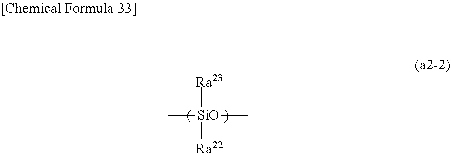

[In the formula, Ra²² and Ra²³ each independently represent a hydrocarbon group which may have a substituent.]

In General Formula (a2-2), the hydrocarbon group which may have a substituent, as Ra²² and Ra²³, is the same as the hydrocarbon group which may have a substituent, as Ra⁰²² in General Formula (a0-2) described above.

Ra²² is preferably a chain-like aliphatic hydrocarbon group which may have a substituent or an aromatic hydrocarbon group which may have a substituent. Ra²³ is preferably a chain-like aliphatic hydrocarbon group which may have a substituent.

Preferred specific examples of the constitutional unit represented by General Formula (a2-2) are shown below.

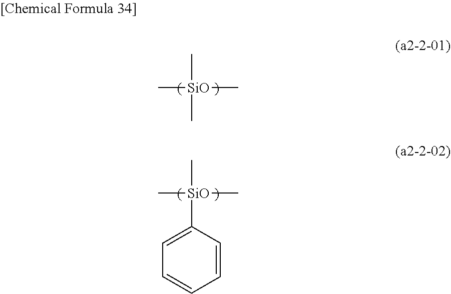

In a case where the silsesquioxane resin in the present embodiment has the constitutional unit (a22), the constitutional unit (a22) may be one kind or may be two or more kinds.

The proportion of the constitutional unit (a22) in the silsesquioxane resin in the present embodiment is, for example, preferably 30% by mole or less, more preferably 1% by mole or more and 25% by mole or less, and still more preferably 2% by mole or more and 20% by mole or less, with respect to the total amount (100% by mole) of all constitutional units that constitute the silsesquioxane resin.
Constitutional unit (a3)

The constitutional unit (a3) is a constitutional unit represented by Chemical Formula (a3-1). This constitutional unit (a3) is useful for enhancing the lithography characteristics. The introduction of the constitutional unit (a3) facilitates the control of the dissolution rate.

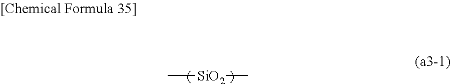

In a case where the silsesquioxane resin in the present embodiment has the constitutional unit (a3), the proportion of the constitutional unit (a3) is, for example, preferably 30% by mole or less, more preferably 1% by mole or more and 25% by mole or less, and still more preferably 2% by mole or more and 20% by mole or less, with respect to the total amount (100% by mole) of all constitutional units that constitute the silsesquioxane resin.

The silsesquioxane resin in the present embodiment may be, for example, a polymer having a terminal structure represented by any one of the following chemical formulae.

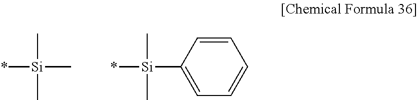

In a case where the polymer (the component (A1)) that is used in the resist composition according to the present embodiment is a resin that is soluble in an alkali developing solution and contains a crosslinkable group, examples of the preferred component (A1) include a silsesquioxane resin having a repeating structure of the constitutional unit (a01) and the constitutional unit (a1); a silsesquioxane resin having a repeating structure of the constitutional unit (a02) and the constitutional unit (a1); and a silsesquioxane resin having a repeating structure of the constitutional unit (a01), the constitutional unit (a02), and the constitutional unit (a1). Among these, a silsesquioxane resin having a repeating structure of the constitutional unit (a01) and the constitutional unit (a1) is more preferable, and a silsesquioxane resin consisting of a repeating structure of the constitutional unit (a01) and the constitutional unit (a1) is particularly preferable.

In the silsesquioxane resin consisting of a repeating structure of the constitutional unit (a01) and the constitutional unit (a1), the proportion of the constitutional unit (a01) is, for example, 1% by mole or more and 50% by mole or less, and it is preferably 1% by mole or more and less than 50% by mole, more preferably 1% by mole or more and 40% by mole or less, still more preferably 2% by mole or more and 30% by mole or less, and particularly preferably 5% by mole or more and 20% by mole or less, with respect to the total amount (100% by mole) of all constitutional units that constitute the silsesquioxane resin, and the proportion of the constitutional unit (a1) is, for example, 50% by mole or more, and it is preferably more than 50% by mole, more preferably 60% by mole or more and 99% by mole or less, still more preferably 70% by mole or more and 98% by mole or less, and particularly preferably 80% by mole or more and 95% by mole or less, with respect to the total amount (100% by mole) of all constitutional units that constitute the silsesquioxane resin.

The weight average molecular weight (Mw) (in terms of the polystyrene equivalent value determined by gel permeation chromatography (GPC)) of the component (A1) is not particularly limited. It is, for example, 1,000 or more, and it is preferably in a range of 2,000 to 20,000, more preferably in a range of 2,500 to 15,000, and still more preferably in a range of 3,000 to 13,000.

In a case where the Mw of the component (A1) is equal to or smaller than the upper limit value of the above-described preferred range, the solubility in an organic solvent is further improved. On the other hand, in a case where it is equal to or larger than the lower limit value of the above-described preferred range, the patterning properties of the resist film become better, and the lithography characteristics and etching resistance of the formed resist pattern are further improved.

The molecular weight polydispersity (Mw/Mn) of the component (A1) is not particularly limited; however, it is preferably in a range of 1.0 to 3.0, more preferably in a range of 1.0 to 2.5, and particularly preferably in a range of 1.0 to 2.0. Mn represents the number average molecular weight.

The proportion of the component (A1) in the component (A) is preferably 50% by mass or more and more preferably 75% by mass or more, and it may be 100% by mass with respect to the total mass of the component (A). In a case where the proportion is 50% by mass or more, a resist pattern having various excellent lithography characteristics such as high sensitivity, resolution, and roughness reduction can be easily formed.

The content of the component (A) in the resist composition according to the present embodiment may be adjusted depending on the resist film thickness to be formed.

### <Other Components>

The resist composition according to the present embodiment may further contain other components in addition to the component (A1) described above. Examples of the other components include a silicon-containing resin other than the component (A1); and a component (B), a component (D), a component (C), a component (E), a component (F), and a component (S), which are described below.

### <<Acid Generator Component>>

The resist composition of the present embodiment may contain, in addition to the component (A1), an acid generator component (the component (B)) that generates an acid upon exposure. This component (B) shall be such that those corresponding to the above-described component (A1) are excluded.

The component (B) is not particularly limited, and those which have been proposed so far as an acid generator for a chemical amplification-type resist composition in the related art can be used.

Examples of these acid generators are numerous and include onium salt-based acid generators such as iodonium salts and sulfonium salts; oxime sulfonate-based acid generators; diazomethane-based acid generators such as bisalkyl or bisaryl sulfonyl diazomethanes and poly(bis-sulfonyl)diazomethanes; nitrobenzyl sulfonate-based acid generators; iminosulfonate-based acid generators; and disulfonate-based acid generators.

In the resist composition according to the present embodiment, the component (B) may be used alone or in a combination of two or more kinds thereof.

In a case where the resist composition contains the component (B), the content of the component (B) in the resist composition is, for example, 20 parts by mass or less with respect to 100 parts by mass of the component (A1).

### <<Base Component>>

The resist composition according to the present embodiment may contain, in addition to the component (A1), a base component (a component (D)) that traps (that is, controls the acid diffusion) acid that is generated upon exposure. The component (D) acts as a quencher (an acid diffusion controlling agent) which traps the acid generated in the resist composition upon exposure.

Examples of the component (D) include a photodecomposable base (D1) having an acid diffusion controllability (hereinafter, referred to as a “component (D1)”) which is lost by the decomposition upon exposure and a nitrogen-containing organic compound (D2) (hereinafter, referred to as a “component (D2)”) which does not correspond to the component (D1). Among these, the photodecomposable base (the component (D1)) is preferable since it is easy to enhance the characteristics of high sensitivity, roughness reduction, and suppression of the occurrence of coating defects.
In regard to photodecomposable base (component (D1))

The component (D1) is not particularly limited as long as it is decomposed upon exposure and loses the acid diffusion controllability. The component (D1) is preferably one or more compounds selected from the group consisting of a compound represented by General Formula (d1-1) (hereinafter, referred to as a “component (d1-1)”), a compound represented by General Formula (d1-2) (hereinafter, referred to as a “component (d1-2)”), and a compound represented by General Formula (d1-3) (hereinafter, referred to as a “component (d1-3)”).

At exposed portions of the resist film, the components (d1-1) to (d1-3) are decomposed and then lose the acid diffusion controllability (basicity), and thus they cannot act as a quencher, whereas they act as a quencher at unexposed portions of the resist film.

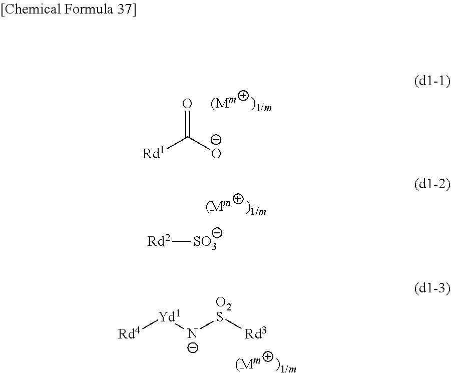

[In the formulae, Rd¹ to Rd⁴ represents cyclic groups which may have a substituent, chain-like alkyl groups which may have a substituent, or chain-like alkenyl groups which may have a substituent. Here, the carbon atom adjacent to the S atom in Rd² in General Formula (d1-2) has no fluorine atom bonded thereto. Yd¹ represents a single bond or a divalent linking group. m represents an integer of 1 or more, and M^{m+}'s each independently represent a sulfonium cation or an iodonium cation.]

{Component (d1-1)}
Anion moiety

In General Formula (d1-1), Rd¹ represents a cyclic group which may have a substituent, a chain-like alkyl group which may have a substituent, or a chain-like alkenyl group which may have a substituent, and examples thereof include the same one as R′²⁰¹.

Among these, Rd¹ is preferably an aromatic hydrocarbon group which may have a substituent, an aliphatic cyclic group which may have a substituent, or a chain-like alkyl group which may have a substituent.

Examples of the substituent which may be contained in these groups (the aromatic hydrocarbon group, the aliphatic cyclic group, and the chain-like alkyl group) include a hydroxyl group, an oxo group, an alkyl group, an aryl group, a fluorine atom, a fluorinated alkyl group, a lactone-containing cyclic group, an ether bond, an ester bond, and a combination thereof. In a case where an ether bond or an ester bond is contained as the substituent, the substituent may be bonded through an alkylene group, and the substituent in this case is preferably linking groups each represented by General Formulae (y-a1-1) to (y-a1-8) described below.

It is noted that in a case where the aromatic hydrocarbon group, the aliphatic cyclic group, or the chain-like alkyl group, as Rd¹, has a linking group represented by each of General Formulae (y-a1-1) to (y-a1-8) as a substituent, in General Formulae (y-a1-1) to (y-a1-8), the group that is bonded to a carbon atom constituting the aromatic hydrocarbon group, the aliphatic cyclic group, or the chain-like alkyl group, as Rd¹, in General Formula (d1-1) is V′¹⁰¹ in General Formulae (y-a1-1) to (y-a1-8).

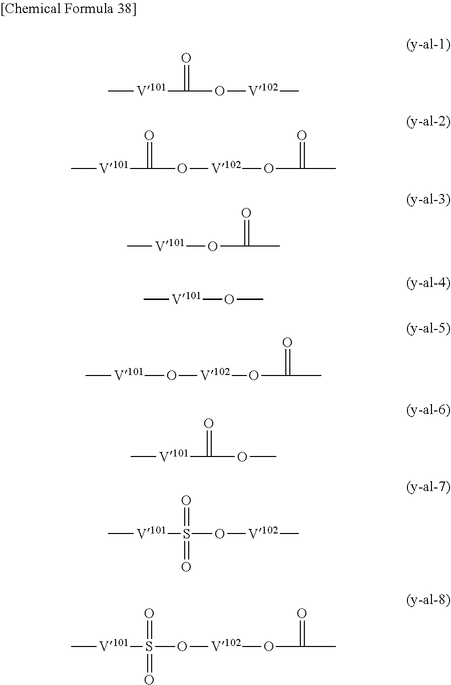

[In the formula, V′¹⁰¹ represents an alkylene group having 1 to 5 carbon atoms or a single bond. V′¹⁰² is a divalent saturated hydrocarbon group having 1 to 30 carbon atoms]

The divalent saturated hydrocarbon group as V′¹⁰² is preferably an alkylene group having 1 to 30 carbon atoms, more preferably an alkylene group having 1 to 10 carbon atoms, and still more preferably an alkylene group having 1 to 5 carbon atoms.

The alkylene group as V′° ¹⁰ and V′¹⁰² may be a linear alkylene group or a branched alkylene group, and a linear alkylene group is preferable.

Specific examples of the alkylene group as V′¹⁰¹ and V′¹⁰² include a methylene group [—CH₂—]; an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, or —C(CH₂CH₃)₂—; an ethylene group [—CH₂CH₂—]; an alkylethylene group such as —CH(CH₃)CH₂—, —CH(CH₃)CH(CH₃)—, —C(CH₃)₂CH₂—, or —CH(CH₂CH₃)CH₂—; a trimethylene group (n-propylene group) [—CH₂CH₂CH₂—]; an alkyltrimethylene group such as —CH(CH₃)CH₂CH₂— or —CH₂CH(CH₃)CH₂—; a tetramethylene group [—CH₂CH₂CH₂CH₂—]; an alkyltetramethylene group such as —CH(CH₃)CH₂CH₂CH₂—, or —CH₂CH(CH₃)CH₂CH₂—; and a pentamethylene group [—CH₂CH₂CH₂CH₂CH₂—].

Further, a part of methylene groups in the alkylene group as V′¹⁰¹ and V′¹⁰² may be substituted with a divalent aliphatic cyclic group having 5 to 10 carbon atoms. The aliphatic cyclic group is preferably a cyclohexylene group, a 1,5-adamantylene group, or a 2,6-adamantylene group.

Examples of the aromatic hydrocarbon group as Rd¹ preferably include a phenyl group, a naphthyl group, and a polycyclic structure (a polycyclic structure including a bicyclooctane skeleton and a ring structure other than the bicyclooctane skeleton) including a bicyclooctane skeleton.

The aliphatic cyclic group as Rd¹ is more preferably a group obtained by removing one or more hydrogen atoms from polycycloalkanes such as adamantane, norbornane, isobornane, tricyclodecane, and tetracyclododecane.

The chain-like alkyl group preferably as Rd¹ has 1 to 10 carbon atoms, and specific examples thereof include a linear alkyl group such as a methyl group, an ethyl group, a propyl group, a butyl group, a pentyl group, a hexyl group, a heptyl group, an octyl group, a nonyl group, or a decyl group, and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, or a 4-methylpentyl group.

In a case where the chain-like alkyl group is a fluorinated alkyl group having a fluorine atom or a fluorinated alkyl group as a substituent, the fluorinated alkyl group preferably has 1 to 11 carbon atoms, more preferably has 1 to 8 carbon atoms, and still more preferably has 1 to 4 carbon atoms. The fluorinated alkyl group may contain an atom other than a fluorine atom. Examples of the atom other than a fluorine atom include an oxygen atom, a sulfur atom, and a nitrogen atom.

Specific preferred examples of the anion moiety in the component (d1-1) are described below.

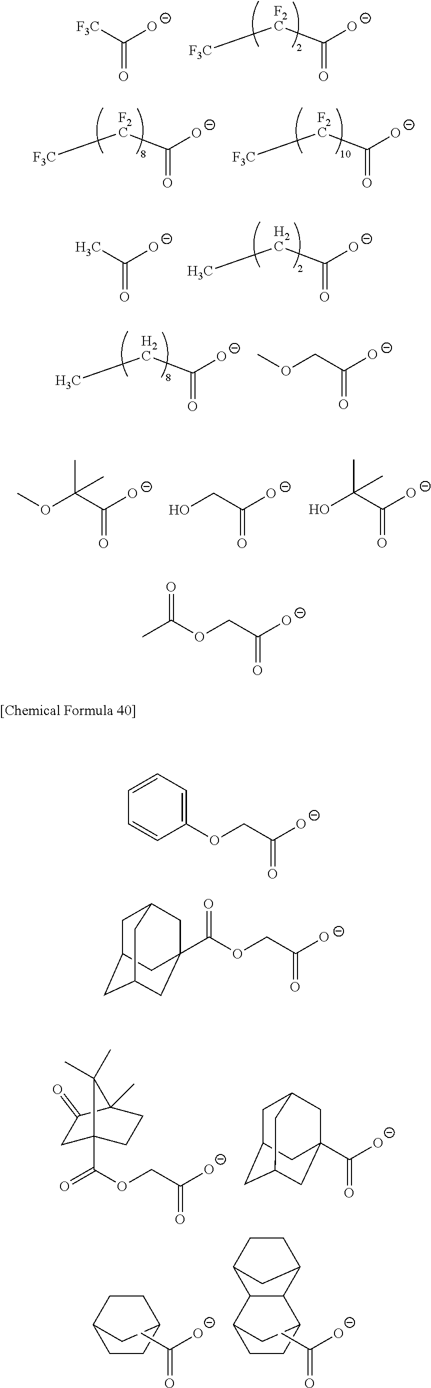

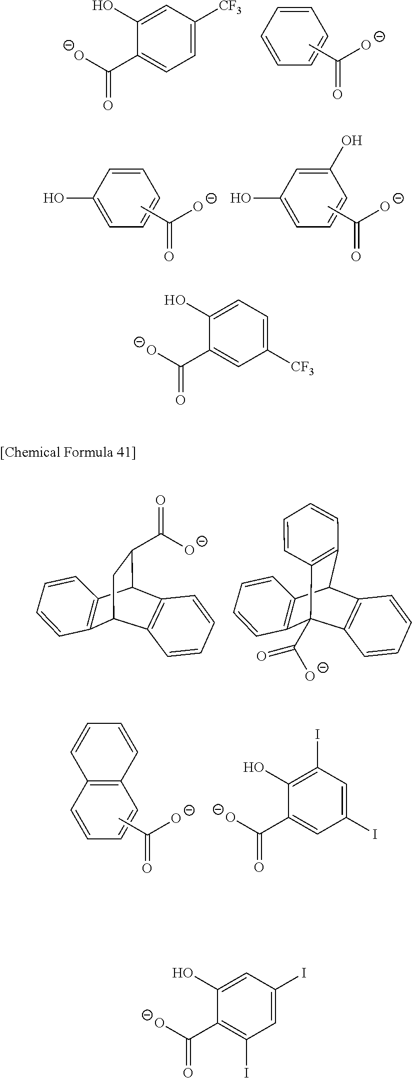

Cation moiety

In General Formula (d1-1), M^{m+} represents a sulfonium cation or an iodonium cation.

Examples of M^{m+} preferably include the same ones as the cations each represented by General Formulae (ca-1) to (ca-3), a cation represented by General Formula (ca-1) is more preferable, and cations each represented by General Formulae (ca-1-1) to (ca-1-85) are still more preferable.

The component (d1-1) may be used alone or in a combination of two or more kinds thereof.

{Component (d1-2)}
Anion moiety

In General Formula (d1-2), Rd² represents a cyclic group which may have a substituent, a chain-like alkyl group which may have a substituent, or a chain-like alkenyl group which may have a substituent, and examples thereof include the same one as R′²⁰¹

Here, the carbon atom adjacent to the S atom in Rd² has no fluorine atom bonded thereto (the carbon atom adjacent to the S atom in Rd² is not subjected to fluorine substitution). As a result, the anion of the component (d1-2) becomes an appropriately weak acid anion, thereby improving the quenching ability of the component (D).

Rd² is preferably a chain-like alkyl group which may have a substituent or an aliphatic cyclic group which may have a substituent, and more preferably an aliphatic cyclic group which may have a substituent.

The chain-like alkyl group preferably has 1 to 10 carbon atoms and more preferably has 3 to 10 carbon atoms.

The aliphatic cyclic group is more preferably a group (which may have a substituent) obtained by removing one or more hydrogen atoms from adamantane, norbornane, isobornane, tricyclodecane, tetracyclododecane, or the like; and a group obtained by removing one or more hydrogen atoms from camphor.

The hydrocarbon group as Rd² may have a substituent. Examples of the substituent include the same ones as the substituents which may be contained in the hydrocarbon group (the aromatic hydrocarbon group, the aliphatic cyclic group, or the chain-like alkyl group) as Rd¹ in General Formula (d1-1).

Specific preferred examples of the anion moiety in the component (d1-2) are described below.

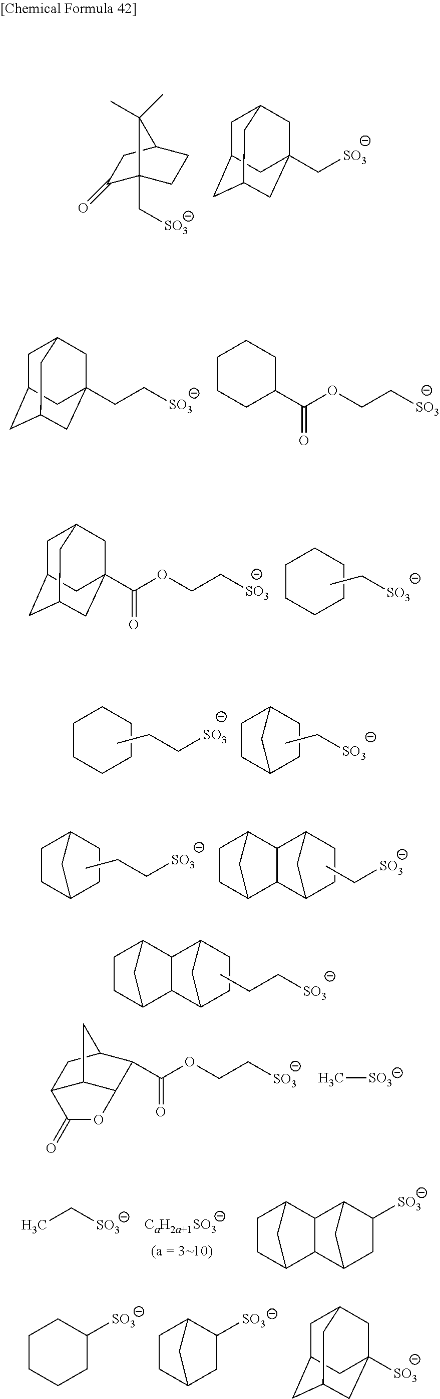

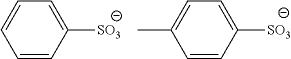

Cation moiety

in General Formula (d1-2), M^{m+} represents a sulfonium cation or an iodonium cation, and it is the same as M^{m+} in General Formula (d1-1).

The component (d1-2) may be used alone or in a combination of two or more kinds thereof.

{Component (d1-3)}
Anion moiety

In General Formula (d1-3), Rd¹ represents a cyclic group which may have a substituent, a chain-like alkyl group which may have a substituent, or a chain-like alkenyl group which may have a substituent, examples thereof include the same one as R′²⁰¹, and a cyclic group containing a fluorine atom, a chain-like alkyl group, or a chain-like alkenyl group is preferable. Among them, a fluorinated alkyl group is preferable, and the same one as the fluorinated alkyl group as Rd¹ is more preferable.

In General Formula (d1-3), Rd⁴ represents a cyclic group which may have a substituent, a chain-like alkyl group which may have a substituent, or a chain-like alkenyl group which may have a substituent, and examples thereof include the same one as R′²⁰¹

Among them, an alkyl group which may have a substituent, an alkoxy group which may have a substituent, an alkenyl group which may have a substituent, or a cyclic group which may have a substituent is preferable.

The alkyl group as Rd⁴ is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group. A part of hydrogen atoms in the alkyl group as Rd⁴ may be substituted with a hydroxyl group, a cyano group, or the like.

The alkoxy group as Rd⁴ is preferably an alkoxy group having 1 to 5 carbon atoms, and specific examples of the alkoxy group having 1 to 5 carbon atoms include a methoxy group, an ethoxy group, an n-propoxy group, an iso-propoxy group, an n-butoxy group, and a tert-butoxy group. Among these, a methoxy group and an ethoxy group are preferable.

Examples of the alkenyl group as Rd⁴ include the same one as R′²⁰¹, and a vinyl group, a propenyl group (an allyl group), a 1-methylpropenyl group, or a 2-methylpropenyl group is preferable. These groups may have an alkyl group having 1 to 5 carbon atoms or a halogenated alkyl group having 1 to 5 carbon atoms as a substituent.

Examples of the cyclic group as Rd⁴ include the same one as the cyclic group as R′²⁰¹, and an alicyclic group obtained by removing one or more hydrogen atoms from a cycloalkane such as cyclopentane, cyclohexane, adamantane, norbornane, isobornane, tricyclodecane, or tetracyclododecane, or an aromatic group such as a phenyl group or a naphthyl group is preferable. In a case where Rd⁴ represents an alicyclic group, the resist composition can be satisfactorily dissolved in an organic solvent, thereby improving the lithography characteristics. In a case where Rd⁴ is an aromatic group, the resist composition is excellent in light absorption efficiency and thus has good sensitivity and lithography characteristics in the lithography using EUV or the like as a light source for exposure.

In General Formula (d1-3), Yd¹ represents a single bond or a divalent linking group.

The divalent linking group as Yd¹ is not particularly limited, and examples thereof include a divalent hydrocarbon group (an aliphatic hydrocarbon group or an aromatic hydrocarbon group) which may have a substituent and a divalent linking group containing a hetero atom. The divalent linking groups include the same ones as those described above as the divalent hydrocarbon group which may have a substituent and the divalent linking group containing a hetero atom described above as the divalent linking group as Ra⁰¹ in General Formula (a0-1).

Yd¹ is preferably a carbonyl group, an ester bond, an amide bond, an alkylene group, or a combination thereof. The alkylene group is more preferably a linear or branched alkylene group, and still more preferably a methylene group or an ethylene group.

Specific preferred examples of the anion moiety in the component (d1-3) are described below.

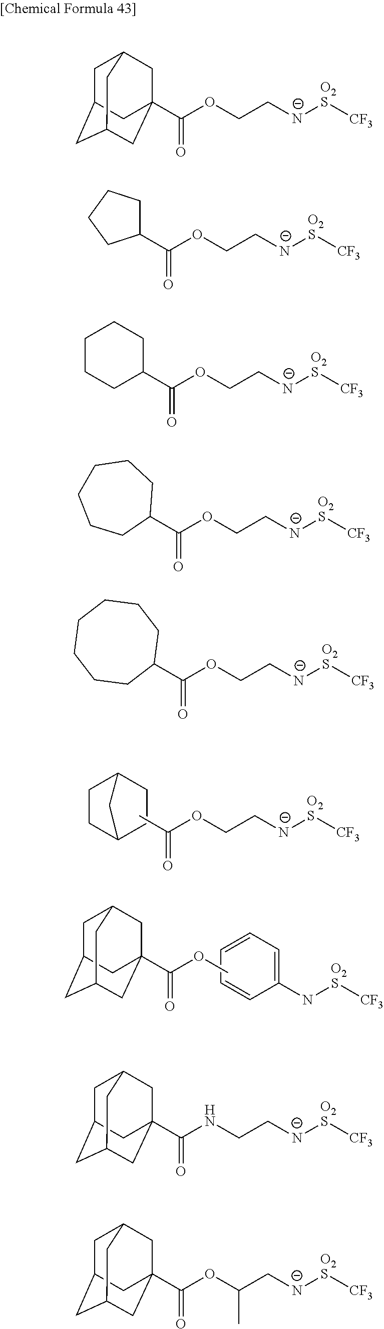

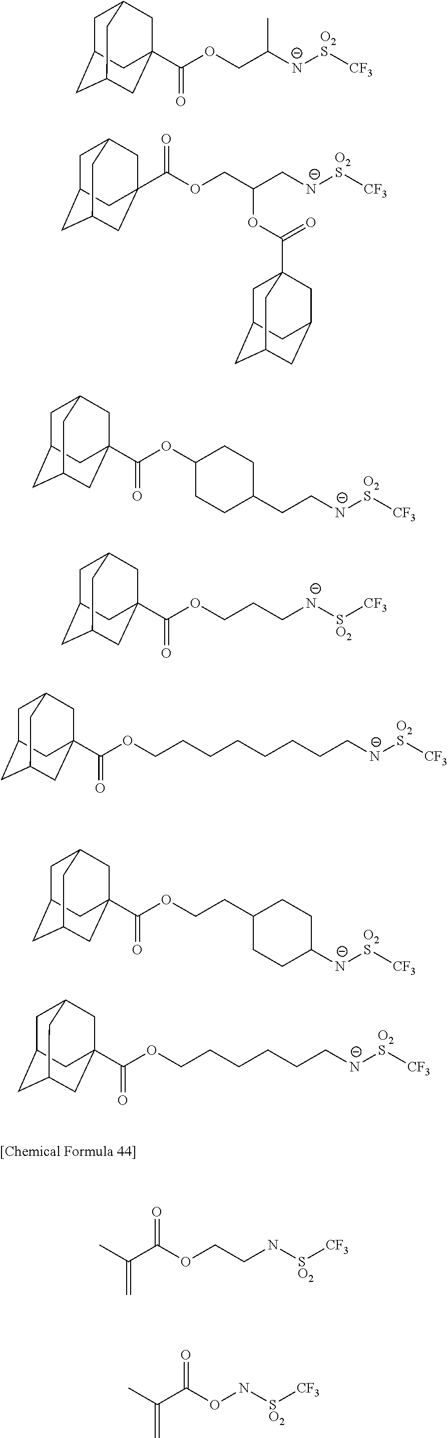

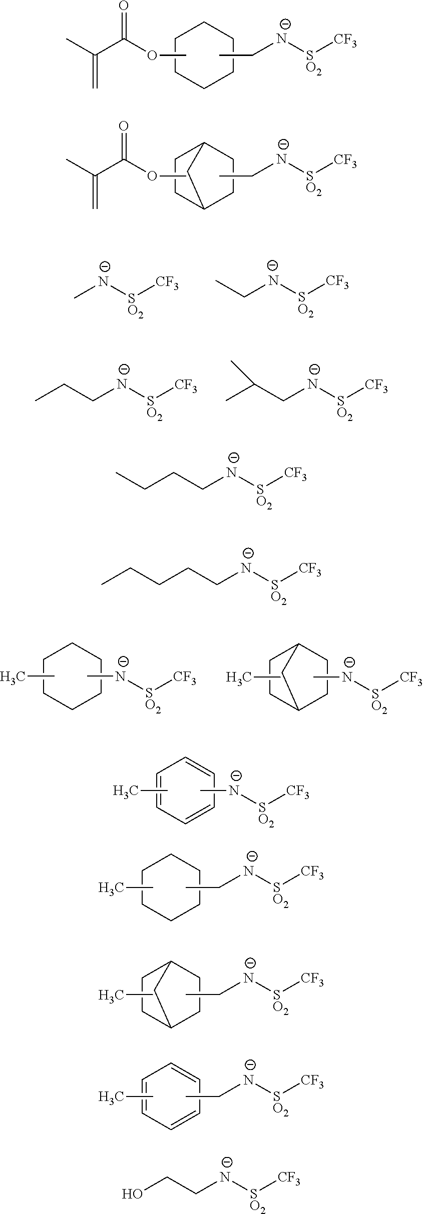

Cation moiety

in General Formula (d1-3), M^{m+} represents a sulfonium cation or an iodonium cation, and it is the same as M^{m+} in General Formula (d1-1).

The component (d1-3) may be used alone or in a combination of two or more kinds thereof.

As the component (D1), only one of the above-described components (d1-1) to (d1-3) or a combination of two or more kinds thereof may be used.

In a case where the resist composition contains the component (D1), the content of the component (D1) in the resist composition is appropriately set depending on the conditions of the exposure amount, and it is, for example, preferably in a range of 5 to 60 parts by mass, more preferably in a range of 10 to 40 parts by mass, and still more preferably in a range of 15 to 35 parts by mass, with respect to 100 parts by mass of the component (A1).

It is preferable that the component (D1) contains the component (d1-1).

The content of the component (d1-1) in the total component (D1) is preferably 50% by mass or more, preferably 70% by mass or more, and still more preferably 90% by mass or more, and the component (D1) may consist of only a compound for the component (d1-1).

Method of producing component (D1):

The methods of producing the components (d1-1) and (d1-2) described above are not particularly limited, and the components (d1-1) and (d1-2) can be produced by conventionally known methods.

Further, the method of producing the component (d1-3) is not particularly limited, and the component (d1-3) can be produced, for example, in the same manner as disclosed in United States Patent Application, Publication No. 2012-0149916.
In regard to component (D2)

The component (D) may contain a nitrogen-containing organic compound component (hereinafter, referred to as a “component (D2)”) which does not correspond to the component (D1).

The component (D2) is not particularly limited as long as it acts as an acid diffusion control agent and does not correspond to the component (D1), and any known compound may be used. Among the above, aliphatic amines are preferable, and among the aliphatic amines, a secondary aliphatic amine or a tertiary aliphatic amine is more preferable.

An aliphatic amine is an amine having one or more aliphatic groups, and the aliphatic groups preferably have 1 to 12 carbon atoms.

Examples of these aliphatic amines include an amine in which at least one hydrogen atom of ammonia (NH₃) has been substituted with an alkyl group or hydroxyalkyl group having 12 or fewer carbon atoms (alkyl amines or alkyl alcohol amines) and a cyclic amine.

Specific examples of the alkyl amine and the alkyl alcohol amine include monoalkyl amines such as n-hexyl amine, n-heptyl amine, n-octyl amine, n-nonyl amine, and n-decyl amine; dialkyl amines such as diethyl amine, di-n-propyl amine, di-n-heptyl amine, di-n-octyl amine, and dicyclohexyl amine; trialkyl amines such as trimethyl amine, triethyl amine, tri-n-propyl amine, tri-n-butyl amine, tri-n-pentyl amine, tri-n-hexyl amine, tri-n-heptyl amine, tri-n-octyl amine, tri-n-nonyl amine, tri-n-decyl amine, and tri-n-dodecyl amine; and alkyl alcohol amines such as diethanol amine, triethanol amine, diisopropanol amine, triisopropanol amine, di-n-octanol amine, and tri-n-octanol amine. Among these, trialkyl amines of 6 to 30 carbon atoms are preferable, and tri-n-pentyl amine and tri-n-octyl amine are particularly preferable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine and piperazine. The aliphatic polycyclic amine preferably has 6 to 10 carbon atoms, and specific examples thereof include 1,5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine and triethanol amine triacetate, and triethanol amine triacetate is preferable.

In addition, as the component (D2), an aromatic amine may be used.

Examples of the aromatic amine include 4-dimethylaminopyridine, pyrrole, indole, pyrazole, imidazole, and derivatives thereof, tribenzylamine, 2,6-diisopropylaniline, N-tert-butoxycarbonylpyrrolidine, 2,6-di-tert-butylpyridine, and 2,6-di-tert-butylpyridine.

The component (D2) may be used alone or in a combination of two or more kinds thereof.

In a case where the resist composition contains the component (D2), the content of the component (D2) in the resist composition is typically in a range of 0.01 to 5 parts by mass with respect to 100 parts by mass of the component (A1). In a case where it is set in the above-described range, the resist pattern shape, the post-exposure temporal stability, and the like are improved.

### <<Crosslinking Agent Component>>

In a case where the resist composition according to the present embodiment is a “negative-tone resist composition for an alkali developing process” that forms a negative-tone resist pattern in an alkali developing process or in a case where it is a “positive-tone resist composition for a solvent developing process” that forms a positive-tone resist pattern in a solvent developing process, the resist composition according to the present embodiment further contains a crosslinking agent component (hereinafter, also referred to as a “component (C)”) in addition to the component (A1) described above.

Examples of the component (C) include a melamine-based crosslinking agent, a urea-based crosslinking agent, an alkylene urea-based crosslinking agent, a glycoluril-based crosslinking agent, a phenol-based crosslinking agent, and an epoxy-based crosslinking agent.

It is noted that the term “lower” used below means having 1 to 5 carbon atoms.

Examples of the melamine-based crosslinking agent include a compound obtained by reacting melamine with formaldehyde to substitute a hydrogen atom of an amino group with a hydroxymethyl group; and a compound obtained by reacting melamine, formaldehyde, and a lower alcohol to substitute a hydrogen atom of an amino group with a lower alkoxymethyl group. Specific examples thereof include hexamethoxymethyl melamine, hexaethoxymethyl melamine, hexapropoxymethyl melamine, and hexabutoxybutyl melamine, among which hexamethoxymethyl melamine is preferable.

Examples of the urea-based crosslinking agent include a compound obtained by reacting urea with formaldehyde to substitute a hydrogen atom of an amino group with a hydroxymethyl group; and a compound obtained by reacting urea, formaldehyde, and a lower alcohol to substitute a hydrogen atom of an amino group with a lower alkoxymethyl group. Specific examples thereof include bismethoxymethyl urea, bisethoxymethyl urea, bispropoxymethyl urea, and bisbutoxymethyl urea, among which bismethoxymethyl urea is preferable.

Examples of the alkylene urea-based crosslinking agent include a compound represented by General Formula (CA-1).

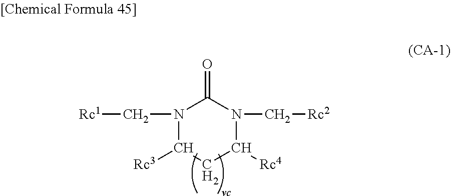

[In General Formula (CA-1), Rc¹ and Rc² each independently represent a hydroxyl group or a lower alkoxy group. Rc³ and Rc⁴ each independently represent a hydrogen atom, a hydroxyl group, or a lower alkoxy group. vc represents an integer in a range of 0 to 2.]

In a case of being a lower alkoxy group, Rc¹ and Rc² are preferably an alkoxy group having 1 to 4 carbon atoms and may be linear or branched. Rc¹ and Rc² may be the same or different from each other, where they are more preferably the same.

In a case of being a lower alkoxy group, Rc³ and Rc⁴ are preferably an alkoxy group having 1 to 4 carbon atoms and may be linear or branched. Rc³ and Rc⁴ may be the same or different from each other, where they are more preferably the same.

vc represents an integer in a range of 0 to 2 and is preferably 0 or 1.

In particular, the alkylene urea-based crosslinking agent is preferably a compound in which vc is 0 (an ethylene urea-based crosslinking agent) and/or a compound in which vc is 1 (a propylene urea-based crosslinking agent).

The compound represented by General Formula (CA-1) can be obtained by subjecting an alkylene urea to a condensation reaction with formalin or by subjecting the product of this reaction to a reaction with a lower alcohol.

Specific examples of the alkylene urea-based crosslinking agent include ethylene urea-based crosslinking agents such as mono- and/or dihydroxymethylated ethylene urea, mono- and/or dimethoxymethylated ethylene urea, mono- and/or diethoxymethylated ethylene urea, mono- and/or dipropoxymethylated ethylene urea, and mono- and/or dibutoxymethylated ethylene urea; propylene urea-based crosslinking agents such as mono- and/or dihydroxymethylated propylene urea, mono- and/or dimethoxymethylated propylene urea, mono- and/or diethoxymethylated propylene urea, mono- and/or dipropoxymethylated propylene urea, and mono- and/or dibutoxymethylated propylene urea; 1,3-di(methoxymethyl) 4,5-dihydroxy-2-imidazolidinone; and 1,3-di(methoxymethyl)-4,5-dimethoxy-2-imidazolidinone.

Examples of the glycoluril-based crosslinking agent include a glycoluril derivative having a substitution with one or both of a hydroxyalkyl group and an alkoxyalkyl group having 1 to 4 carbon atoms at the N-position. Such a glycoluril derivative can be obtained by subjecting glycoluril to a condensation reaction with formalin or by subjecting the product of this reaction to a reaction with a lower alcohol.

Specific examples of the glycoluril-based crosslinking agents include mono-, di-tri-, and/or tetra-hydroxymethylated glycoluril; mono-, di-, tri-, and/or tetra-methoxymethylated glycoluril; mono-, di-, tri-, and/or tetra-ethoxymethylated glycoluril; mono-, di-, tri-, and/or tetra-propoxymethylated glycoluril; and mono-, di-, tri-, and/or tetra-butoxymethylated glycoluril.

The phenol-based crosslinking agent is not particularly limited as long as it is a compound having a plurality of phenolic core structures in the same molecule, and any phenol-based crosslinking agent can be selected and used. In a case where a plurality of phenolic core structures is contained, crosslinking reactivity is improved.

The number of phenolic core structures is preferably 2 to 5, more preferably 2 to 4, and still more preferably 2 or 3.

Suitable glycoluril-based crosslinking agents and suitable phenol-based crosslinking agents are each shown below.

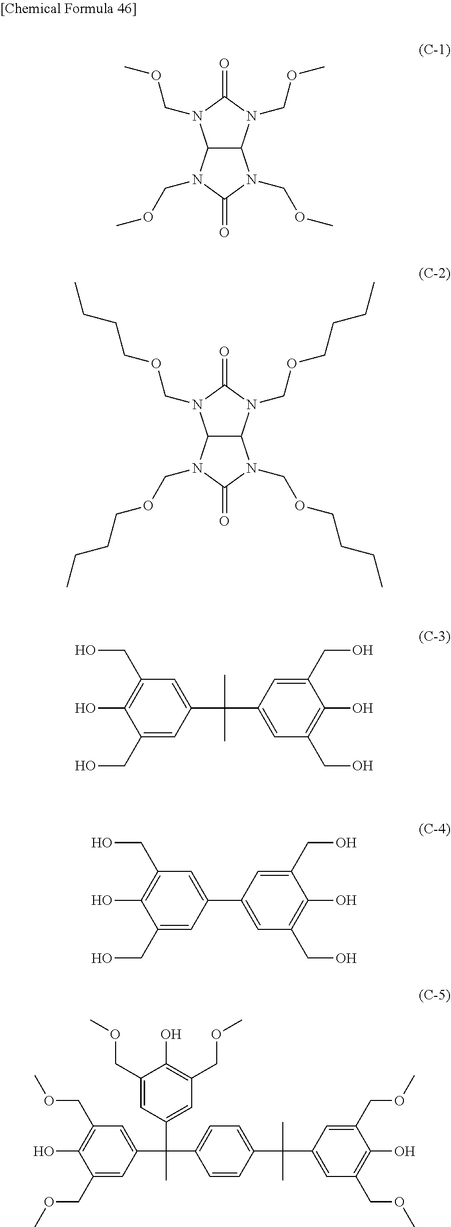

The epoxy-based crosslinking agent is not particularly limited as long as it has an epoxy group, and any epoxy-based crosslinking agent can be selected and used. Among the above, the one having two or more epoxy groups is preferable. In a case where two or more epoxy groups are contained, crosslinking reactivity is improved.

The number of epoxy groups is preferably 2 or more, more preferably 2 to 4, and most preferably 2.

Suitable epoxy-based crosslinking agents are shown below.

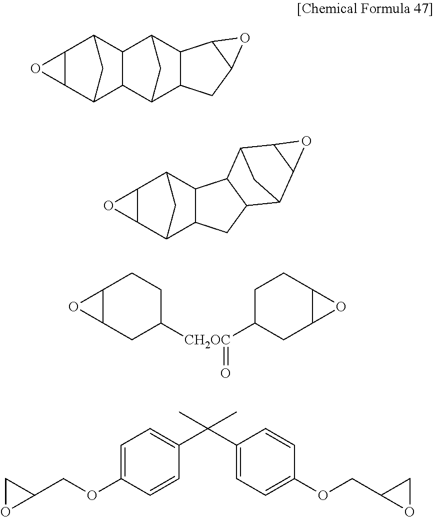

Among them, the component (C) is preferably a compound having an alkylol group such as a methylol group, or an alkoxyalkyl group such as a methoxymethyl group, more preferably a crosslinking agent selected from the group consisting of a glycoluril-based crosslinking agent and a phenol-based crosslinking agent, and still more preferably a glycoluril-based crosslinking agent.

In the resist composition according to the present embodiment, the component (C) may be used alone or in a combination of two or more kinds thereof.

In the resist composition according to the present embodiment, the content of the component (C) is preferably in a range of 1 to 50 parts by mass, more preferably in a range of 3 to 30 parts by mass, still more preferably in a range of 5 to 20 parts by mass, and most preferably in a range of 5 to 15 parts by mass, with respect to 100 parts by mass of the component (A1).

In a case where the content of the component (C) is equal to or larger than the lower limit value of the above-described preferred range, the crosslinking proceeds sufficiently to facilitate obtaining a dissolution contrast, and thus resolution performance and lithography characteristics are further improved. In addition, a favorable resist pattern with less swelling can be obtained. In addition, in a case where the content thereof is equal to or smaller than the upper limit value of the above-described preferred range, the storage stability of the resist composition is favorable, and the temporal deterioration of the sensitivity is easily suppressed.

<<At Least One Compound (E) Selected from the Group Consisting of Organic Carboxylic Acid, Phosphorus Oxo Acid, and Derivatives Thereof>>

For the purpose of preventing any deterioration in sensitivity and improving the resist pattern shape and the post-exposure temporal stability, the resist composition according to the present embodiment may contain, as an optional component, at least one compound (E) (hereinafter referred to as a “component (E)”) selected from the group consisting of an organic carboxylic acid, and a phosphorus oxo acid and a derivative thereof.

Specific examples of the organic carboxylic acid include acetic acid, malonic acid, citric acid, malic acid, succinic acid, benzoic acid, and salicylic acid, and among them, salicylic acid is preferable.

Examples of the phosphorus oxo acid include phosphoric acid, phosphonic acid, and phosphinic acid. Among these, phosphonic acid is preferable.

In the resist composition according to the present embodiment, one kind of the component (E) may be used alone, or two or more kinds thereof may be used in combination.

In a case where the resist composition contains the component (E), the content of the component (E) is preferably in a range of 0.1 to 10 parts by mass and more preferably in a range of 1 to 5 parts by mass with respect to 100 parts by mass of the component (A1). In a case where it is set in the above-described range, the temporal stability of the resist composition is improved.

### <<Fluorine Additive Component (F)>>

The resist composition according to the present embodiment may contain a fluorine additive component (hereinafter, referred to as a “component (F)”) as a hydrophobic resin. The component (F) is used to impart water repellency to the resist film and used as a resin different from the component (A), whereby the lithography characteristics can be improved.

As the component (F), a fluorine-containing polymeric compound described in Japanese Unexamined Patent Application, First Publication No. 2010-002870, Japanese Unexamined Patent Application, First Publication No. 2010-032994, Japanese Unexamined Patent Application, First Publication No. 2010-277043, Japanese Unexamined Patent Application, First Publication No. 2011-13569, and Japanese Unexamined Patent Application, First Publication No. 2011-128226 can be mentioned.

Specific examples of the component (F) include polymers having a constitutional unit (f1) represented by General Formula (f1-1) shown below. This polymer is preferably a polymer (a homopolymer) consisting only of a constitutional unit (f1) represented by General Formula (f1-1); a copolymer of the constitutional unit (f1) and a constitutional unit (a101) that contains an acid decomposable group having a polarity that is increased by action of acid; a copolymer of the constitutional unit (f1), a constitutional unit derived from acrylic acid or methacrylic acid, and the following constitutional unit (a101), and more preferably a copolymer of the constitutional unit (f1) and the following constitutional unit (a101).

The constitutional unit (a101) to be copolymerized with the constitutional unit (f1) is preferably a constitutional unit derived from 1-ethyl-1-cyclooctyl (meth)acrylate or a constitutional unit derived from 1-methyl-1-adamantyl (meth)acrylate, and more preferably a constitutional unit derived from 1-ethyl-1-cyclooctyl (meth)acrylate.

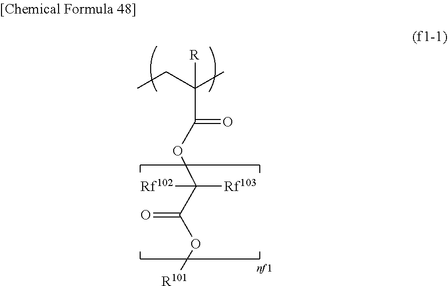

[In the formula, R has the same definition as described above. Rf¹⁰² and Rf¹⁰³ each independently represent a hydrogen atom, a halogen atom, an alkyl group having 1 to 5 carbon atoms, or a halogenated alkyl group having 1 to 5 carbon atoms, and Rf¹⁰² and Rf¹⁰³ may be the same as or different from each other. nf¹ represents an integer in a range of 0 to 5 and Rf¹⁰¹ represents an organic group containing a fluorine atom.]

In General Formula (f1-1), examples of R bonded to the carbon atom at the α-position include an alkyl group having 1 to 5 carbon atoms, a halogenated alkyl group having 1 to 5 carbon atoms, or a hydrogen atom. R is preferably a hydrogen atom or a methyl group.

In General Formula (f1-1), the halogen atom of Rf¹⁰² and Rf¹⁰³ is preferably a fluorine atom. The alkyl group having 1 to 5 carbon atoms as Rf¹⁰² and Rf¹⁰³ is preferably a methyl group or an ethyl group. Specific examples of the halogenated alkyl group having 1 to 5 carbon atoms as Rf¹⁰² and Rf¹⁰³ include groups in which part or all of hydrogen atoms of the above-described alkyl groups of 1 to 5 carbon atoms have been substituted with a halogen atom. The halogen atom is preferably a fluorine atom. Among the above, Rf¹⁰² and Rf¹⁰³ are preferably a hydrogen atom, a fluorine atom, or an alkyl group having 1 to 5 carbon atoms, more preferably a hydrogen atom, a fluorine atom, a methyl group, or an ethyl group, and still more preferably a hydrogen atom.

In General Formula (f1-1), nf¹ represents an integer in a range of 0 to 5, and it is preferably an integer in a range of 0 to 3 and more preferably an integer of 1 or 2.

In General Formula (f1-1), Rf¹⁰¹ represents an organic group containing a fluorine atom and is preferably a hydrocarbon group containing a fluorine atom.

The hydrocarbon group containing a fluorine atom may be linear, branched, or cyclic, and preferably has 1 to 20 carbon atoms, more preferably has 1 to 15 carbon atoms, and particularly preferably has 1 to 10 carbon atoms.

In addition, in the hydrocarbon group containing a fluorine atom, 25% or more of the hydrogen atoms in the hydrocarbon group are preferably fluorinated, more preferably 50% or more are fluorinated, and particularly preferably 60% or more are fluorinated since the hydrophobicity of the resist film during immersion exposure increases.

Among them, Rf¹⁰¹ is more preferably a fluorinated hydrocarbon group having 1 to 6 carbon atoms, and particularly preferably a trifluoromethyl group, —CH₂—CF₃, —CH₂—CF₂—CF₃, —CH(CF₃)₂, —CH₂—CH₂—CF₃, or —CH₂—CH₂—CF₂—CF₂—CF₂—CF₃.

The weight average molecular weight (Mw) (in terms of the polystyrene equivalent value determined by gel permeation chromatography) of the component (F) is preferably in a range of 1,000 to 50,000, more preferably in a range of 5,000 to 40,000, and most preferably in a range of 10,000 to 30,000. In a case where the weight average molecular weight is equal to or smaller than the upper limit value of this range, the resist composition exhibits sufficient solubility in a resist solvent to be used as a resist. On the other hand, in a case where the weight average molecular weight is equal to or larger than the lower limit value of this range, the water repellency of the resist film is excellent.

Further, the molecular weight polydispersity (Mw/Mn) of the component (F) is preferably in a range of 1.0 to 5.0, more preferably in a range of 1.0 to 3.0, and most preferably in a range of 1.0 to 2.5.

In the resist composition according to the present embodiment, the component (F) may be used alone or in a combination of two or more kinds thereof.

In a case where the resist composition contains the component (F), the content of the component (F) in the resist composition is preferably in a range of 0.5 to 10 parts by mass and more preferably in a range of 1 to 10 parts by mass with respect to 100 parts by mass of the component (A1).

### <<Organic Solvent Component (S)>>

The resist composition according to the present embodiment may be produced by dissolving the resist materials in an organic solvent component (hereinafter, referred to as a “component (S)”).

In the resist composition according to the present embodiment, the component (S) may be used alone or as a mixed solvent of two or more kinds thereof. Among these, propylene glycol monomethyl ether acetate (PGMEA), propylene glycol monomethyl ether, γ-butyrolactone, ethyl lactate (EL), or cyclohexanone is preferable.

In addition, a mixed solvent obtained by mixing PGMEA with a polar solvent is also preferable as the component (S). The blending ratio (mass ratio) may be appropriately determined in consideration of the compatibility between PGMEA and the polar solvent.

In addition, the component (S) is also preferably a mixed solvent of at least one selected from PGMEA and EL and 7-butyrolactone. In this case, as the mixing ratio, the mass ratio of the former to the latter is preferably in a range of 70:30 to 95:5.

The amount of the component (S) to be used is not particularly limited and is appropriately set, depending on a thickness of a film to be coated, to a concentration at which the component (S) can be applied onto a substrate or the like.

In the resist composition according to the present embodiment, the solid content concentration of the resist composition is preferably in a range of 0.1% to 10% by mass, more preferably in a range of 0.2% to 5% by mass, and still more preferably in a range of 0.3% to 2% by mass, from the viewpoint of coatability on a substrate or the like.

In addition, in the resist composition of the present embodiment, the content proportion of the polymer (A1) in the solid content of the resist composition is preferably 40% by mass or more, more preferably 50% by mass or more and 85% by mass or less, still more preferably 60% by mass or more and 80% by mass or less, and particularly preferably 65% by mass or more and 75% by mass or less.

In a case where the content proportion of the component (A1) in the solid content of the resist composition is in the above-described preferred range, the effect of reducing pattern roughness is easily enhanced, and the etching resistance is easily enhanced.

It is noted that the term “the solid content of the resist composition” shall refer to a content consisting of components constituting the resist composition, excluding the organic solvent component (S).

In addition, in the resist composition of the present embodiment, the content proportion of the silicon (Si) in the solid content of the resist composition is preferably 5% by mass or more, more preferably in a range of 5% to 20% by mass, and still more preferably in a range of 5% to 15% by mass.

In a case where the content proportion of the silicon (Si) in the solid content of the resist composition is equal to or larger than the lower limit value of the above-described preferred range, etching resistance is easily increased, whereas in a case where it is equal to or smaller than the upper limit value of the above-described preferred range, a resist pattern having favorable lithography characteristics is easily formed.

As desired, other miscible additives can also be added to the resist composition according to the present embodiment. For example, for improving the performance of the resist film, an additive resin, a dissolution inhibitor, a plasticizer, a stabilizer, a colorant, a halation prevention agent, and a dye can be appropriately contained therein.

For example, in the resist composition according to the present embodiment, a hydroxystyrene resin, a resin that is a novolak resin and does not contain silicon, or the like may be used in combination, in addition to the component (A1) described above. In the hydroxystyrene resin, the hydrogen atom at the α-position of hydroxystyrene may be substituted with a substituent. Examples of this substituent include an alkyl group and a halogenated alkyl group.

After dissolving the resist material in the component (S), the resist composition according to the present embodiment may be subjected to the removal of impurities and the like by using a porous polyimide membrane, a porous polyamideimide membrane, or the like. For example, the resist composition may be filtered using a filter consisting of a porous polyimide membrane, a filter consisting of a porous polyamideimide membrane, or a filter consisting of a porous polyimide membrane and a porous polyamideimide membrane. Examples of the porous polyimide membrane and the porous polyamideimide membrane include those described in Japanese Unexamined Patent Application, First Publication No. 2016-155121.

The resist composition according to the present embodiment described above contains the polymer (the component (A1)) containing a siloxane bond and a specific ionic group that is decomposed upon exposure to generate acid. Since the component (A1) contains a siloxane bond, the resist composition has an advantage that a resist film to be formed has high dry etching resistance, as compared with a resist composition containing a general organic material as a base material component.

In addition, since the component (A1) contains a specific ionic group that is decomposed upon exposure to generate acid, the resist composition has an effect of reducing pattern roughness of a pattern to be formed. This is conceived to be due to the facts that a specific ionic group is bonded to the polymer (component (A1)) molecule in the resist composition, and thus a site where the specific ionic group is decomposed upon exposure to generate acid is easily distributed uniformly in a resist film to be formed as compared with a general resist composition that separately contains a base material component and an acid generator component; and that a sulfonate anion group (—SO₃) among the specific ionic groups is bonded to the side chain of the polymer, and thus the diffusion of the acid generated upon exposure is suppressed.

Such a resist composition has excellent fine resolution in EUV lithography. In addition, it is possible to form a fine-sized pattern having a line width of ten and several nm in a favorable shape while suppressing roughness, which has been difficult in the related art, and it is possible to achieve both etching resistance and lithography characteristics.

Such a resist composition is a resist material that makes it possible to form a silicon-containing pattern, for example, having a fine line width and reduced roughness, and that can be suitably used in the microfabrication in EUV lithography.

### (Resist Pattern Forming Method)

The resist pattern forming method according to the second aspect according to the present invention is a method including a step (i) of forming a resist film on a support using the resist composition according to the first aspect of the present invention described above, a step (ii) of exposing the resist film, and a step (iii) of developing the exposed resist film to form a resist pattern.

Examples of one embodiment of such a resist pattern forming method include a resist pattern forming method carried out as described below.

[Step (i)]

First, the resist composition of the above-described embodiment is applied onto a support with a spinner or the like, and a baking (post-apply baking (PAB)) treatment is carried out, for example, at a temperature condition in a range of 80° C. to 150° C. for 40 to 120 seconds, preferably for 60 to 90 seconds to form a resist film.

[Step (ii)]

The selective exposure is carried out on the resist film, for example, by the exposure through a mask (mask pattern) having a predetermined pattern formed on the mask by using an exposure apparatus such as an electron beam drawing apparatus or an EUV exposure apparatus, or direct irradiation of the resist film for drawing with an electron beam without using a mask pattern.

After the above exposure, a baking (post-exposure baking (PEB)) treatment is carried out, for example, under the temperature condition in a range of 80° C. 150° C. for 40 to 120 seconds and preferably 60 to 90 seconds.

[Step (iii)]

Next, the exposed resist film is subjected to a developing treatment. The developing treatment is carried out using an alkali developing solution in a case of an alkali developing process, and a developing solution containing an organic solvent (organic developing solution) in a case of a solvent developing process.

After the developing treatment, it is preferable to conduct a rinse treatment. As the rinse treatment, water rinsing using pure water is preferable in a case of an alkali developing process, and rinsing using a rinse liquid containing an organic solvent is preferable in a case of a solvent developing process.

In a case of a solvent developing process, after the developing treatment or the rinse treatment, the developing solution or rinse liquid that adheres on the pattern may be removed by a treatment using a supercritical fluid.

After the developing treatment or the rinse treatment, drying is conducted. As desired, baking treatment (post-baking) can be carried out following the developing treatment.

The support is not specifically limited and a known support in the related art can be used. For example, substrates for electronic components, and such substrates having a predetermined wiring pattern formed thereon can be used. Specific examples of the material of the substrate include metals such as silicon wafer, copper, chromium, iron and aluminum; and glass. Suitable materials for the wiring pattern include copper, aluminum, nickel, and gold.

In addition, as the support, any support having the above-described substrate on which an inorganic and/or organic film is provided may be used. Examples of the inorganic film include an inorganic antireflection film (an inorganic BARC). Examples of the organic film include an organic antireflection film (organic BARC) and an organic film such as a lower-layer organic film used in a multilayer resist method.

Here, the multilayer resist method is a method in which at least one layer of an organic film (lower-layer organic film) and at least one layer of a resist film (upper-layer resist film) are provided on a substrate, and a resist pattern formed on the upper-layer resist film is used as a mask to conduct patterning of the lower-layer organic film. This method is considered as being capable of forming a pattern with a high aspect ratio. More specifically, in the multilayer resist method, a desired thickness can be ensured by the lower-layer organic film, and as a result, the thickness of the resist film can be reduced, and an extremely fine pattern with a high aspect ratio can be formed.

The multilayer resist method is basically classified into a method in which a double-layer structure consisting of an upper-layer resist film and a lower-layer organic film is formed (double-layer resist method), and a method in which a multilayer structure having three or more layers consisting of an upper-layer resist film, a lower-layer organic film, and one or more intermediate layers (thin metal films or the like) provided between the upper-layer resist film and the lower-layer organic film (triple-layer resist method).

The wavelength to be used for exposure is not particularly limited, and the exposure can be carried out using radiation such as an ArF excimer laser, a KrF excimer laser, an F₂ excimer laser, an extreme ultraviolet ray (EUV), a vacuum ultraviolet ray (VUV), an electron beam (EB), an X-ray, or a soft X-ray.

The resist pattern forming method according to the present embodiment is useful particularly for a method in which a resist film is exposed by an extreme ultraviolet ray (EUV) or an electron beam (EB) in the above-described step of exposing the resist film.

The exposure method for a resist film may be a general exposure (dry exposure) carried out in air or an inert gas such as nitrogen, or liquid immersion lithography.

The liquid immersion lithography is an exposure method in which the region between the resist film and the lens at the lowermost position of the exposure apparatus is pre-filled with a solvent (liquid immersion medium) that has a larger refractive index than the refractive index of air, and the exposure (immersion exposure) is carried out in this state.

As the liquid immersion medium, a solvent that exhibits a refractive index larger than the refractive index of air but smaller than the refractive index of the resist film to be exposed is preferable. The refractive index of the solvent is not particularly limited as long as it is in the above-described range.

Examples of the solvent which exhibits a refractive index that is larger than the refractive index of air but smaller than the refractive index of the resist film include water, a fluorine-based inert liquid, a silicon-based solvent, and a hydrocarbon-based solvent.

Specific examples of the fluorine-based inert liquids include liquids containing a fluorine-based compound such as C₃HCl₂F₅, C₄F₉OCH₃, C₄F₉₀C₂H₅, or C₅H₃F₇ as the main component, and the boiling point is preferably in a range of 70° to 180° C. and more preferably in a range of 800 to 160° C. A fluorine-based inert liquid having a boiling point in the above-described range is advantageous in that removing the medium used in the liquid immersion after the completion of exposure can be preferably carried out by a simple method.

The fluorine-based inert liquid is preferably a perfluoroalkyl compound in which all of the hydrogen atoms of the alkyl group are substituted with a fluorine atom. Specific examples of these perfluoroalkyl compounds include perfluoroalkyl ether compounds and perfluoroalkyl amine compounds.

Further, specifically, examples of the perfluoroalkyl ether compound include perfluoro(2-butyl-tetrahydrofuran) (boiling point: 102° C.), and examples of the perfluoroalkyl amine compound include perfluorotributyl amine (boiling point: 174° C.).

As the liquid immersion medium, water is preferable in terms of cost, safety, environment, and versatility.

Examples of the alkali developing solution used for a developing treatment in an alkali developing process include an aqueous solution of tetramethylammonium hydroxide (TMAH) of 0.1% to 10% by mass.

As the organic solvent contained in the organic developing solution, which is used for a developing treatment in a solvent developing process, any one of the conventionally known organic solvents capable of dissolving the component (A) (component (A) prior to exposure) can be appropriately selected from the conventionally known organic solvents. Specific examples of the organic solvent include polar solvents such as a ketone-based solvent, an ester-based solvent, an alcohol-based solvent, a nitrile-based solvent, an amide-based solvent, an ether-based solvent, and a hydrocarbon-based solvent.

A ketone-based solvent is an organic solvent containing C—C(═O)—C in the structure thereof. An ester-based solvent is an organic solvent containing C—C(═O)—O—C in the structure thereof. An alcohol-based solvent is an organic solvent containing an alcoholic hydroxyl group in the structure thereof. The term “alcoholic hydroxyl group” indicates a hydroxyl group bonded to a carbon atom of an aliphatic hydrocarbon group. A nitrile-based solvent is an organic solvent containing a nitrile group in the structure thereof. An amide-based solvent is an organic solvent containing an amide group in the structure thereof. An ether-based solvent is an organic solvent containing C—O—C in the structure thereof.

Some organic solvents have a plurality of the functional groups which characterize the above-described solvents in the structure thereof. In such a case, the organic solvent can be classified as any type of solvent having a functional group that characterizes a solvent. For example, diethylene glycol monomethyl ether can be classified as an alcohol-based solvent or an ether-based solvent.

A hydrocarbon-based solvent consists of a hydrocarbon which may be halogenated and does not have any substituent other than a halogen atom. The halogen atom is preferably a fluorine atom.

Among the above, the organic solvent contained in the organic developing solution is preferably a polar solvent and more preferably a ketone-based solvent, an ester-based solvent, or a nitrile-based solvent.

Examples of the ketone-based solvent include 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetylcarbinol, acetophenone, methyl naphthyl ketone, isophorone, propylene carbonate, γ-butyrolactone, and methylamyl ketone (2-heptanone). Among these examples, the ketone-based solvent is preferably methylamyl ketone (2-heptanone).

Examples of the ester-based solvent include methyl acetate, butyl acetate, ethyl acetate, isopropyl acetate, amyl acetate, isoamyl acetate, ethyl methoxyacetate, ethyl ethoxyacetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Among these, the ester-based solvent is preferably butyl acetate.

Examples of the nitrile-based solvent include acetonitrile, propionitrile, valeronitrile, and butyronitrile.

As desired, the organic developing solution may have a conventionally known additive blended. Examples of the additive include surfactants. The surfactant is not particularly limited; however, for example, an ionic or non-ionic fluorine-based and/or a silicon-based surfactant can be used.

The developing treatment can be carried out by a conventionally known developing method. Examples thereof include a method in which the support is immersed in the developing solution for a predetermined time (a dip method), a method in which the developing solution is cast upon the surface of the support by surface tension and maintained for a predetermined time (a puddle method), a method in which the developing solution is sprayed onto the surface of the support (spray method), and a method in which a developing solution is continuously ejected from a developing solution ejecting nozzle and applied onto a support, which is being rotated at a constant rate while being scanned at a constant rate (dynamic dispense method).

As the organic solvent contained in the rinse liquid used in the rinse treatment after the developing treatment in a case of a solvent developing process, for example, an organic solvent hardly dissolving the resist pattern can be appropriately selected and used, among the organic solvents mentioned as organic solvents that are used for the organic developing solution. In general, at least one kind of solvent selected from a hydrocarbon-based solvent, a ketone-based solvent, an ester-based solvent, an alcohol-based solvent, an amide-based solvent, and an ether-based solvent is used.

As the organic solvent, one kind of solvent may be used alone, or two or more kinds of solvents may be used in combination. In addition, an organic solvent other than the above-described examples or water may be mixed thereto.

The rinse treatment using a rinse liquid (washing treatment) can be carried out by a conventionally known rinse method. Examples of the rinse treatment method include a method in which the rinse liquid is continuously ejected and applied onto the support while rotating it at a constant rate (rotational coating method), a method in which the support is immersed in the rinse liquid for a predetermined time (dip method), and a method in which the rinse liquid is sprayed onto the surface of the support (spray method).

According to the resist pattern forming method according to the present embodiment described above, since the resist composition according to the first aspect described above is used, it is possible to form a fine-sized pattern having both etching resistance and lithography characteristics. For example, even in the lithography by EUV, it is possible to form a fine pattern in a range of ten and several nm, which has excellent fine resolution and sufficient etching resistance. In a case of a line and space pattern (an LS pattern), it is possible to easily form an LS pattern having a reduced roughness in the line side wall and having a more uniform width.

In particular, the resist pattern forming method according to the present embodiment is a method useful for subjecting the exposed resist film to alkali development to form a negative-tone resist pattern in the step (iii).

Various materials that are used in the resist composition according to the above-described embodiment and the resist pattern forming method according to the above-described embodiment (for example, a resist solvent, a developing solution, a rinse liquid, a composition for forming an antireflection film, and a composition for forming a top coat) preferably do not contain impurities such as a metal, a metal salt containing halogen, an acid, an alkali, and a component containing a sulfur atom or phosphorus atom. Here, examples of the impurities containing metal atoms include Na, K, Ca, Fe, Cu, Mn, Mg, Al, Cr, Ni, Zn, Ag, Sn, Pb, Li, and salts thereof. The content of the impurities contained in these materials is preferably 200 ppb or less, more preferably 1 ppb or less, still more preferably 100 parts per trillion (ppt) or less, and particularly preferably 10 ppt or less, where it is most preferable that the impurities are substantially free (below the detection limit of the measuring device).

### (Polymer (1))

The polymer according to the third aspect of the present invention contains a siloxane bond and an ionic group represented by General Formula (I0″), which is decomposed upon exposure to generate acid.

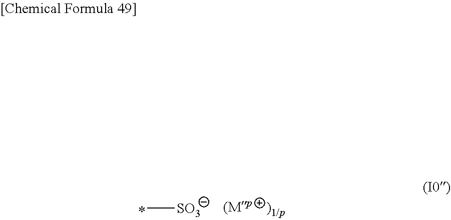

[In the formula, M″^{p+} represents an onium cation or a metal cation. p represents an integer of 1 or more. * represents a bonding site.]

In Formula (I0″), examples of the onium cation as M″^{p+} in the cation moiety ((M″^{p+})_{1/p}) include a sulfonium cation, an iodonium cation, and an ammonium cation.

Examples of the sulfonium cation and the iodonium cation as M″^{p+} in the cation moiety (M″^{p+})_{1/p}) include the same ones as the sulfonium cation and the iodonium cation in the cation moiety (M^{m+})_{1/m}) in General Formula (I0) described above. Examples of the ammonium cation as M″^{p+} include an organic ammonium cation represented by General Formula (ca-4).

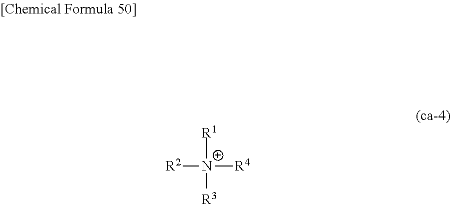

[In the formula, R¹ to R⁴ each independently represent a hydrocarbon group which may have a substituent. Alternatively, at least two of R¹ to R⁴ may be bonded to each other to form an alicyclic structure together with the nitrogen atom in the formula.]

In General Formula (ca-4), The hydrocarbon groups as R¹ to R⁴ are each independently preferably a hydrocarbon group having 1 to 15 carbon atoms and more preferably a hydrocarbon group having 1 to 10 carbon atoms. Further, the total number of carbon atoms in the hydrocarbon group as R¹ to R⁴ is preferably in a range of 1 to 20, more preferably in a range of 3 to 18, and still more preferably in a range of 4 to 15.

Examples of the hydrocarbon group as R¹ to R⁴ include a linear or branched alkyl group and a cyclic hydrocarbon group.

The linear or branched alkyl group is preferably a linear or branched alkyl group having 1 to 10 carbon atoms and more preferably a linear or branched alkyl group having 1 to 5 carbon atoms.

The cyclic hydrocarbon group may be an alicyclic hydrocarbon group or an aromatic hydrocarbon group.

The alicyclic hydrocarbon group is preferably a group obtained by removing one hydrogen atom from a monocycloalkane. The monocycloalkane is preferably a monocycloalkane having 3 to 6 carbon atoms, and specific examples thereof include cyclopentane and cyclohexane. The aromatic hydrocarbon group is preferably a phenyl group or a benzyl group.

Examples of the substituent which may be included in the hydrocarbon group as R¹ to R⁴ include an alkoxy group, a hydroxyl group, an oxo group (═O), and an amino group.

Specific examples of the suitable cation represented by General Formula (ca-4) include cations each represented by Chemical Formulae (ca-4-1) to (ca-4-4) described below.

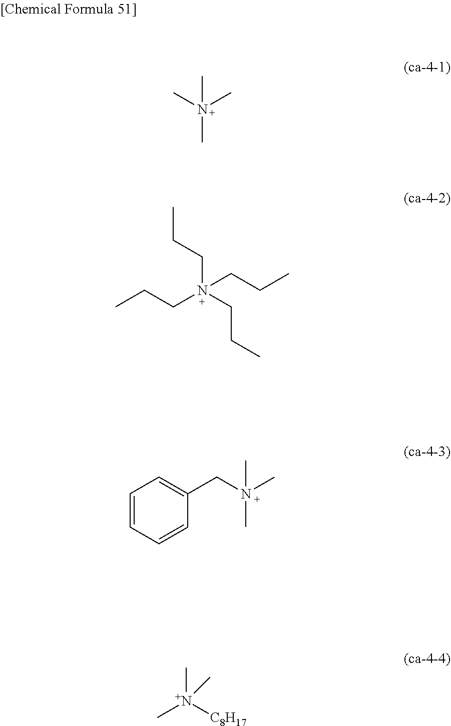

In Formula (I0″), examples of the metal cation as M″^{p+} in the cation moiety ((M″^{p+})_{1/p}) include alkali metal ions such as a sodium ion and a lithium ion; alkaline earth metal ions; and a rubidium ion, a strontium ion, and a yttrium ion.

Examples of the polymer according to the third aspect include the polymer (A1) contained in the resist composition according to the first aspect described above.

In addition, examples of the polymer according to the third aspect also include each of a polymer in which the cation moiety ((M^{m+})_{1/m}) in the polymer (A1) is changed to an ammonium cation and a polymer in which the cation moiety ((M^{m+})_{1/m}) in the polymer (A1) is changed to a metal cation.

The polymer according to the third aspect of the present invention described above can be a resin component useful as a base material component of a resist composition. In addition, the polymer according to the third aspect of the present invention can be a useful compound as an intermediate in a case of producing the resin component (the ammonium salt or the like in Synthesis Example (2) described later).

### (Polymer (2))

The polymer according to the fourth aspect of the present invention contains a siloxane bond and an ionic group represented by General Formula (I0), which is decomposed upon exposure to generate acid.

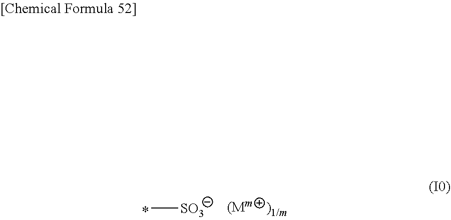

[In the formula, M^{m+} represents a sulfonium cation or an iodonium cation. m represents an integer of 1 or more. * represents a bonding site.]

The polymer according to the fourth aspect is the same as the polymer (A1) contained in the resist composition according to the first aspect described above. Examples of one embodiment of such a polymer include a silsesquioxane resin having a repeating structure of the constitutional unit (a01) and the constitutional unit (a1); a silsesquioxane resin having a repeating structure of the constitutional unit (a02) and the constitutional unit (a1); and a silsesquioxane resin having a repeating structure of the constitutional unit (a01), the constitutional unit (a02), and the constitutional unit (a1).

The polymer (polymer (A1)) according to the fourth aspect can be produced using a known production method. For example, the polymer (polymer (A1)) according to the fourth aspect can be produced by selecting a raw material corresponding to the target polymer as in Synthesis Example (2) described later and using a production method including a first step (condensation or the like), a second step (condensation or the like), and a third step (salt exchange or the like) Such a polymer according to the fourth aspect can be a resin component useful as a base material component of a resist composition.

### EXAMPLES

Hereinafter, the present invention will be described in more detail based on Examples; however, the present invention is not limited to these Examples.

### <Production of Polymer>

According to the following Synthesis Examples (1) to (8), each of a polymer (A2-1) and a polymer (A1-1) to a polymer (A1-7) was produced.

### Synthesis Example (1): Production of polymer (A2-1)

60 g of isopropyl alcohol, 30 g of toluene, 7 g of pure water, and 2 g of an aqueous solution of 25% tetramethylammonium were mixed to be uniform, and then 60 g of 4-methoxytrimethoxysilane was added dropwise thereto over 5 minutes while carrying out stirring. Then, the resultant mixture was subjected to stirring and heating at 40° C. for 3 hours while carrying out stirring. After carrying out cooling to room temperature, 300 g of toluene and 90 g of water were added to the stirred and heated solution, and the resultant mixture was stirred and then allowed to stand to remove the aqueous phase. Thereafter, 39 g of an aqueous solution of 1% acetic acid was added thereto, and the resultant mixture was stirred and then allowed to stand to remove the aqueous layer, and further, washing was carried out three times with 60 g of pure water. The obtained organic layer was subjected to concentration and drying with a rotary evaporator. Then, 90 g of toluene was added thereto, and concentration and drying were carried out using a rotary evaporator, which was repeated three times to obtain a viscous material. 67 g of sodium iodide, 67 g of trimethylsilyl chloride, 180 g of dewatered acetonitrile, and 45 g of dewatered toluene were added thereto, and the resultant mixture was heated at 55° C. for 36 hours while carrying out stirring. After carrying out cooling to room temperature and then carrying out cooling in an ice bath, 67 g of pure water was added dropwise thereto over 5 minutes while carrying out stirring in an ice bath. Then, 224 g of an aqueous solution of 30% sodium hydrogen sulfite was added thereto, and stirring was carried out at room temperature for 30 minutes. The obtained solution was allowed to stand to remove an aqueous layer. Then, 180 g of methyl isobutyl ketone and 90 g of pure water were added thereto, and then the aqueous layer was removed. 45 g of pure water was added to the obtained organic layer, the resultant mixture was stirred and heated at 60° C. for 1 hour and then allowed to stand to remove an aqueous layer, and further, washing was carried out three times with 45 g of pure water. The obtained organic phase was subjected to concentration and drying with a rotary evaporator, 112 g of methyl isobutyl ketone was subsequently added thereto, and concentration and drying were carried out using a rotary evaporator, which was repeated three times. Then, methyl isobutyl ketone was added thereto and dissolved so that the concentration was 50%, whereby 72 g of a 50% methyl isobutyl ketone solution of a target polymer (A2-1) (having a trimethylsilyl group as a terminal structure) was obtained.

Regarding the obtained polymer (A2-1), it was confirmed that the weight average molecular weight (Mw) in terms of the standard polystyrene equivalent value, which is measured by GPC, is 5,100, and the molecular weight polydispersity (Mw/Mn) is 1.48, and ¹³C-NMR gives the following structure (the proportion (in terms of molar ratio) between the constitutional units in the structural formula is 1=100).

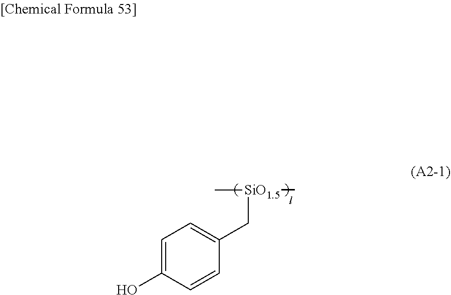

### Synthesis Example (2): Production of Polymer (A1-1)

### First Step:

2 g of 1,1-difluoro-2-hydroxyethanesulfonic acid benzyltrimethylammonium salt, 0.86 g of phthalic anhydride, 0.08 g of 4-dimethylaminopyridine, and 6 g of dewatered N,N-dimethylformamide were added and made to be uniform, and then the resultant mixture was stirred at room temperature for 5 hours.

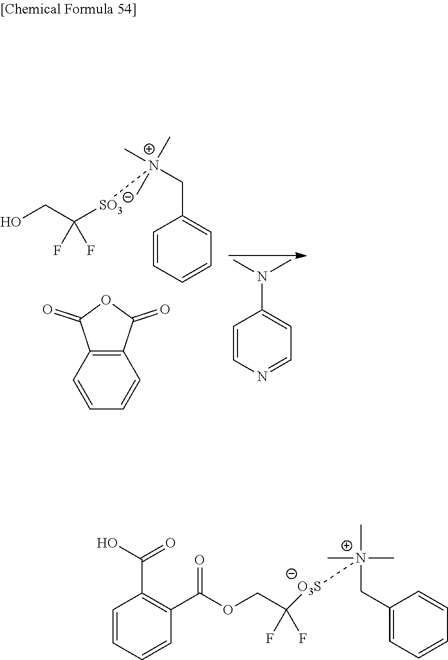

### Second Step:

After the first step, 8.0 g of a 50% methyl isobutyl ketone solution of the polymer (A2-1) (having a trimethylsilyl group as a terminal structure) and 4 g of dewatered N,N-dimethylformamide were added, 0.73 g of diisopropylcarbodiimide was added dropwise thereto over 5 minutes while carrying out ice-cooling and stirring, the resultant mixture was stirred for 30 minutes while being subjected ice-cooling as it was, and further, the temperature thereof was returned to room temperature, followed by stirring for 12 hours. 70 g of methyl isobutyl ketone, 30 g of isopropyl alcohol, 95 g of pure water, and 5 g of an aqueous solution of 1% hydrochloric acid were added to the obtained solution. and the resultant mixture was stirred and then allowed to stand to remove an aqueous layer. Thereafter, washing was carried out three times with 40 g of a solution of pure water:isopropyl alcohol=9:1 to obtain an organic layer containing an intermediate.

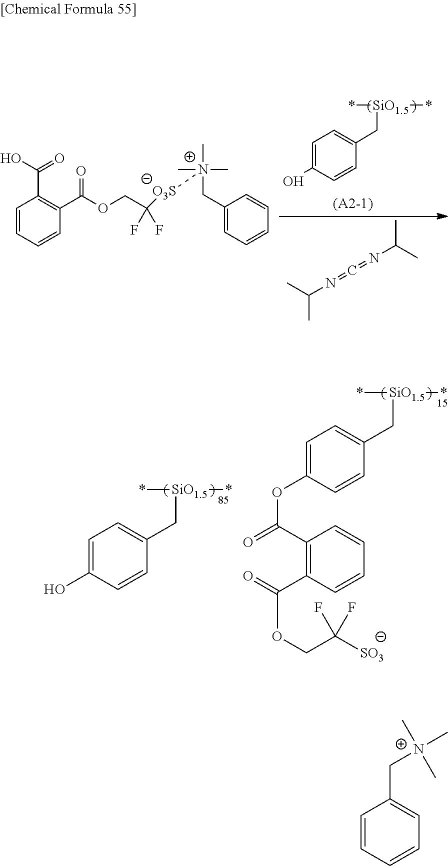

### Third Step:

40 g of an aqueous solution of600 bis(3,5-difluorophenyl)phenylsulfonium hydrochloride and 4 g of isopropyl alcohol were added to the obtained organic layer, and the resultant mixture was stirred for 30 minutes and then allowed to stand still to remove the aqueous layer. Thereafter, 4 g of an aqueous solution of 6% bis(3,5-difluorophenyl)phenylsulfonium hydrochloride, 2 g of isopropyl alcohol, and 18 g of pure water were added to the obtained organic layer, and the resultant mixture was stirred for 5 minutes and then allowed to stand still to remove the aqueous layer, which was repeated five times.

The obtained solution was subjected to concentration and drying with a rotary evaporator, 50 g of propylene glycol monomethyl ether was subsequently added thereto, and concentration and drying were carried out using a rotary evaporator, which was repeated three times. Then, propylene glycol monomethyl ether was added thereto and dissolved so that the concentration was 10%, whereby a 10% propylene glycol monomethyl ether solution of the polymer (A1-1) (having a trimethylsilyl group as a terminal structure) was obtained.

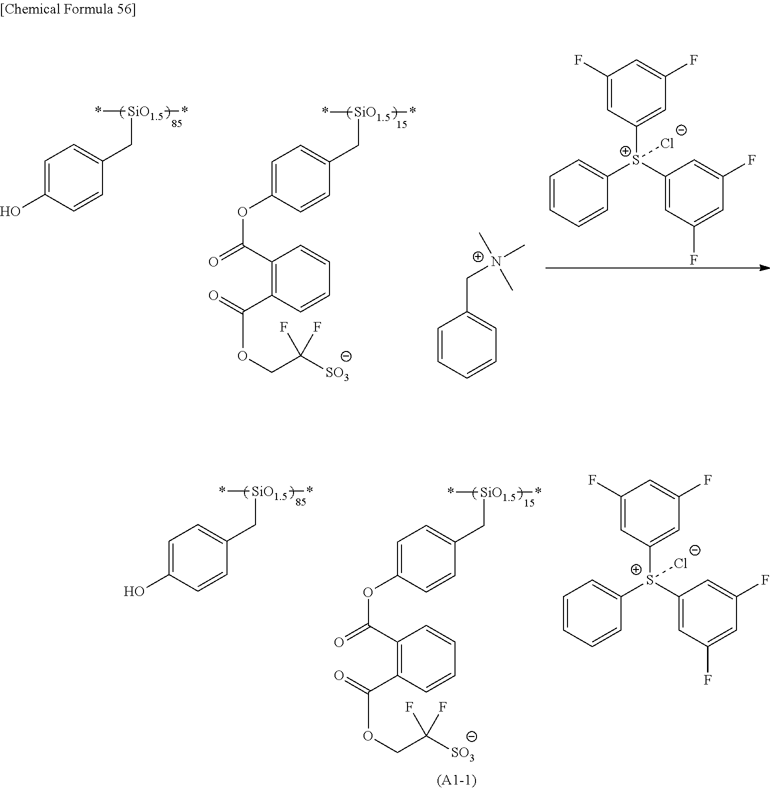

Regarding the obtained polymer (A1-1), it was confirmed that the weight average molecular weight (Mw) in terms of the standard polystyrene equivalent value, which is measured by GPC, is 8,900, and the molecular weight polydispersity (Mw/Mn) is 1.87, and the analysis by ¹³C-NMR and ¹⁹F-NMR gives the following structure (the proportion (in terms of molar ratio) between the constitutional units in the structural formula is 1/m=85/15).

¹³C-NMR (600 MHZ, acetone)

a→0.85C, 155 ppm

b→0.15C, 149 ppm

c+d→0.3C, 167 ppm

¹⁹F-NMR (400 MHz, DMSO)

A*2→0.3 F, −114 ppm

B*4→0.6 F, −104 ppm

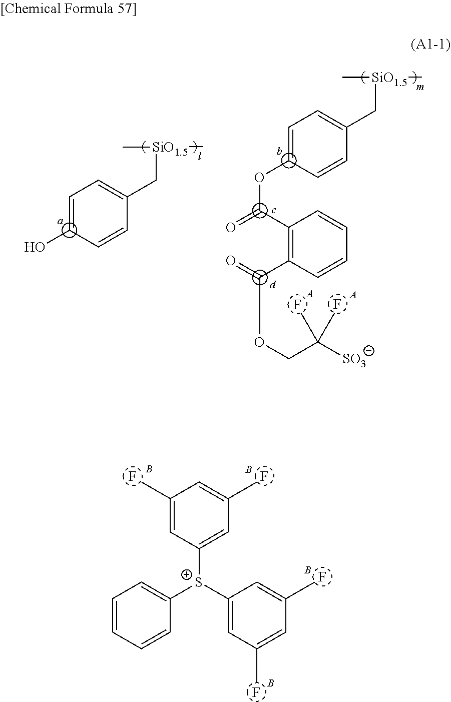

### Synthesis Example (3): Production of Polymer (A1-2)

The operation was carried out in the same manner as in Synthesis Example (2) to obtain a 10% propylene glycol monomethyl ether solution of the polymer (A1-2) (having a trimethylsilyl group as a terminal structure), except that in Synthesis Example (2) described above, 8.0 g of the 50% methyl isobutyl ketone solution of the polymer (A2-1) (having a trimethylsilyl group as a terminal structure) was changed to 12.0 g and 4 g of the dewatered N,N-dimethylformamide was changed to 6 g.

Regarding the obtained polymer (A1-2), it was confirmed that the weight average molecular weight (Mw) in terms of the standard polystyrene equivalent value, which is measured by GPC, is 7,100, and the molecular weight polydispersity (Mw/Mn) is 1.65, and the analysis by ¹³C-NMR and ¹⁹F-NMR gives the following structure (the proportion (in terms of molar ratio) between the constitutional units in the structural formula is 1/m=90/10).

¹³C-NMR (600 MHZ, acetone)

a→0.9C, 155 ppm

b→0.1C, 149 ppm

c+d→0.2C, 167 ppm

¹⁹F-NMR (400 MHz, DMSO)

A*2→0.2 F, −114 ppm

B*4→0.4 F, −104 ppm

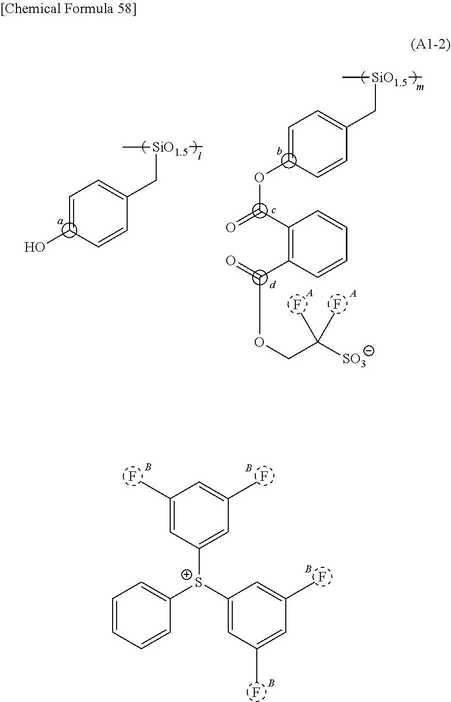

### Synthesis Example (4): Production of Polymer (A1-3)

The operation was carried out in the same manner as in Synthesis Example (2) to obtain a 10% propylene glycol monomethyl ether solution of the polymer (A1-3) (having a trimethylsilyl group as a terminal structure), except that in Synthesis Example (2) described above, 40 g of the aqueous solution of 6% bis(3,5-difluorophenyl)phenylsulfonium hydrochloride was changed to 33 g of an aqueous solution of 6% triphenylsulfonium hydrochloride; and 4 g of the aqueous solution of 6% bis(3,5-difluorophenyl)phenylsulfonium hydrochloride was changed to 4 g of an aqueous solution of 6% triphenylsulfonium hydrochloride.

Regarding the obtained polymer (A1-3), it was confirmed that the weight average molecular weight (Mw) in terms of the standard polystyrene equivalent value, which is measured by GPC, is 8,900, and the molecular weight polydispersity (Mw/Mn) is 1.86, and the analysis by ¹³C-NMR and ¹⁹F-NMR gives the following structure (the proportion (in terms of molar ratio) between the constitutional units in the structural formula is 1/m=85/15).

¹³C-NMR (600 MHZ, acetone)

a→0.85C, 155 ppm

b→0.15C, 149 ppm

c+d→0.3C, 167 ppm

¹⁹F-NMR (400 MHz, DMSO)

A*2→0.3 F, −114 ppm

* It was confirmed that a triphenylsulfonium form is obtained since the peak of the benzyltrimethylammonium form has disappeared.

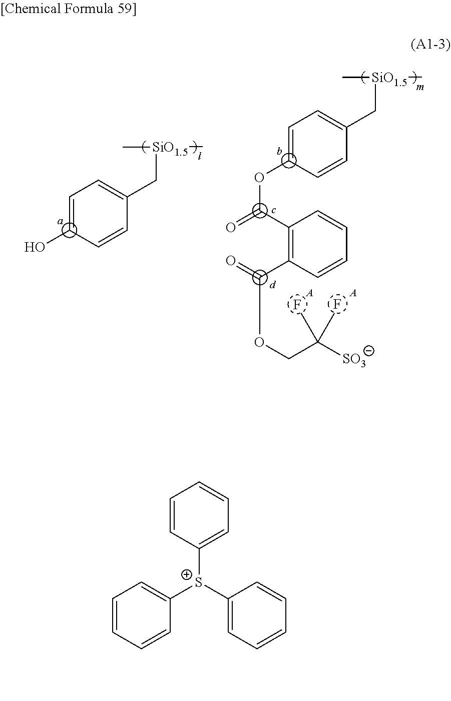

### Synthesis Example (5): Production of Polymer (A1-4)

The operation was carried out in the same manner as in Synthesis Example (2) to obtain a 10% propylene glycol monomethyl ether solution of the polymer (A1-4) (having a trimethylsilyl group as a terminal structure), except that in Synthesis Example (2) described above, 40 g of the aqueous solution of 6% bis(3,5-difluorophenyl)phenylsulfonium hydrochloride was changed to 30 g of an aqueous solution of 6% diphenyliodonium hydrochloride; and 40 g of the aqueous solution of 6% bis(3,5-difluorophenyl)phenylsulfonium hydrochloride was changed to 4 g of an aqueous solution of 6% diphenyliodonium hydrochloride.

Regarding the obtained polymer (A1-4), it was confirmed that the weight average molecular weight (Mw) in terms of the standard polystyrene equivalent value, which is measured by GPC, is 8,600, and the molecular weight polydispersity (Mw/Mn) is 1.81, and the analysis by ¹³C-NMR and ¹⁹F-NMR gives the following structure (the proportion (in terms of molar ratio) between the constitutional units in the structural formula is 1/m=85/15).

¹³C-NMR (600 MHZ, acetone)

a→0.85C, 155 ppm

b→0.15C, 149 ppm

c+d→0.3C, 167 ppm

¹⁹F-NMR (400 MHz, DMSO)

A*2→0.3 F, −114 ppm

* It was confirmed that a diphenyliodonium form is obtained since the peak of the benzyltrimethylammonium form has disappeared.

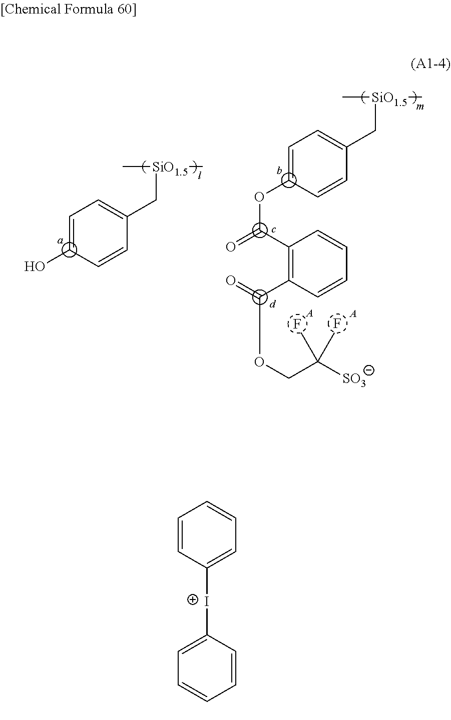

### Synthesis Example (6): Production of Polymer (A1-5)

The operation was carried out in the same manner as in Synthesis Example (2) to obtain a 10% propylene glycol monomethyl ether solution of the polymer (A1-5) (having a trimethylsilyl group as a terminal structure), except that in Synthesis Example (2) described above, 0.86 g of phthalic anhydride was changed to 0.58 g of succinic anhydride.

Regarding the obtained polymer (A1-5), it was confirmed that the weight average molecular weight (Mw) in terms of the standard polystyrene equivalent value, which is measured by GPC, is 11,000, and the molecular weight polydispersity (Mw/Mn) is 2.00, and the analysis by ¹³C-NMR and ¹⁹F-NMR gives the following structure (the proportion (in terms of molar ratio) between the constitutional units in the structural formula is 1/m=85/15).

¹³C-NMR (600 MHZ, acetone)

a→0.85C, 155 ppm

b→0.15C, 149 ppm

c+d→0.3C, 167 ppm

¹⁹F-NMR (400 MHz, DMSO)

A*2→0.3 F, −114 ppm

B*4→0.6 F, −104 ppm

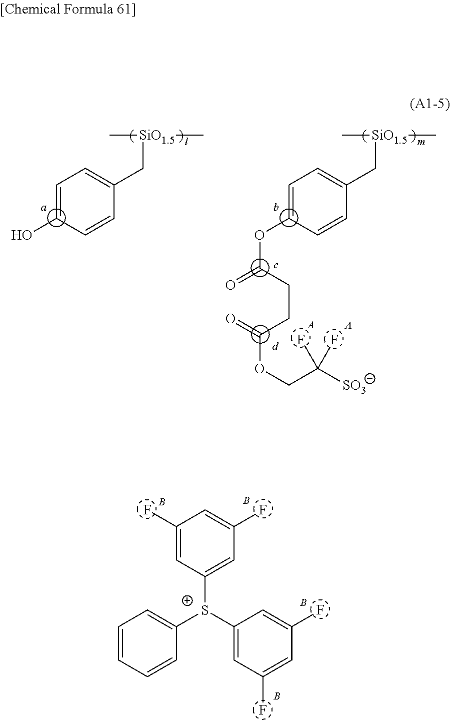

### Synthesis Example (7). Production of Polymer (A1-6)

The operation was carried out in the same manner as in Synthesis Example (2) to obtain a 10% propylene glycol monomethyl ether solution of the polymer (A1-6) (having a trimethylsilyl group as a terminal structure), in Synthesis Example (2) described above, 0.86 g of phthalic anhydride was changed to 1.58 g of 3-iodophthalic anhydride.

Regarding the obtained polymer (A1-6), it was confirmed that the weight average molecular weight (Mw) in terms of the standard polystyrene equivalent value, which is measured by GPC, is 9,200, and the molecular weight polydispersity (Mw/Mn) is 1.90, and the analysis by ¹³C-NMR and ¹⁹F-NMR gives the following structure (the proportion (in terms of molar ratio) between the constitutional units in the structural formula is 1/m=85/15).

¹³C-NMR (600 MHZ, acetone)

a→0.85C, 155 ppm

b→0.15C, 149 ppm

c+d→0.3C, 167 ppm

¹⁹F-NMR (400 MHz, DMSO)

A*2→0.3 F, −114 ppm

B*4→0.6 F, −104 ppm

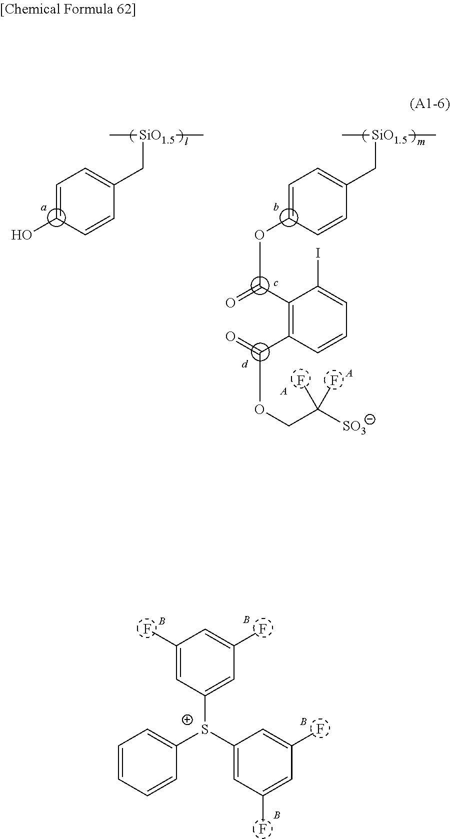

### Synthesis Example (8): Production of Polymer (A1-7)

1.1 g of 2,3,5,6-tetrafluoro-4-sulfoxybenzoic acid and 4.4 g of methanol were mixed to be uniform, and then 0.83 g of a methanol solution of 40% benzyltrimethylammonium hydroxide was added dropwise thereto over 5 minutes while carrying out ice-cooling and stirring. The obtained solution was subjected to concentration and drying with a rotary evaporator and washed three times with 10 g of acetonitrile. 6 g of dewatered N,N-dimethylformamide was added to 1.3 g of the obtained solid, the resultant mixture was stirred to be uniform.

11.2 g of a 50% methyl isobutyl ketone solution of the polymer (A2-1) (having a trimethylsilyl group as a terminal structure) and 6 g of dewatered N,N-dimethylformamide were added thereto, 0.73 g of diisopropylcarbodiimide was added dropwise thereto over 5 minutes while carrying out ice-cooling and stirring, the resultant mixture was stirred for 30 minutes while being subjected ice-cooling as it was, and further, the temperature thereof was returned to room temperature, followed by stirring for 12 hours. 70 g of methyl isobutyl ketone, 30 g of isopropyl alcohol, 95 g of pure water, and 5 g of an aqueous solution of 1% hydrochloric acid were added to the obtained solution, and the resultant mixture was stirred and then allowed to stand to remove an aqueous layer. Thereafter, washing was carried out three times with 40 g of a solution of pure water:isopropyl alcohol=9:1.

40 g of an aqueous solution of 6% bis(3,5-difluorophenyl)phenylsulfonium hydrochloride and 4 g of isopropyl alcohol were added to the obtained organic layer, and the resultant mixture was stirred for 30 minutes and then allowed to stand still to remove the aqueous layer. Thereafter, 4 g of an aqueous solution of 6% bis(3,5-difluorophenyl)phenylsulfonium hydrochloride, 2 g of isopropyl alcohol, and 18 g of pure water were added to the obtained organic layer, and the resultant mixture was stirred for 5 minutes and then allowed to stand still to remove the aqueous layer, which was repeated five times. The obtained solution was subjected to concentration and drying with a rotary evaporator, 50 g of propylene glycol monomethyl ether was subsequently added thereto, and concentration and drying were carried out using a rotary evaporator, which was repeated three times. Then, propylene glycol monomethyl ether was added thereto and dissolved so that the concentration was 10%, whereby a 10% propylene glycol monomethyl ether solution of the polymer (A1-7) (having a trimethylsilyl group as a terminal structure) was obtained.

Regarding the obtained polymer (A1-7), it was confirmed that the weight average molecular weight (Mw) in terms of the standard polystyrene equivalent value, which is measured by GPC, is 7,000, and the molecular weight polydispersity (Mw/Mn) is 1.61, and the analysis by ¹³C-NMR and ¹⁹F-NMR gives the following structure (the proportion (in terms of molar ratio) between the constitutional units in the structural formula is 1/m=85/15).

¹³C-NMR (600 MHZ, acetone)

a→0.85C, 155 ppm

b→0.15C, 149 ppm

c→0.15C, 172 ppm

¹⁹F-NMR (400 MHz, DMSO)

A*4→0.6 F, −139 ppm

B *4→0.6 F, −104 ppm

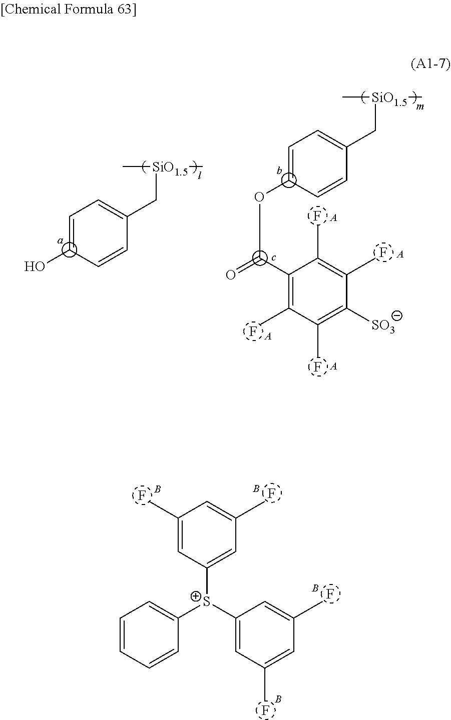

### <Preparation of Resist Composition>

### Examples 1 to 14 and Comparative Examples 1 and 2

Each of the components shown in Table 1 was mixed and dissolved to prepare a resist composition of each Example.

TABLE 1

| | Component | Component | Component | Component | | | | |
|---|---|---|---|---|---|---|---|---|
| | (A) | (D) | (C) | (E) | Component (S) | | Component (B) | |
| Example 1 | (A)-1 | (D)-1 | (C)-1 | (E)-1 | (S)-1 | (S)-2 | — | — |
| | [100] | [32] | [10] | [3] | [15800] | [4000] | | |
| Example 2 | (A)-2 | (D)-1 | (C)-1 | (E)-1 | (S)-1 | (S)-2 | — | — |
| | [100] | [32] | [10] | [3] | [15800] | [4000] | | |
| Example 3 | (A)-2 | (D)-1 | (C)-1 | (E)-1 | (S)-1 | (S)-2 | — | — |
| | [100] | [22] | [10] | [3] | [15800] | [4000] | | |
| Example 4 | (A)-3 | (D)-1 | (C)-1 | (E)-1 | (S)-1 | (S)-2 | — | — |
| | [100] | [32] | [10] | [3] | [15800] | [4000] | | |
| Example 5 | (A)-4 | (D)-1 | (C)-1 | (E)-1 | (S)-1 | (S)-2 | — | — |
| | [100] | [32] | [10] | [3] | [15800] | [4000] | | |
| Example 6 | (A)-5 | (D)-1 | (C)-1 | (E)-1 | (S)-1 | (S)-2 | — | — |
| | [100] | [32] | [10] | [3] | [15800] | [4000] | | |
| Example 7 | (A)-6 | (D)-1 | (C)-1 | (E)-1 | (S)-1 | (S)-2 | — | — |
| | [100] | [32] | [10] | [3] | [15800] | [4000] | | |
| Example 8 | (A)-7 | (D)-1 | (C)-1 | (E)-1 | (S)-1 | (S)-2 | — | — |
| | [100] | [32] | [10] | [3] | [15800] | [4000] | | |
| Example 9 | (A)-1 | (D)-2 | (C)-1 | (E)-1 | (S)-1 | (S)-2 | — | — |
| | [100] | [21] | [10] | [3] | [15800] | [4000] | | |
| Example 10 | (A)-5 | (D)-2 | (C)-1 | (E)-1 | (S)-1 | (S)-2 | — | — |
| | [100] | [21] | [10] | [3] | [15800] | [4000] | | |
| Example 11 | (A)-6 | (D)-2 | (C)-1 | (E)-1 | (S)-1 | (S)-2 | — | — |
| | [100] | [21] | [10] | [3] | [15800] | [4000] | | |
| Example 12 | (A)-1 | (D)-1 | (C)-2 | (E)-1 | (S)-1 | (S)-2 | — | — |
| | [100] | [32] | [10] | [3] | [15800] | [4000] | | |
| Example 13 | (A)-5 | (D)-1 | (C)-1 | (E)-1 | (S)-1 | (S)-2 | — | — |
| | [100] | [32] | [10] | [3] | [15800] | [4000] | | |
| Example 14 | (A)-6 | (D)-1 | (C)-1 | (E)-1 | (S)-1 | (S)-2 | — | — |
| | [100] | [32] | [10] | [3] | [15800] | [4000] | | |
| Comparative | (A)-0 | (D)-1 | (C)-1 | (E)-1 | (S)-1 | (S)-2 | (B)-1 | — |
| Example 1 | [100] | [39] | [10] | [3] | [15800] | [4000] | [36] | |
| Comparative | (A)-8 | (D)-3 | — | — | (S)-1 | (S)-2 | (B)-2 | (B)-3 |
| Example 2 | [100] | [4] | | | [15800] | [4000] | [4] | [15] |

In Table 1, each abbreviation has the following meaning. The numerical values in the brackets are blending amounts (parts by mass).

(A)-1 to (A)-7: The polymer (A1-1) to the polymer (A1-7) described above

(A)-0: The polymer (A2-1) described above

(A)-8: A polymer represented by Chemical Formula (A2-2) described later. As a result of a GPC measurement to determine the weight average molecular weight (Mw) in terms of the standard polystyrene equivalent value, this polymer (A2-2) has a weight average molecular weight of 7,800 and a molecular weight polydispersity (Mw/Mn) of 1.45. The copolymerization compositional ratio (the proportion (in terms of molar ratio) between the constitutional units in the structural formula) determined by ¹³C-NMR is l/m/n/o/p=6/21/31/28/14.

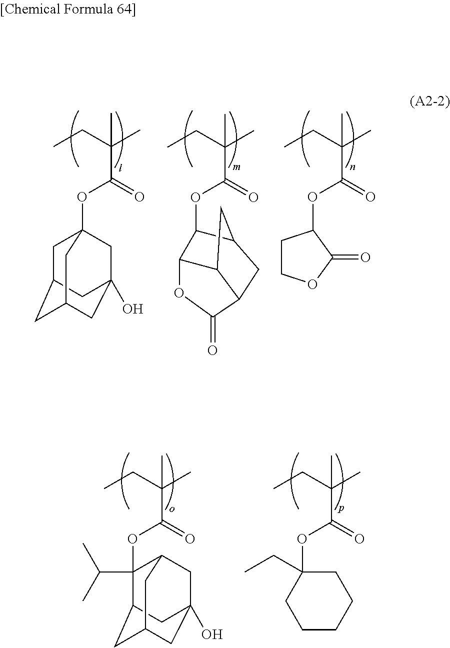

(D)-1: An acid diffusion control agent consisting of the following compound (D1-1)

(D)-2: An acid diffusion control agent consisting of the following compound (D1-2)

(D)-3: An acid diffusion control agent consisting of the following compound (D2-1)

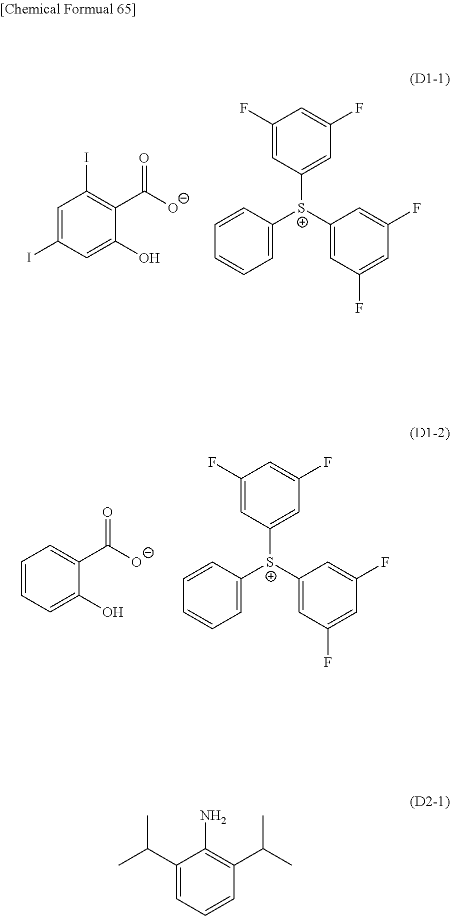 [SMILES: O=C([O-])c1c(O)cc(I)cc1I ; Fc1cc(F)cc([S+](c2ccccc2)c2cc(F)cc(F)c2)c1 ; O=C([O-])c1ccccc1O ; Fc1cc(F)cc([S+](c2ccccc2)c2cc(F)cc(F)c2)c1 ; CC(C)c1cccc(C(C)C)c1N]

(C)-1: A crosslinking agent consisting of the following compound (C-1)

(C)-2: A crosslinking agent consisting of the following compound (C-2)

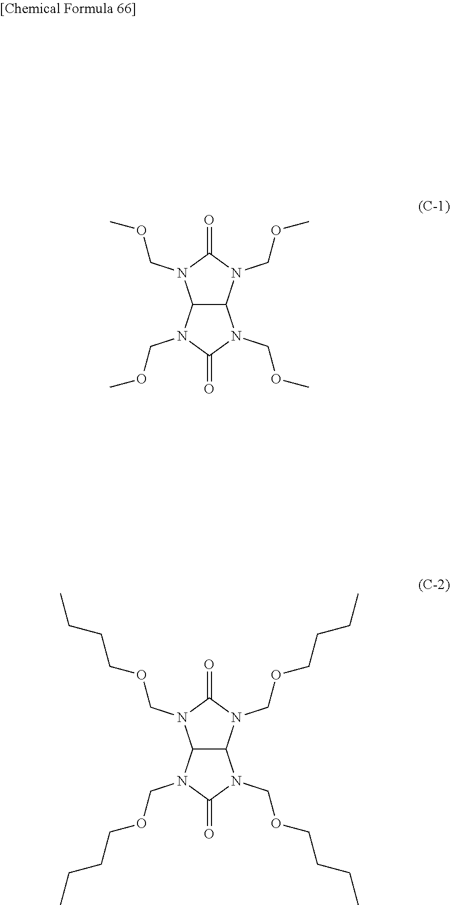

(E)-1: Salicylic acid

(S)-1: Propylene glycol monomethyl ether

(S)-2: Propylene glycol monomethyl ether acetate

(B)-1: An acid generator consisting of the following compound (B1-1)

(B)-2: An acid generator consisting of the following compound (B2-1)

(B)-3: An acid generator consisting of the following compound (B1-2)

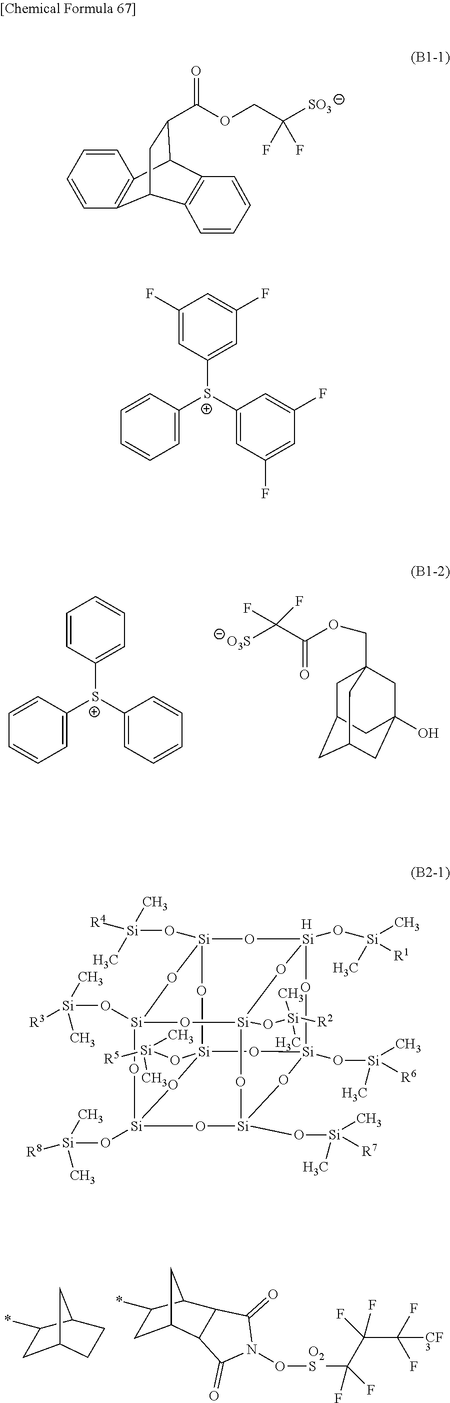

* R¹ to R⁸ are any of the two kinds of terminal structures described above. Each of the two kinds of terminal structures is introduced by 50%. * represents a bonding site to Si.

### <Resist Pattern Formation>

A resist organic underlayer film composition “AL412”, (manufactured by Brewer Science Inc.) was applied onto a 12-inch silicon wafer using a spin coater and sintered and dried on a hot plate at 205° C. for 60 seconds to form an organic underlayer film having a film thickness of 20 nm.

A resist composition was applied onto the organic underlayer film using a spin coater, and a pre-baking (PAB) treatment was carried out at 90° C. for 60 seconds on a hot plate to form a resist film having a film thickness of 22 nm.

The resist film was irradiated with EUV light (13.5 nm) through a photomask by an EUV exposure apparatus NXE3400 (manufactured by ASML Holding N.V., numerical aperture (NA)=0.33, illumination conditions: annular σ-in =0.60, σ-out=0.82).

Then, PEB treatment was carried out at 90° C. for 60 seconds.

Next, alkali development was carried out with a 2.38% by mass TMAH aqueous solution (trade name: NMD-3, manufactured by Tokyo Ohka Kogyo Co., Ltd.) at 23° C. for 10 seconds.

Thereafter, water rinsing was carried out for 30 seconds using pure water, followed by shake-off drying.

As a result, a line and space pattern (an LS pattern) having a line width of 14 nm was formed.

### [Evaluation of Optimum Exposure Amount (Eop)]

According to the resist pattern formation described above, an optimum exposure amount Eop (mJ/cm²) for forming an LS pattern having a line width of 14 nm was determined.

### [Evaluation of Linewise Roughness (LWR)]

For the LS pattern having a line width of 14 nm formed in <<Resist pattern formation>> described above, 3a, which is a scale indicating LWR, was determined.

“3σ” indicates a triple value (unit: nm) of the standard deviation (σ) determined from measurement results obtained by measuring 400 line positions in the longitudinal direction of the line with a scanning electron microscope (acceleration voltage: 800V, product name: S-9380, manufactured by Hitachi High-Tech Corporation).

The smaller the value of 36 is, the smaller the roughness in the line side wall is, which means an LS pattern having a more uniform width was obtained.

TABLE 2

| | PAB | PEB | Eop | LWR |
|---|---|---|---|---|
| | (° C.) | (° C.) | (mJ/cm²) | (nm) |
| Example 1 | 90 | 90 | 58 | 2.09 |
| Example 2 | 90 | 90 | 87 | 2.09 |
| Example 3 | 90 | 90 | 57 | 2.20 |
| Example 4 | 90 | 90 | 60 | 2.12 |
| Example 5 | 90 | 90 | 62 | 2.15 |
| Example 6 | 90 | 90 | 52 | 2.14 |
| Example 7 | 90 | 90 | 54 | 2.08 |
| Example 8 | 90 | 90 | 63 | 2.19 |
| Example 9 | 90 | 90 | 56 | 2.20 |
| Example 10 | 90 | 90 | 59 | 2.17 |
| Example 11 | 90 | 90 | 63 | 2.17 |
| Example 12 | 90 | 90 | 62 | 2.13 |
| Example 13 | 90 | 90 | 53 | 2.18 |
| Example 14 | 90 | 90 | 55 | 2.12 |
| Comparative | 90 | 90 | 56 | 2.70 |
| Example 1 | | | | |

| | | | |
|---|---|---|---|
| Comparative | 90 | 90 | Not resolved |
| Example 2 | | | |

From the results in Table 2, it can be confirmed that the resist compositions of Examples 1 to 14, to which the present invention is applied, have reduced roughness in the line side wall as compared with the resist composition of Comparative Example 1, and thus a resist pattern having a more favorable shape is formed.

It is noted that in a case where the resist composition of Comparative Example 2 was used, no resolution occurred.

While preferred embodiments of the invention have been described and illustrated above, it should be understood that these are exemplary of the invention and are not to be considered as limiting. Additions, omissions, substitutions, and other modifications can be made without departing from the scope of the invention. Accordingly, the invention is not to be considered as being limited by the foregoing description and is only limited by the scope of the appended claims.

What is claimed is:

1. A resist composition that generates acid upon exposure and exhibits changed solubility in a developing solution under action of acid, the resist composition comprising:
a polymer (A1) containing a siloxane bond and an ionic group represented by General Formula (I0), which is decomposed upon exposure to generate acid: 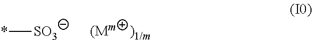
wherein M^{m+} represents a sulfonium cation or an iodonium cation, m represents an integer of 1 or more, and * represents a bonding site.

2. The resist composition according to claim 1, wherein the polymer (A1) has a constitutional unit represented by General Formula (a0-1): 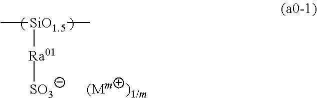
wherein Ra⁰¹ represents a divalent linking group having 1 to 40 carbon atoms, M^{m+} represents a sulfonium cation or an iodonium cation, and m represents an integer of 1 or more.

3. The resist composition according to claim 2, wherein Ra⁰¹ in General Formula (a0-1) represents a divalent linking group containing an ester bond.

4. The resist composition according to claim 3, wherein Ra⁰¹ in General Formula (a0-1) represents a divalent linking group further comprising a fluorine atom.

5. The resist composition according to claim 1, wherein the polymer (A1) further comprises a phenolic hydroxyl group.

6. The resist composition according to claim 1, wherein the polymer (A1) has a constitutional unit represented by General Formula (a1-1): 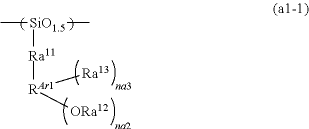
wherein Ra¹¹ represents a divalent linking group or a single bond, R^{Ar1} represents an aromatic hydrocarbon group, Ra¹² represents a hydrocarbon group having 1 to 6 carbon atoms or a hydrogen atom, Ra¹³ represents a hydrocarbon group having 1 to 6 carbon atoms, na2 is 1 or 2, and na3 represents an integer in a range of 0 to 4.

7. The resist composition according to claim 1, further comprising a photodecomposable base that is decomposed upon exposure and loses acid diffusion controllability.

8. The resist composition according to claim 1, further comprising a crosslinking agent component.

9. A method of forming a resist pattern, comprising:
forming a resist film on a support using the resist composition according to claim 1;
exposing the resist film; and
developing the exposed resist film to form a resist pattern.

10. The resist pattern forming method according to claim 9, the exposed resist film is subjected to alkali development to form a negative-tone resist pattern.

11. A polymer comprising:
a siloxane bond; and
an ionic group represented by General Formula (I0″), which is decomposed upon exposure to generate an acid: 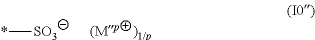
wherein M″^{p+} represents an onium cation or a metal cation, p represents an integer of 1 or more, and * represents a bonding site.

12. A polymer comprising:
a siloxane bond and;
an ionic group represented by General Formula (I0), which is decomposed upon exposure to generate an acid: 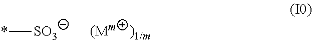
wherein M^{m+} represents a sulfonium cation or an iodonium cation, m represents an integer of 1 or more, and * represents a bonding site.
